(19) United States
(12) Patent Application Publication
(10) Pub. No.: US 2009/0174313 A1
(43) Pub. Date: Jul. 9, 2009

(54) ORGANIC ELECTROLUMINESCENCE DEVICE AND ORGANIC-ELECTROLUMINESCENCE-MATERIAL-CONTAINING SOLUTION

(75) Inventors: Kazuki NISHIMURA, Sodegaura-shi (JP); Toshihiro IWAKUMA, Sodegaura-shi (JP); Kenichi FUKUOKA, Sodegaura-shi (JP); Chishio HOSOKAWA, Sodegaura-shi (JP); Masahiro KAWAMURA, Sodegaura-shi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: Idemitsu Kosan Co., Ltd., Chiyoda-ku (JP)

(21) Appl. No.: 12/275,789

(22) Filed: Nov. 21, 2008

(30) Foreign Application Priority Data
Nov. 22, 2007 (JP) 2007-303712
Nov. 21, 2008 (JP) 2008-297887

(51) Int. Cl. H01L 51/54; C09K 11/06

(52) U.S. Cl. 313/504; 252/301.16

(57) ABSTRACT

An organic electroluminescence device includes: an anode (3); a cathode (8); and an organic thin-film layer provided between the anode (3) and the cathode (8). The organic thin-film layer includes an emitting layer (5) and an organic layer (6) provided on the emitting layer (5) adjacently to the cathode (8). The emitting layer (5) contains: a first polycyclic fused aromatic compound having a substituted or unsubstituted polycyclic fused aromatic skeleton; and a first phosphorescent material for emitting phosphorescence. The organic layer (6) contains a second polycyclic fused aromatic compound having a substituted or unsubstituted polycyclic fused aromatic skeleton.

### BACKGROUND OF THE INVENTION

1. Field of the Invention

The present invention relates to an organic electroluminescence device and an organic-electroluminescent-material-containing solution for forming the organic electroluminescence device.

2. Description of Related Art

An organic electroluminescence device (organic EL device), which includes an organic emitting layer between an anode and a cathode, has been known to emit light using exciton energy generated by a recombination of holes and electrons that have been injected into the emitting layer.

Such an organic EL device, which has the advantages as a self-emitting device, is expected to serve as an emitting device excellent in luminous efficiency, image quality, power consumption and thin design.

Further improvements on an organic EL device include improvements in luminous efficiency. In this respect, in order to enhance internal quantum efficiency, developments on phosphorescent materials that emit light using triplet exciton have been advanced. In recent years, a report has been made on an organic device that uses phosphorescent emission (e.g., Document 1: US2002/182441).

Since the internal quantum efficiency can be enhanced up to 75% or more (up to approximately 100% in theory) by using such a phosphorescent material, an organic EL device having high efficiency and consuming less power can be obtained.

For use of an emitting material in an organic EL device, a doping method, according to which a dopant material is doped to a host material, has been known as a usable method.

In order to efficiently generate exciton from injected energy and to efficiently use exciton energy for light emission, the exciton energy generated by the host is transferred to the dopant, so that light is emitted from the dopant.

Intermolecular transfer of energy from the host to the dopant requires energy gap Eg_{H} of the host to be larger than energy gap Eg_{D} of the dopant.

A known representative example of a material having effectively-large triplet energy gap has been CBP (4.4′-bis(N-carbazolyl)biphenyl).

By using such CBP as the host, energy can be transferred to a phosphorescent material for emitting light of a predetermined emitting wavelength (e.g., green, red), by which an organic EL device of high efficiency can be obtained.

However, although an organic EL device in which CBP is used as the host exhibits much higher luminous efficiency due to phosphorescent emission, the organic EL device has such a short lifetime as to be practically inapplicable.

On the other hand, a variety of host materials for fluorescent dopants are known. Various proposals have been made on a host material that, with a combination of a fluorescent dopant, exhibits excellent luminous efficiency and lifetime.

However, although singlet energy gap of a host material for fluorescent-emitting layer is larger than singlet energy gap Eg(S) of a fluorescent dopant, triplet energy gap Eg(T) of the host material is not necessarily larger than that of the fluorescent dopant. Thus, it is not successful to simply apply the host material for fluorescent-emitting layer to a host for phosphorescent emission.

Well-known examples of the host material for fluorescent-emitting layer are an anthracene derivative, a pyrene derivative and a naphthacene derivative. However, triplet energy gap Eg(T) of such compounds is approximately 1.9 eV and thus insufficient for emission wavelength in visible light range of 450 nm to 750 nm. Such an anthracene derivative is not suitable as a host for phosphorescent material.

In addition, since exciton may disperse to the outside of the emitting layer before light is emitted, an organic EL device in which a hole blocking layer is provided to the organic emitting layer adjacently to the cathode has been proposed. Such a hole blocking layer is exemplarily formed from a material such as BAlq or BCP. According to a known arrangement of an organic electroluminescence device, a compound containing phenanthrene is used for the hole blocking layer, and a layer containing Ir(ppy)₃ is provided (e.g., Document 2: JP-A-2005-197262).

As described above, no host material has been known to be capable of efficiently transferring energy to the phosphorescent material while exhibiting such a long lifetime as to be practically applicable, which has hindered a practical realization of a device in which a phosphorescent material is used.

Further, although the technique disclosed in the document 2 can work on deactivation of exciton, lifetime of the organic EL device of the document 2 remains to be further improved.

### SUMMARY OF THE INVENTION

An object of the invention is to provide an phosphorescent organic EL device capable of emitting light with practically-effective emission wavelength and having long lifetime.

An organic EL device according to an aspect of the invention includes: an anode;

a cathode; and an organic thin-film layer provided between the anode and the cathode, in which the organic thin-film layer includes: an emitting layer including: a first polycyclic fused aromatic compound having a substituted or unsubstituted polycyclic fused aromatic skeleton; and a first phosphorescent material for emitting phosphorescence; and an organic layer provided on the emitting layer adjacently to the cathode, the organic layer comprising a second polycyclic fused aromatic compound having a substituted or unsubstituted polycyclic fused aromatic skeleton.

According to the aspect of the invention, the organic layer functions as a hole blocking layer. While an unstable material such as BAlq or BCP has been conventionally used for the hole blocking layer, a polycyclic fused aromatic compound (a stable material) is used according to the aspect of the invention. Accordingly, molecular stability can be enhanced and device lifetime can be prolonged.

On the other hand, anthracene, tetracene or the like, which has been used as a host material for fluorescent emission, has not been applicable to a host material for phosphorescent emission because of small width of its triplet energy gap Eg(T). However, according to the aspect of the invention, such a problem is solved by applying a polycyclic fused aromatic compound of which triplet energy gap Eg(T) is large to the host material.

Preferably in the aspect of the invention, at least either one of the first polycyclic fused aromatic compound and the second polycyclic aromatic compound has minimum excited triplet energy gap of 2.1 eV to 2.7 eV, and the polycyclic fused aromatic skeleton has 10 to 30 ring-forming atoms.

Conventionally, a material having large triplet energy gap such as CBP has been a candidate for phosphorescent material widely applicable in a wide wavelength region of green to red. However, when triplet energy gap is excessively large, a difference in energy gap may be so large for a red-emitting phosphorescent material that energy may not be intermolecularly transferred efficiently, thereby unfavorably shortening the device lifetime. On the other hand, the material according to the aspect of the invention is less suitably applicable to a host for such a wide-gap phosphorescent material as a blue-emitting one because the minimum excited triplet energy gap is in a range of 2.1 eV to 2.7 eV, but is applicable to a host for a phosphorescent material having excited triplet energy gap of 2.7 eV or less, particularly to a host for a red-emitting phosphorescent material, because the energy gap is suitable. Thus, energy can be efficiently transferred from exciton of the host to the phosphorescent material, and phosphorescent emission that is highly efficient and stable for a long time can be obtained.

Triplet energy gap Eg(T) of the material may be exemplarily defined based on the phosphorescence spectrum. For instance, in an aspect of the invention, the triplet energy gap Eg(T) may be defined as follows.

Specifically, each material is dissolved in an EPA solvent (diethylether:isopentane:ethanol=5:5:2 in volume ratio) at a concentration of 10 μmol/L, thereby forming a sample for phosphorescence measurement.

Then, the sample for phosphorescence measurement is put into a quartz cell, cooled to 77K and irradiated with exciting light, so that a wavelength of phosphorescence radiated therefrom is measured.

A tangent line is drawn to be tangent to a rising section adjacent to short-wavelength of the obtained phosphorescence spectrum, a wavelength value at an intersection of the tangent line and a base line is converted into energy value, and the converted energy value is defined as the triplet energy gap Eg(T).

For the measurement, for instance, a commercially-available measuring equipment F-4500 (manufactured by Hitachi, Ltd.) may be used.

However, the triplet energy gap does not need to be defined by the above method, but may be defined by any other suitable method as long as an object and a spirit of the invention are not impaired.

In addition, since the molecular stability is not sufficiently enhanced when the number of the ring-forming atoms (excluding the number of atoms in substituents) in the skeleton is too small, the number of the ring-forming atoms (excluding the number of atoms in substituents) is set at 10 or more. On the other hand, since a HOMO-LUMO gap is so much narrowed that the triplet energy gap becomes insufficient for a useful emission wavelength when the number of the rings in the polycyclic fused ring is too large, the number of the ring-forming atoms (excluding the number of atoms in substituents) is set at 30 or less. The number of the ring-forming atoms (excluding the number of atoms in substituents) in the polycyclic fused aromatic skeleton is preferably set in a range of 20 to 30.

Preferably in the aspect of the invention, ionization potential of the second polycyclic fused aromatic compound is larger than ionization potential of the first polycyclic fused aromatic compound.

The ionization potential Ip means energy required for removing electron(s) from a compound of each material (i.e., energy required for ionization). The ionization potential is, for instance, a value measured by an ultraviolet-ray photoelectron spectrometer (AC-3, manufactured by Riken Keiki Co., Ltd.).

In addition, the first phosphorescent material is a material that emits light by receiving energy transfer from the first polycyclic fused aromatic compound, or a material that emits light with exciton being directly generated on the phosphorescent material.

According to the aspect of the invention, since the ionization potential of the second polycyclic fused aromatic compound is larger than the ionization potential of the first polycyclic fused aromatic compound, an energy difference at the time when the holes are injected into the emitting layer and the organic layer becomes stepwise. Thus, load on the emitting layer and the organic layer can be reduced, and the device lifetime can be prolonged.

Preferably in the aspect of the invention, minimum triplet energy gap Eg(T2) of the second polycyclic fused aromatic compound is larger than minimum triplet energy gap Eg(T1) of the first polycyclic fused aromatic compound.

The optical energy gap Eg(S) means a difference between a conduction level and a valence electron level. For instance, the optical energy gap is obtained by converting a wavelength value at an intersection of a long-wavelength side tangent line of absorption spectrum of toluene dilute solution of each material and a base line (base line obtained from absorbance) into energy.

As described above, by using the different host materials (the first polycyclic fused aromatic compound and the second polycyclic fused aromatic compound) respectively in the emitting layer and the organic layer, performance required for the host materials can be separated. For instance, by assigning the function of electron transportation to the second polycyclic fused aromatic compound, the first polycyclic fused aromatic compound can be selected from materials having small electron transporting capability but having high performance such as long lifetime and high efficiency.

Further, by combining the first polycyclic fused aromatic compound having high hole transporting capability with the second polycyclic fused aromatic compound having high electron transporting capability, a recombination region can be trapped within the emitting layer. With this arrangement, a leak of charges into the hole transporting layer and the electron transporting layer can be reduced, and shortening of the lifetime due to streamlining and degradation of a transporting material can be prevented.

Preferably in the aspect of the invention, the organic layer further includes a second phosphorescent material for emitting phosphorescence. Also preferably in the aspect of the invention, the organic layer further includes the first phosphorescent material.

According to the aspect of the invention, the organic layer functions both as the hole blocking layer and the emitting layer. Thus, not only the above-described effect(s) and advantage(s) can be obtained, but also the organic layer can also function as the emitting layer in the organic EL device.

Preferably in the aspect of the invention, the polycyclic fused aromatic skeletons each are present as a divalent or multivalent group in a chemical structure formula.

Examples of the substituent for the polycyclic fused aromatic skeleton are halogen atom, hydroxyl group, substituted or unsubstituted amino group, nitro group, cyano group, substituted or unsubstituted alkyl group, substituted or unsubstituted alkenyl group, substituted or unsubstituted cycloalkyl group, substituted or unsubstituted alkoxy group, substituted or unsubstituted aromatic hydrocarbon group, substituted or unsubstituted aromatic heterocyclic group, substituted or unsubstituted aralkyl group, substituted or unsubstituted aryloxy group, substituted or unsubstituted alkoxycarbonyl group, and carboxyl group.

When the polycyclic fused aromatic skeleton includes a plurality of substituents, the substituents may form a ring.

Examples of the halogen atom are fluorine, chlorine, bromine, iodine and the like.

The substituted or unsubstituted amino group is represented by —NX¹X². X¹ and X² each independently and exemplarily represent hydrogen atom, methyl group, ethyl group, propyl group, isopropyl group, n-butyl group, s-butyl group, isobutyl group, t-butyl group, n-pentyl group, n-hexyl group, n-heptyl group, n-octyl group, hydroxymethyl group, 1-hydroxyethyl group, 2-hydroxyethyl group, 2-hydroxyisobutyl group, 1,2-dihydroxyethyl group, 1,3-dihydroxyisopropyl group, 2,3-dihydroxy-t-butyl group, 1,2,3-trihydroxypropyl group, chloromethyl group, 1-chloroethyl group, 2-chloroethyl group, 2-chloroisobutyl group, 1,2-dichloroethyl group, 1,3-dichloroisopropyl group, 2,3-dichloro-t-butyl group, 1,2,3-trichloropropyl group, bromomethyl group, 1-bromoethyl group, 2-bromoethyl group, 2-bromoisobutyl group, 1,2-dibromoethyl group, 1,3-dibromoisopropyl group, 2,3-dibromo-t-butyl group, 1,2,3-tribromopropyl group, iodomethyl group, 1-iodoethyl group, 2-iodoethyl group, 2-iodoisobutyl group, 1,2-diiodoethyl group, 1,3-diiodoisopropyl group, 2,3-diiodo-t-butyl group, 1,2,3-triiodopropyl group, aminomethyl group, 1-aminoethyl group, 2-aminoethyl group, 2-aminoisobutyl group, 1,2-diaminoethyl group, 1,3-diaminoisopropyl group, 2,3-diamino-t-butyl group, 1,2,3-triaminopropyl group, cyanomethyl group, 1-cyanoethyl group, 2-cyanoethyl group, 2-cyanoisobutyl group, 1,2-dicyanoethyl group, 1,3-dicyanoisopropyl group, 2,3-dicyano-t-butyl group, 1,2,3-tricyanopropyl group, nitromethyl group, 1-nitroethyl group, 2-nitroethyl group, 2-nitroisobutyl group, 1,2-dinitroethyl group, 1,3-dinitroisopropyl group, 2,3-dinitro-t-butyl group, 1,2,3-trinitropropyl group, phenyl group, 1-naphthyl group, 2-naphthyl group, 1-anthryl group, 2-anthryl group, 9-anthryl group, 1-phenanthryl group, 2-phenanthryl group, 3-phenanthryl group, 4-phenanthryl group, 9-phenanthryl group, 1-naphthacenyl group, 2-naphthacenyl group, 9-naphthacenyl group, 4-styrylphenyl group, 1-pyrenyl group, 2-pyrenyl group, 4-pyrenyl group, 2-biphenylyl group, 3-biphenylyl group, 4-biphenylyl group, p-terphenyl-4-yl group, p-terphenyl-3-yl group, p-terphenyl-2-yl group, m-terphenyl-4-yl group, m-terphenyl-3-yl group, m-terphenyl-2-yl group, o-tolyl group, m-tolyl group, p-tolyl group, p-t-butylphenyl group, p-(2-phenylpropyl)phenyl group, 3-methyl-2-naphthyl group, 4-methyl-1-naphthyl group, 4-methyl-1-anthryl group, 4′-methylbiphenylyl group, 4″-t-butyl-p-terphenyl-4-yl group, 2-pyrrolyl group, 3-pyrrolyl group, pyrazinyl group, 2-pyridinyl group, 3-pyridinyl group, 4-pyridinyl group, 2-indolyl group, 3-indolyl group, 4-indolyl group, 5-indolyl group, 6-indolyl group, 7-indolyl group, 1-isoindolyl group, 3-isoindolyl group, 4-isoindolyl group, 5-isoindolyl group, 6-isoindolyl group, 7-isoindolyl group, 2-furyl group, 3-furyl group, 2-benzofuranyl group, 3-benzofuranyl group, 4-benzofuranyl group, 5-benzofuranyl group, 6-benzofuranyl group, 7-benzofuranyl group, 1-isobenzofuranyl group, 3-isobenzofuranyl group, 4-isobenzofuranyl group, 5-isobenzofuranyl group, 6-isobenzofuranyl group, 7-isobenzofuranyl group, 2-quinolyl group, 3-quinolyl group, 4-quinolyl group, 5-quinolyl group, 6-quinolyl group, 7-quinolyl group, 8-quinolyl group, 1-isoquinolyl group, 3-isoquinolyl group, 4-isoquinolyl group, 5-isoquinolyl group, 6-isoquinolyl group, 7-isoquinolyl group, 8-isoquinolyl group, 2-quinoxalinyl group, 5-quinoxalinyl group, 6-quinoxalinyl group, 1-phenanthridinyl group, 2-phenanthridinyl group, 3-phenanthridinyl group, 4-phenanthridinyl group, 6-phenanthridinyl group, 7-phenanthridinyl group, 8-phenanthridinyl group, 9-phenanthridinyl group, 10-phenanthridinyl group, 1-acridinyl group, 2-acridinyl group, 3-acridinyl group, 4-acridinyl group, 9-acridinyl group, 1,7-phenanthrolin-2-yl group, 1,7-phenanthrolin-3-yl group, 1,7-phenanthrolin-4-yl group, 1,7-phenanthrolin-5-yl group, 1,7-phenanthrolin-6-yl group, 1,7-phenanthrolin-8-yl group, 1,7-phenanthrolin-9-yl group, 1,7-phenanthrolin-10-yl group, 1,8-phenanthrolin-2-yl group, 1,8-phenanthrolin-3-yl group, 1,8-phenanthrolin-4-yl group, 1,8-phenanthrolin-5-yl group, 1,8-phenanthrolin-6-yl group, 1,8-phenanthrolin-7-yl group, 1,8-phenanthrolin-9-yl group, 1,8-phenanthrolin-10-yl group, 1,9-phenanthrolin-2-yl group, 1,9-phenanthrolin-3-yl group, 1,9-phenanthrolin-4-yl group, 1,9-phenanthrolin-5-yl group, 1,9-phenanthrolin-6-yl group, 1,9-phenanthrolin-7-yl group, 1,9-phenanthrolin-8-yl group, 1,9-phenanthrolin-10-yl group, 1,10-phenanthrolin-2-yl group, 1,10-phenanthrolin-3-yl group, 1,10-phenanthrolin-4-yl group, 1,10-phenanthrolin-5-yl group, 2,9-phenanthrolin-1-yl group, 2,9-phenanthrolin-3-yl group, 2,9-phenanthrolin-4-yl group, 2,9-phenanthrolin-5-yl group, 2,9-phenanthrolin-6-yl group, 2,9-phenanthrolin-7-yl group, 2,9-phenanthrolin-8-yl group, 2,9-phenanthrolin-10-yl group, 2,8-phenanthrolin-1-yl group, 2,8-phenanthrolin-3-yl group, 2,8-phenanthrolin-4-yl group, 2,8-phenanthrolin-5-yl group, 2,8-phenanthrolin-6-yl group, 2,8-phenanthrolin-7-yl group, 2,8-phenanthrolin-9-yl group, 2,8-phenanthrolin-10-yl group, 2,7-phenanthrolin-1-yl group, 2,7-phenanthrolin-3-yl group, 2,7-phenanthrolin-4-yl group, 2,7-phenanthrolin-5-yl group, 2,7-phenanthrolin-6-yl group, 2,7-phenanthrolin-8-yl group, 2,7-phenanthrolin-9-yl group, 2,7-phenanthrolin-10-yl group, 1-phenazinyl group, 2-phenazinyl group, 1-phenothiazinyl group, 2-phenothiazinyl group, 3-phenothiazinyl group, 4-phenothiazinyl group, 1-phenoxazinyl group, 2-phenoxazinyl group, 3-phenoxazinyl group, 4-phenoxazinyl group, 2-oxazolyl group, 4-oxazolyl group, 5-oxazolyl group, 2-oxadiazolyl group, 5-oxadiazolyl group, 3-furazanyl group, 2-thienyl group, 3-thienyl group, 2-methylpyrrol-1-yl group, 2-methylpyrrol-3-yl group, 2-methylpyrrol-4-yl group, 2-methylpyrrol-5-yl group, 3-methylpyrrol-1-yl group, 3-methylpyrrol-2-yl group, 3-methylpyrrol-4-yl group, 3-methylpyrrol-5-yl group, 2-t-butylpyrrol-4-yl group, 3-(2-phenylpropyl)pyrrol-1-yl group, 2-methyl-1-indolyl group, 4-methyl-1-indolyl group, 2-methyl-3-indolyl group, 4-methyl-3-indolyl group, 2-t-butyl-1-indolyl group, 4-t-butyl-1-indolyl group, 2-t-butyl-3-indolyl group, and 4-t-butyl-3-indolyl group.

Examples of the substituted or unsubstituted alkyl group are methyl group, ethyl group, propyl group, isopropyl group, n-butyl group, s-butyl group, isobutyl group, t-butyl group, n-pentyl group, n-hexyl group, n-heptyl group, n-octyl group, hydroxymethyl group, 1-hydroxyethyl group, 2-hydroxyethyl group, 2-hydroxyisobutyl group, 1,2-dihydroxyethyl group, 1,3-dihydroxyisopropyl group, 2,3-dihydroxy-t-butyl group, 1,2,3-trihydroxypropyl group, chloromethyl group, 1-chloroethyl group, 2-chloroethyl group, 2-chloroisobutyl group, 1,2-dichloroethyl group, 1,3-dichloroisopropyl group, 2,3-dichloro-t-butyl group, 1,2,3-trichloropropyl group, bromomethyl group, 1-bromoethyl group, 2-bromoethyl group, 2-bromoisobutyl group, 1,2-dibromoethyl group, 1,3-dibromoisopropyl group, 2,3-dibromo-t-butyl group, 1,2,3-tribromopropyl group, iodomethyl group, 1-iodoethyl group, 2-iodoethyl group, 2-iodoisobutyl group, 1,2-diiodoethyl group, 1,3-diiodoisopropyl group, 2,3-diiodo-t-butyl group, 1,2,3-triiodopropyl group, aminomethyl group, 1-aminoethyl group, 2-aminoethyl group, 2-aminoisobutyl group, 1,2-diaminoethyl group, 1,3-diaminoisopropyl group, 2,3-diamino-t-butyl group, 1,2,3-triaminopropyl group, cyanomethyl group, 1-cyanoethyl group, 2-cyanoethyl group, 2-cyanoisobutyl group, 1,2-dicyanoethyl group, 1,3-dicyanoisopropyl group, 2,3-dicyano-t-butyl group, 1,2,3-tricyanopropyl group, nitromethyl group, 1-nitroethyl group, 2-nitroethyl group, 2-nitroisobutyl group, 1,2-dinitroethyl group, 1,3-dinitroisopropyl group, 2,3-dinitro-t-butyl group, and 1,2,3-trinitropropyl group.

Examples of the substituted or unsubstituted alkenyl group are vinyl group, allyl group, 1-butenyl group, 2-butenyl group, 3-butenyl group, 1,3-butanedienyl group, 1-methylvinyl group, styryl group, 4-diphenylaminostyryl group, 4-di-p-tolylaminostyryl group, 4-di-m-tolylaminostyryl group, 2,2-diphenylvinyl group, 1,2-diphenylvinyl group, 1-methylallyl group, 1,1-dimethylallyl group, 2-methylallyl group, 1-phenylallyl group, 2-phenylallyl group, 3-phenylallyl group, 3,3-diphenylallyl group, 1,2-dimethylallyl group, 1-phenyl-1-butenyl group, and 3-phenyl-1-butenyl group.

Examples of the substituted or unsubstituted cycloalkyl group are cyclopropyl group, cyclobutyl group, cyclopentyl group, cyclohexyl group, and 4-methylcyclohexyl group.

The substituted or unsubstituted alkoxy group is represented by —OY. Examples of Y are methyl group, ethyl group, propyl group, isopropyl group, n-butyl group, s-butyl group, isobutyl group, t-butyl group, n-pentyl group, n-hexyl group, n-heptyl group, n-octyl group, hydroxymethyl group, 1-hydroxyethyl group, 2-hydroxyethyl group, 2-hydroxyisobutyl group, 1,2-dihydroxyethyl group, 1,3-dihydroxyisopropyl group, 2,3-dihydroxy-t-butyl group, 1,2,3-trihydroxypropyl group, chloromethyl group, 1-chloroethyl group, 2-chloroethyl group, 2-chloroisobutyl group, 1,2-dichloroethyl group, 1,3-dichloroisopropyl group, 2,3-dichloro-t-butyl group, 1,2,3-trichloropropyl group, bromomethyl group, 1-bromoethyl group, 2-bromoethyl group, 2-bromoisobutyl group, 1,2-dibromoethyl group, 1,3-dibromoisopropyl group, 2,3-dibromo-t-butyl group, 1,2,3-tribromopropyl group, iodomethyl group, 1-iodoethyl group, 2-iodoethyl group, 2-iodoisobutyl group, 1,2-diiodoethyl group, 1,3-diiodoisopropyl group, 2,3-diiodo-t-butyl group, 1,2,3-triiodopropyl group, aminomethyl group, 1-aminoethyl group, 2-aminoethyl group, 2-aminoisobutyl group, 1,2-diaminoethyl group, 1,3-diaminoisopropyl group, 2,3-diamino-t-butyl group, 1,2,3-triaminopropyl group, cyanomethyl group, 1-cyanoethyl group, 2-cyanoethyl group, 2-cyanoisobutyl group, 1,2-dicyanoethyl group, 1,3-dicyanoisopropyl group, 2,3-dicyano-t-butyl group, 1,2,3-tricyanopropyl group, nitromethyl group, 1-nitroethyl group, 2-nitroethyl group, 2-nitroisobutyl group, 1,2-dinitroethyl group, 1,3-dinitroisopropyl group, 2,3-dinitro-t-butyl group, and 1,2,3-trinitropropyl group.

Examples of the substituted or unsubstituted aromatic hydrocarbon group are phenyl group, 1-naphthyl group, 2-naphthyl group, 1-anthryl group, 2-anthryl group, 9-anthryl group, 1-phenanthryl group, 2-phenanthryl group, 3-phenanthryl group, 4-phenanthryl group, 9-phenanthryl group, 1-naphthacenyl group, 2-naphthacenyl group, 9-naphthacenyl group, 1-pyrenyl group, 2-pyrenyl group, 4-pyrenyl group, 2-biphenylyl group, 3-biphenylyl group, 4-biphenylyl group, p-terphenyl-4-yl group, p-terphenyl-3-yl group, p-terphenyl-2-yl group, m-terphenyl-4-yl group, m-terphenyl-3-yl group, m-terphenyl-2-yl group, o-tolyl group, m-tolyl group, p-tolyl group, p-t-butylphenyl group, p-(2-phenylpropyl)phenyl group, 3-methyl-2-naphthyl group, 4-methyl-1-naphthyl group, 4-methyl-1-anthryl group, 4′-methylbiphenylyl group, and 4″-t-butyl-p-terphenyl-4-yl group.

Examples of the substituted or unsubstituted aromatic heterocyclic group are 1-pyrrolyl group, 2-pyrrolyl group, 3-pyrrolyl group, pyrazinyl group, 2-pyridinyl group, 3-pyridinyl group, 4-pyridinyl group, 1-indolyl group, 2-indolyl group, 3-indolyl group, 4-indolyl group, 5-indolyl group, 6-indolyl group, 7-indolyl group, 1-isoindolyl group, 2-isoindolyl group, 3-isoindolyl group, 4-isoindolyl group, 5-isoindolyl group, 6-isoindolyl group, 7-isoindolyl group, 2-furyl group, 3-furyl group, 2-benzofuranyl group, 3-benzofuranyl group, 4-benzofuranyl group, 5-benzofuranyl group, 6-benzofuranyl group, 7-benzofuranyl group, 1-isobenzofuranyl group, 3-isobenzofuranyl group, 4-isobenzofuranyl group, 5-isobenzofuranyl group, 6-isobenzofuranyl group, 7-isobenzofuranyl group, 2-quinolyl group, 3-quinolyl group, 4-quinolyl group, 5-quinolyl group, 6-quinolyl group, 7-quinolyl group, 8-quinolyl group, 1-isoquinolyl group, 3-isoquinolyl group, 4-isoquinolyl group, 5-isoquinolyl group, 6-isoquinolyl group, 7-isoquinolyl group, 8-isoquinolyl group, 2-quinoxalinyl group, 5-quinoxalinyl group, 6-quinoxalinyl group, 1-phenanthridinyl group, 2-phenanthridinyl group, 3-phenanthridinyl group, 4-phenanthridinyl group, 6-phenanthridinyl group, 7-phenanthridinyl group, 8-phenanthridinyl group, 9-phenanthridinyl group, 10-phenanthridinyl group, 1-acridinyl group, 2-acridinyl group, 3-acridinyl group, 4-acridinyl group, 9-acridinyl group, 1,7-phenanthrolin-2-yl group, 1,7-phenanthrolin-3-yl group, 1,7-phenanthrolin-4-yl group, 1,7-phenanthrolin-5-yl group, 1,7-phenanthrolin-6-yl group, 1,7-phenanthrolin-8-yl group, 1,7-phenanthrolin-9-yl group, 1,7-phenanthrolin-10-yl group, 1,8-phenanthrolin-2-yl group, 1,8-phenanthrolin-3-yl group, 1,8-phenanthrolin-4-yl group, 1,8-phenanthrolin-5-yl group, 1,8-phenanthrolin-6-yl group, 1,8-phenanthrolin-7-yl group, 1,8-phenanthrolin-9-yl group, 1,8-phenanthrolin-10-yl group, 1,9-phenanthrolin-2-yl group, 1,9-phenanthrolin-3-yl group, 1,9-phenanthrolin-4-yl group, 1,9-phenanthrolin-5-yl group, 1,9-phenanthrolin-6-yl group, 1,9-phenanthrolin-7-yl group, 1,9-phenanthrolin-8-yl group, 1,9-phenanthrolin-10-yl group, 1,10-phenanthrolin-2-yl group, 1,10-phenanthrolin-3-yl group, 1,10-phenanthrolin-4-yl group, 1,10-phenanthrolin-5-yl group, 2,9-phenanthrolin-1-yl group, 2,9-phenanthrolin-3-yl group, 2,9-phenanthrolin-4-yl group, 2,9-phenanthrolin-5-yl group, 2,9-phenanthrolin-6-yl group, 2,9-phenanthrolin-7-yl group, 2,9-phenanthrolin-8-yl group, 2,9-phenanthrolin-10-yl group, 2,8-phenanthrolin-1-yl group, 2,8-phenanthrolin-3-yl group, 2,8-phenanthrolin-4-yl group, 2,8-phenanthrolin-5-yl group, 2,8-phenanthrolin-6-yl group, 2,8-phenanthrolin-7-yl group, 2,8-phenanthrolin-9-yl group, 2,8-phenanthrolin-10-yl group, 2,7-phenanthrolin-1-yl group, 2,7-phenanthrolin-3-yl group, 2,7-phenanthrolin-4-yl group, 2,7-phenanthrolin-5-yl group, 2,7-phenanthrolin-6-yl group, 2,7-phenanthrolin-8-yl group, 2,7-phenanthrolin-9-yl group, 2,7-phenanthrolin-10-yl group, 1-phenazinyl group, 2-phenazinyl group, 1-phenothiazinyl group, 2-phenothiazinyl group, 3-phenothiazinyl group, 4-phenothiazinyl group, 10-phenothiazinyl group, 1-phenoxazinyl group, 2-phenoxazinyl group, 3-phenoxazinyl group, 4-phenoxazinyl group, 10-phenoxazinyl group, 2-oxazolyl group, 4-oxazolyl group, 5-oxazolyl group, 2-oxadiazolyl group, 5-oxadiazolyl group, 3-furazanyl group, 2-thienyl group, 3-thienyl group, 2-methylpyrrol-1-yl group, 2-methylpyrrol-3-yl group, 2-methylpyrrol-4-yl group, 2-methylpyrrol-5-yl group, 3-methylpyrrol-1-yl group, 3-methylpyrrol-2-yl group, 3-methylpyrrol-4-yl group, 3-methylpyrrol-5-yl group, 2-t-butylpyrrol-4-yl group, 3-(2-phenylpropyl)pyrrol-1-yl group, 2-methyl-1-indolyl group, 4-methyl-1-indolyl group, 2-methyl-3-indolyl group, 4-methyl-3-indolyl group, 2-t-butyl-1-indolyl group, 4-t-butyl-1-indolyl group, 2-t-butyl-3-indolyl group, and 4-t-butyl-3-indolyl group.

Examples of the substituted or unsubstituted aralkyl group are benzyl group, 1-phenylethyl group, 2-phenylethyl group, 1-phenylisopropyl group, 2-phenylisopropyl group, phenyl-t-butyl group, α-naphthylmethyl group, 1-α-naphthylethyl group, 2-α-naphthylethyl group, 1-α-naphthylisopropyl group, 2-α-naphthylisopropyl group, β-naphthylmethyl group, 1-β-naphthylethyl group, 2-β-naphthylethyl group, 1-β-naphthylisopropyl group, 2-β-naphthylisopropyl group, 1-pyrrolylmethyl group, 2-(1-pyrrolyl)ethyl group, p-methylbenzyl group, m-methylbenzyl group, o-methylbenzyl group, p-chlorobenzyl group, m-chlorobenzyl group, o-chlorobenzyl group, p-bromobenzyl group, m-bromobenzyl group, o-bromobenzyl group, p-iodobenzyl group, m-iodobenzyl group, o-iodobenzyl group, p-hydroxybenzyl group, m-hydroxybenzyl group, o-hydroxybenzyl group, p-aminobenzyl group, m-aminobenzyl group, o-aminobenzyl group, p-nitrobenzyl group, m-nitrobenzyl group, o-nitrobenzyl group, p-cyanobenzyl group, m-cyanobenzyl group, o-cyanobenzyl group, 1-hydroxy-2-phenylisopropyl group, and 1-chloro-2-phenylisopropyl group.

The substituted or unsubstituted aryloxy group is represented by —OZ. Examples of Z are phenyl group, 1-naphthyl group, 2-naphthyl group, 1-anthryl group, 2-anthryl group, 9-anthryl group, 1-phenanthryl group, 2-phenanthryl group, 3-phenanthryl group, 4-phenanthryl group, 9-phenanthryl group, 1-naphthacenyl group, 2-naphthacenyl group, 9-naphthacenyl group, 1-pyrenyl group, 2-pyrenyl group, 4-pyrenyl group, 2-biphenylyl group, 3-biphenylyl group, 4-biphenylyl group, p-terphenyl-4-yl group, p-terphenyl-3-yl group, p-terphenyl-2-yl group, m-terphenyl-4-yl group, m-terphenyl-3-yl group, m-terphenyl-2-yl group, o-tolyl group, m-tolyl group, p-tolyl group, p-t-butylphenyl group, p-(2-phenylpropyl)phenyl group, 3-methyl-2-naphthyl group, 4-methyl-1-naphthyl group, 4-methyl-1-anthryl group, 4′-methylbiphenylyl group, 4″-t-butyl-p-terphenyl-4-yl group, 2-pyrrolyl group, 3-pyrrolyl group, pyrazinyl group, 2-pyridinyl group, 3-pyridinyl group, 4-pyridinyl group, 2-indolyl group, 3-indolyl group, 4-indolyl group, 5-indolyl group, 6-indolyl group, 7-indolyl group, 1-isoindolyl group, 3-isoindolyl group, 4-isoindolyl group, 5-isoindolyl group, 6-isoindolyl group, 7-isoindolyl group, 2-furyl group, 3-furyl group, 2-benzofuranyl group, 3-benzofuranyl group, 4-benzofuranyl group, 5-benzofuranyl group, 6-benzofuranyl group, 7-benzofuranyl group, 1-isobenzofuranyl group, 3-isobenzofuranyl group, 4-isobenzofuranyl group, 5-isobenzofuranyl group, 6-isobenzofuranyl group, 7-isobenzofuranyl group, 2-quinolyl group, 3-quinolyl group, 4-quinolyl group, 5-quinolyl group, 6-quinolyl group, 7-quinolyl group, 8-quinolyl group, 1-isoquinolyl group, 3-isoquinolyl group, 4-isoquinolyl group, 5-isoquinolyl group, 6-isoquinolyl group, 7-isoquinolyl group, 8-isoquinolyl group, 2-quinoxalinyl group, 5-quinoxalinyl group, 6-quinoxalinyl group, 1-phenanthridinyl group, 2-phenanthridinyl group, 3-phenanthridinyl group, 4-phenanthridinyl group, 6-phenanthridinyl group, 7-phenanthridinyl group, 8-phenanthridinyl group, 9-phenanthridinyl group, 10-phenanthridinyl group, 1-acridinyl group, 2-acridinyl group, 3-acridinyl group, 4-acridinyl group, 9-acridinyl group, 1,7-phenanthrolin-2-yl group, 1,7-phenanthrolin-3-yl group, 1,7-phenanthrolin-4-yl group, 1,7-phenanthrolin-5-yl group, 1,7-phenanthrolin-6-yl group, 1,7-phenanthrolin-8-yl group, 1,7-phenanthrolin-9-yl group, 1,7-phenanthrolin-10-yl group, 1,8-phenanthrolin-2-yl group, 1,8-phenanthrolin-3-yl group, 1,8-phenanthrolin-4-yl group, 1,8-phenanthrolin-5-yl group, 1,8-phenanthrolin-6-yl group, 1,8-phenanthrolin-7-yl group, 1,8-phenanthrolin-9-yl group, 1,8-phenanthrolin-10-yl group, 1,9-phenanthrolin-2-yl group, 1,9-phenanthrolin-3-yl group, 1,9-phenanthrolin-4-yl group, 1,9-phenanthrolin-5-yl group, 1,9-phenanthrolin-6-yl group, 1,9-phenanthrolin-7-yl group, 1,9-phenanthrolin-8-yl group, 1,9-phenanthrolin-10-yl group, 1,10-phenanthrolin-2-yl group, 1,10-phenanthrolin-3-yl group, 1,10-phenanthrolin-4-yl group, 1,10-phenanthrolin-5-yl group, 2,9-phenanthrolin-1-yl group, 2,9-phenanthrolin-3-yl group, 2,9-phenanthrolin-4-yl group, 2,9-phenanthrolin-5-yl group, 2,9-phenanthrolin-6-yl group, 2,9-phenanthrolin-7-yl group, 2,9-phenanthrolin-8-yl group, 2,9-phenanthrolin-10-yl group, 2,8-phenanthrolin-1-yl group, 2,8-phenanthrolin-3-yl group, 2,8-phenanthrolin-4-yl group, 2,8-phenanthrolin-5-yl group, 2,8-phenanthrolin-6-yl group, 2,8-phenanthrolin-7-yl group, 2,8-phenanthrolin-9-yl group, 2,8-phenanthrolin-10-yl group, 2,7-phenanthrolin-1-yl group, 2,7-phenanthrolin-3-yl group, 2,7-phenanthrolin-4-yl group, 2,7-phenanthrolin-5-yl group, 2,7-phenanthrolin-6-yl group, 2,7-phenanthrolin-8-yl group, 2,7-phenanthrolin-9-yl group, 2,7-phenanthrolin-10-yl group, 1-phenazinyl group, 2-phenazinyl group, 1-phenothiazinyl group, 2-phenothiazinyl group, 3-phenothiazinyl group, 4-phenothiazinyl group, 1-phenoxazinyl group, 2-phenoxazinyl group, 3-phenoxazinyl group, 4-phenoxazinyl group, 2-oxazolyl group, 4-oxazolyl group, 5-oxazolyl group, 2-oxadiazolyl group, 5-oxadiazolyl group, 3-furazanyl group, 2-thienyl group, 3-thienyl group, 2-methylpyrrol-1-yl group, 2-methylpyrrol-3-yl group, 2-methylpyrrol-4-yl group, 2-methylpyrrol-5-yl group, 3-methylpyrrol-1-yl group, 3-methylpyrrol-2-yl group, 3-methylpyrrol-4-yl group, 3-methylpyrrol-5-yl group, 2-t-butylpyrrol-4-yl group, 3-(2-phenylpropyl)pyrrol-1-yl group, 2-methyl-1-indolyl group, 4-methyl-1-indolyl group, 2-methyl-3-indolyl group, 4-methyl-3-indolyl group, 2-t-butyl-1-indolyl group, 4-t-butyl-1-indolyl group, 2-t-butyl-3-indolyl group, and 4-t-butyl-3-indolyl group.

The substituted or unsubstituted alkoxycarbonyl group is represented by —COOY. Examples of Y are methyl group, ethyl group, propyl group, isopropyl group, n-butyl group, s-butyl group, isobutyl group, t-butyl group, n-pentyl group, n-hexyl group, n-heptyl group, n-octyl group, hydroxymethyl group, 1-hydroxyethyl group, 2-hydroxyethyl group, 2-hydroxyisobutyl group, 1,2-dihydroxyethyl group, 1,3-dihydroxyisopropyl group, 2,3-dihydroxy-t-butyl group, 1,2,3-trihydroxypropyl group, chloromethyl group, 1-chloroethyl group, 2-chloroethyl group, 2-chloroisobutyl group, 1,2-dichloroethyl group, 1,3-dichloroisopropyl group, 2,3-dichloro-t-butyl group, 1,2,3-trichloropropyl group, bromomethyl group, 1-bromoethyl group, 2-bromoethyl group, 2-bromoisobutyl group, 1,2-dibromoethyl group, 1,3-dibromoisopropyl group, 2,3-dibromo-t-butyl group, 1,2,3-tribromopropyl group, iodomethyl group, 1-iodoethyl group, 2-iodoethyl group, 2-iodoisobutyl group, 1,2-diiodoethyl group, 1,3-diiodoisopropyl group, 2,3-diiodo-t-butyl group, 1,2,3-triiodopropyl group, aminomethyl group, 1-aminoethyl group, 2-aminoethyl group, 2-aminoisobutyl group, 1,2-diaminoethyl group, 1,3-diaminoisopropyl group, 2,3-diamino-t-butyl group, 1,2,3-triaminopropyl group, cyanomethyl group, 1-cyanoethyl group, 2-cyanoethyl group, 2-cyanoisobutyl group, 1,2-dicyanoethyl group, 1,3-dicyanoisopropyl group, 2,3-dicyano-t-butyl group, 1,2,3-tricyanopropyl group, nitromethyl group, 1-nitroethyl group, 2-nitroethyl group, 2-nitroisobutyl group, 1,2-dinitroethyl group, 1,3-dinitroisopropyl group, 2,3-dinitro-t-butyl group, and 1,2,3-trinitropropyl group.

Preferably in the aspect of the invention, the polycyclic fused aromatic skeletons each have a substituent, and the substituent is a substituted or unsubstituted aryl group or a heteroaryl group. Also preferably in the aspect of the invention, the substituent of the polycyclic fused aromatic skeletons each is other than a substituent having a carbazole skeleton.

By introducing an aryl group or a heteroaryl group as the substituent, the energy gap can be adjusted and molecular associate can be prevented. Thus, the lifetime can be prolonged.

When a carbazole group is introduced as the substituent, triplet energy gap is widened due to increase in ionization potential, so that a multilayer structure for the first emitting layer and the second emitting layer to be gradually injected with holes and electrons from the anode and the cathode respectively may not be easily obtained, thereby unfavorably hindering prolongation of device lifetime. In addition, although the material in which a carbazole group is introduced as the substituent is also applicable to a host for a phosphorescent material for emitting light of a shorter wavelength, introduction of a carbazole group, which is typically vulnerable to oxidation, may unfavorably lead to shorter lifetime.

In this respect, although leading to narrower energy gap between the first emitting layer and the second emitting layer, exclusion of a carbazole group from candidates for the substituent is preferable because the lifetime can be prolonged.

Preferably in the aspect of the invention, the polycyclic fused aromatic skeletons each are selected from a group consisting of substituted or unsubstituted phenanthrene-diyl, chrysene-diyl, fluoranthene-diyl and triphenylene-diyl.

Also preferably in the aspect of the invention, the polycyclic fused aromatic skeletons each are substituted by a group containing phenanthrene, chrysene, fluoranthene or triphenylene.

Preferably in the aspect of the invention, the polycyclic fused aromatic skeletons each are represented by one of formulae (1) to (4) as follows.

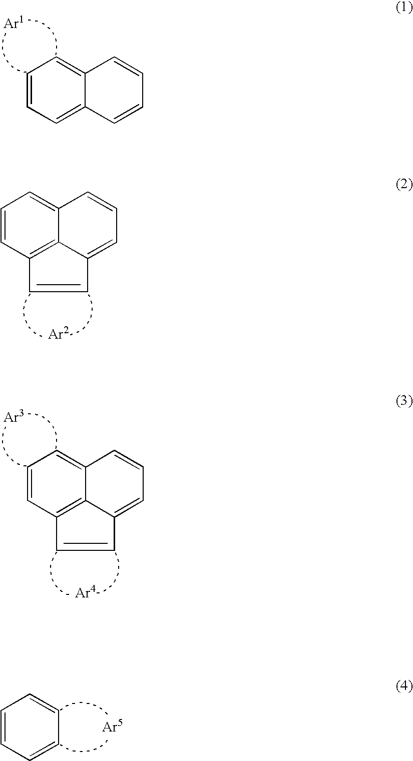

In the formulae (1) to (4), Ar¹ to Ar⁵ each represent a substituted or unsubstituted fused ring structure having 4 to 10 ring-forming carbon atoms (excluding the number of carbon atoms in the substituents).

Examples of the compound represented by the formula (1) are substituted or unsubstituted phenanthrene and chrysene.

Examples of the compound represented by the formula (2) are substituted or unsubstituted acenaphthylene, acenaphthene and fluoranthene.

An example of the compound represented by the formula (3) is substituted or unsubstituted benzofluoranthene.

An example of the compound represented by the formula (4) is the elementary substance of substituted or unsubstituted naphthalene or its derivative.

The naphthalene derivative is exemplarily represented by the following formula (4A).

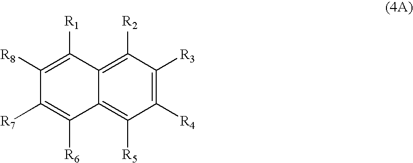

In the formula (4A), R₁ to R₈ each independently represent a hydrogen atom or a substituent formed by one group or a combination of two or more groups selected from a substituted or unsubstituted aryl group having 5 to 30 ring-forming carbon atoms (excluding the number of carbon atoms in the substituent), a branched or linear alkyl group having 1 to 30 carbon atoms and a substituted or unsubstituted cycloalkyl group having 3 to 20 carbon atoms.

Examples of the naphthalene derivative are as follows.

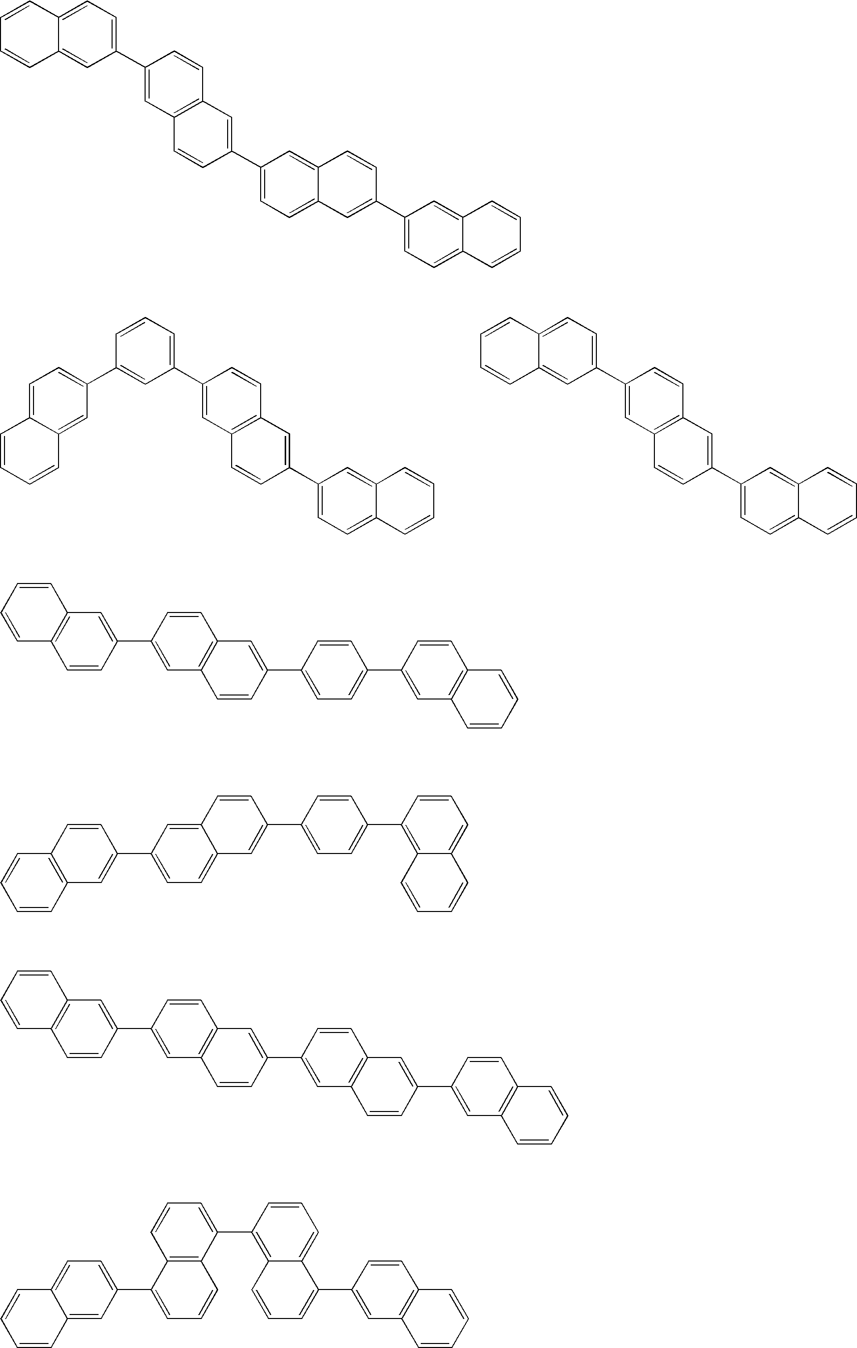

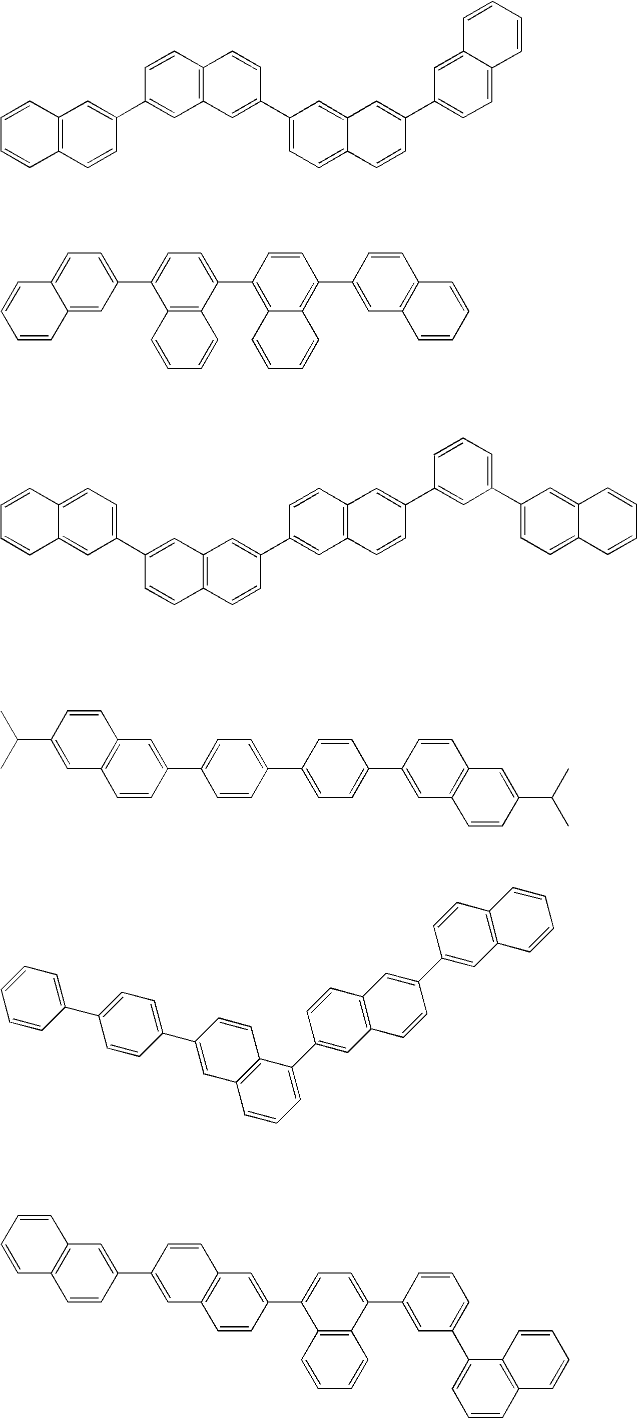

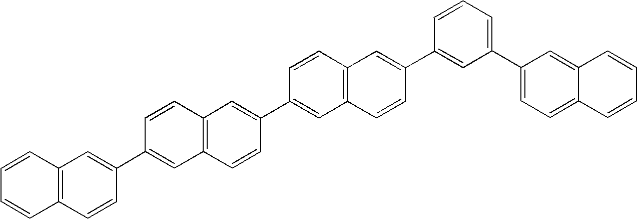

In the aspect of the invention, the polycyclic fused aromatic skeleton is preferably the elementary substance of phenanthrene represented by the following formula (5) or its derivative.

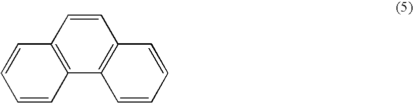

Examples of the substituent for the phenanthrene derivative are alkyl group, cycloalkyl group, aralkyl group, alkenyl group, cycloalkenyl group, alkynyl group, hydroxyl group, mercapto group, alkoxy group, alkylthio group, arylether group, arylthioether group, aryl group, heterocyclic group, halogen, haloalkane, haloalkene, haloalkyne, cyano group, aldehyde group, carbonyl group, carboxyl group, ester group, amino group, nitro group, silyl group, siloxanyl group.

The phenanthrene derivative is exemplarily represented by the following formula (5A).

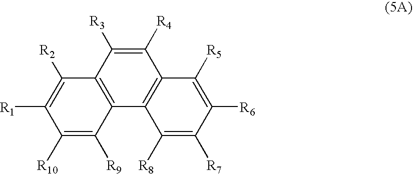

In the formula (5A), R₁ to R₁₀ each independently represent a hydrogen atom or a substituent formed by one group or a combination of two or more groups selected from a substituted or unsubstituted aryl group having 5 to 30 ring-forming carbon atoms (excluding the number of carbon atoms in the substituent), a branched or linear alkyl group having 1 to 30 carbon atoms and a substituted or unsubstituted cycloalkyl group having 3 to 20 carbon atoms.

Examples of the phenanthrene derivative represented by the formula (5) are as follows.

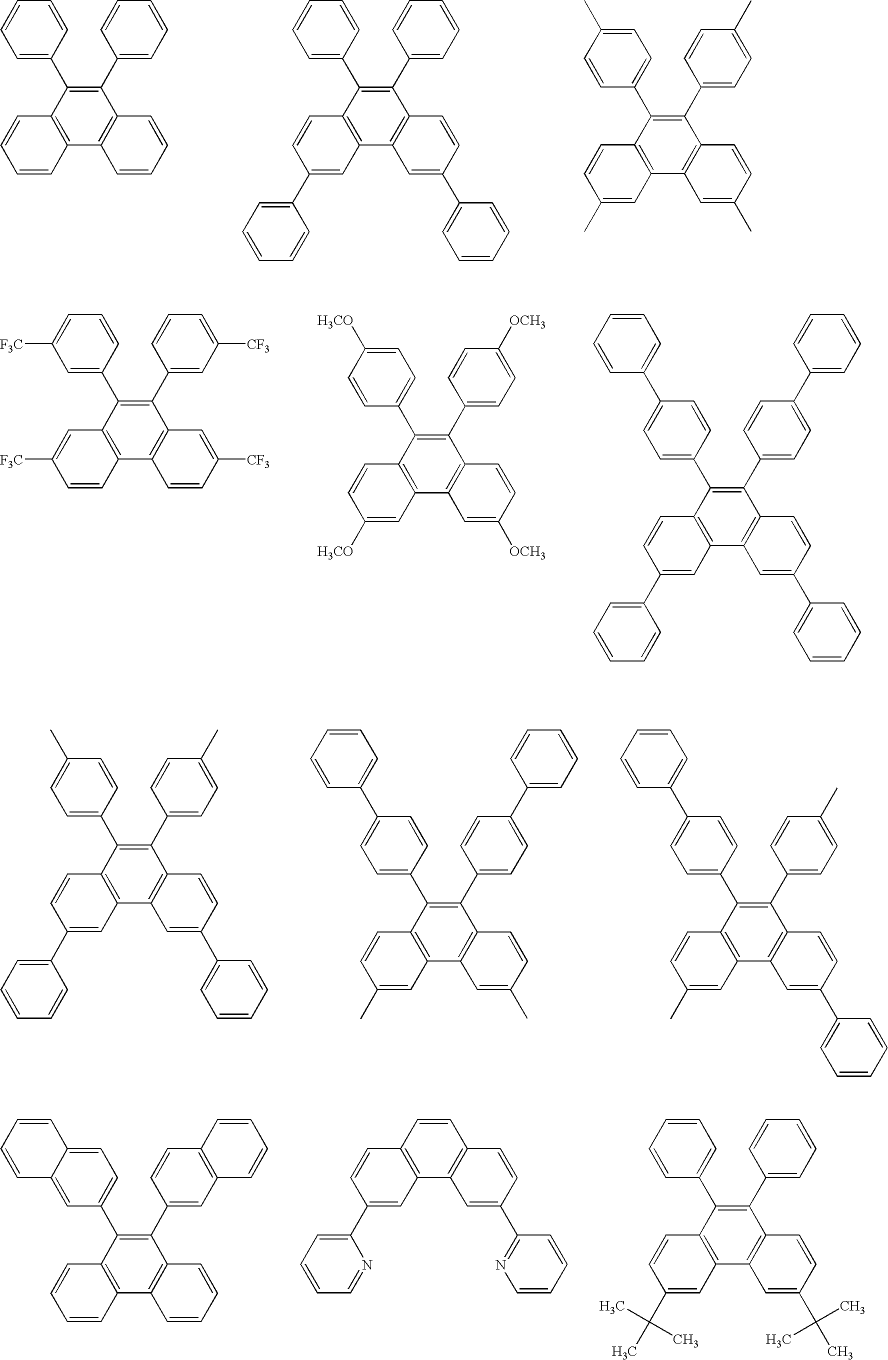

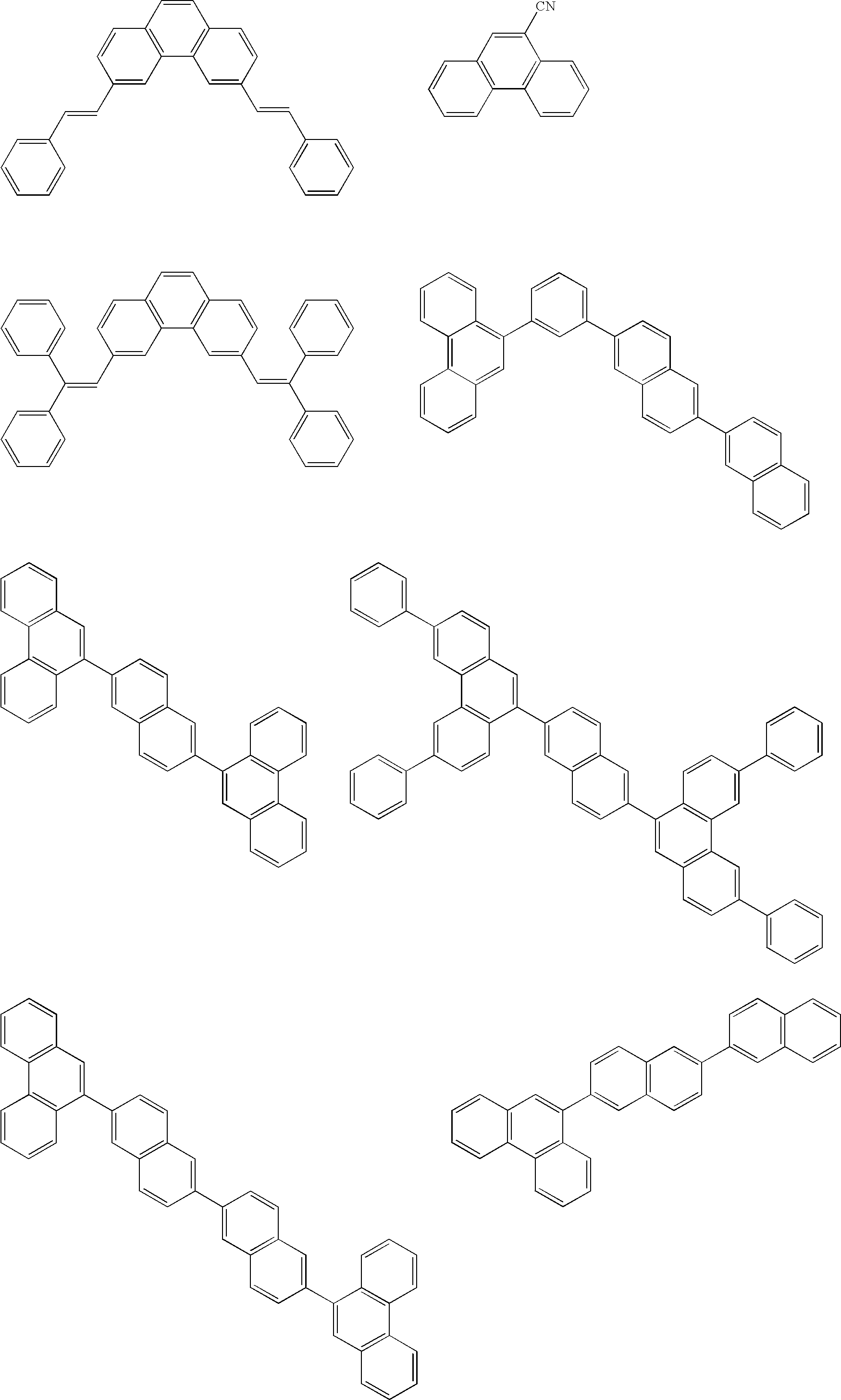

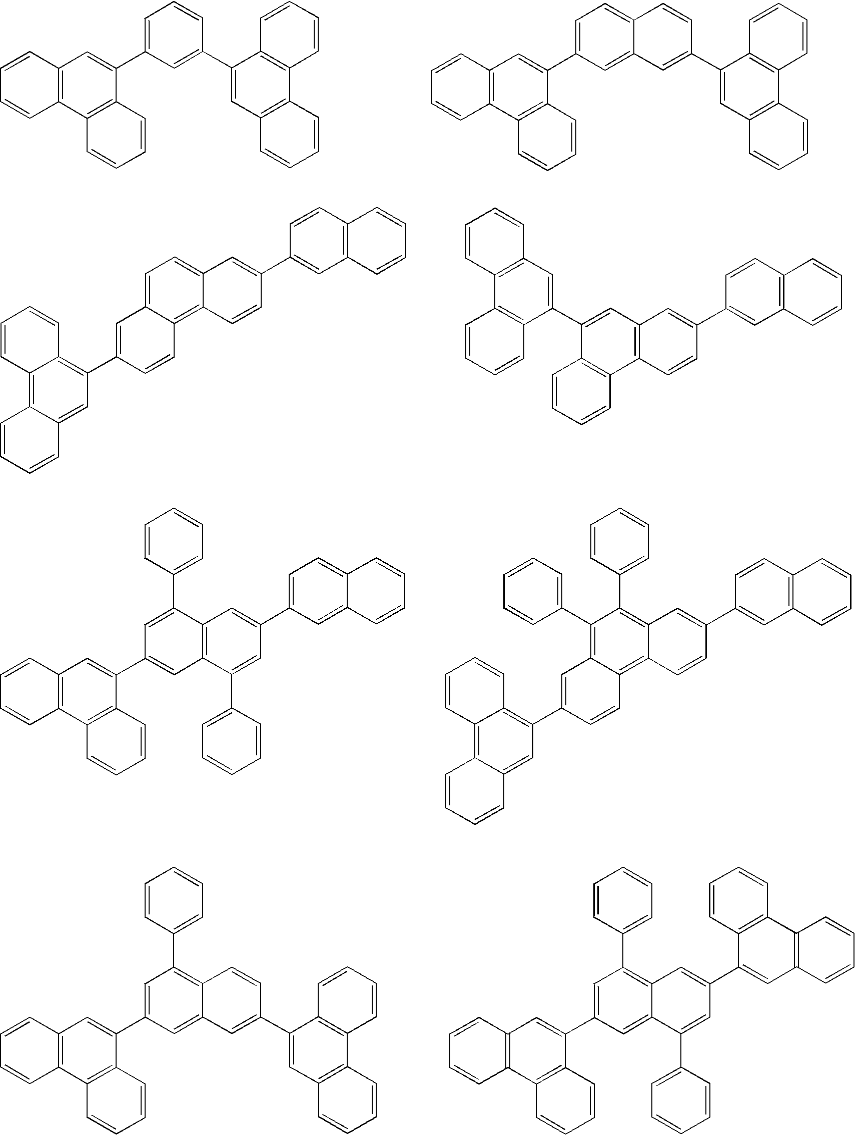

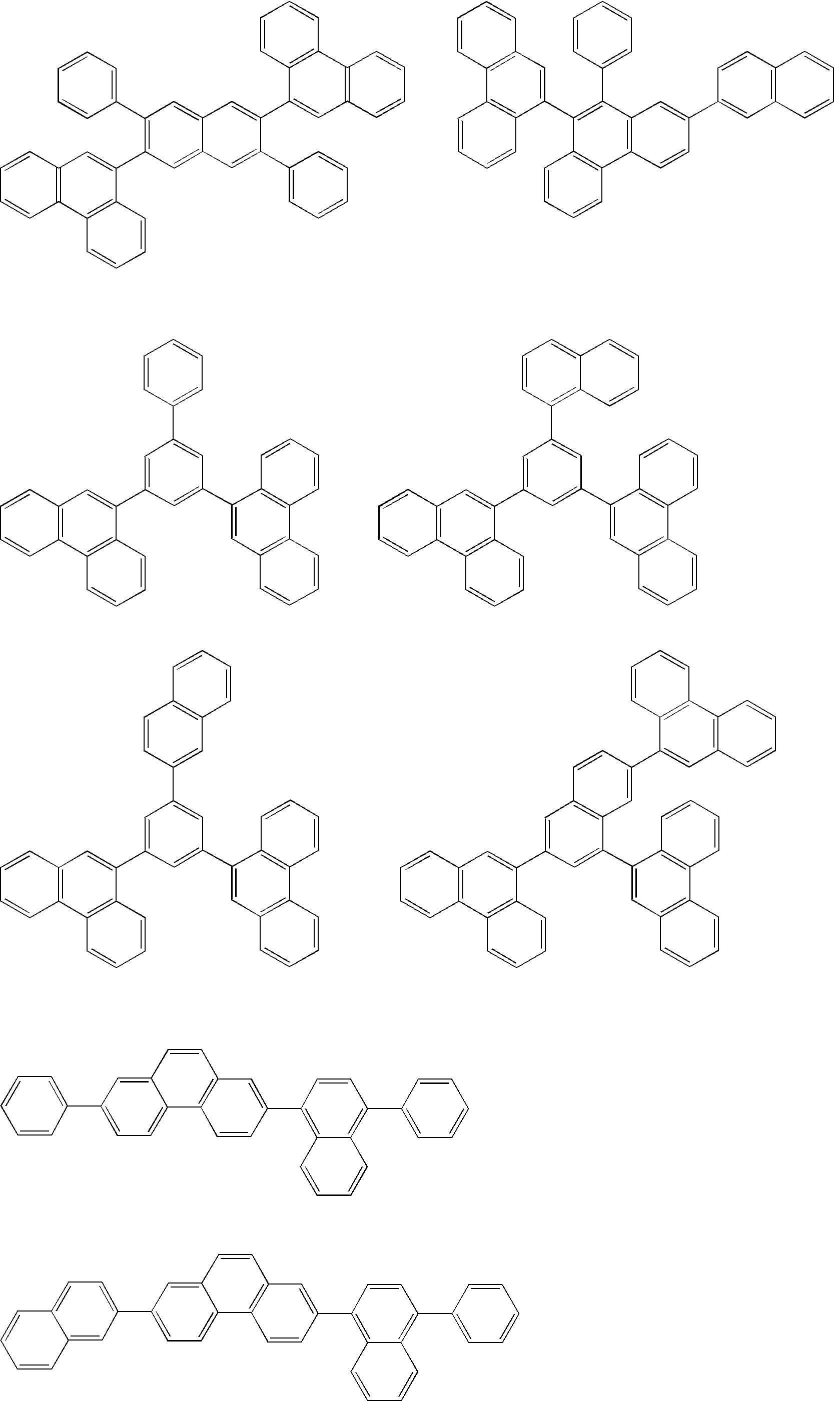

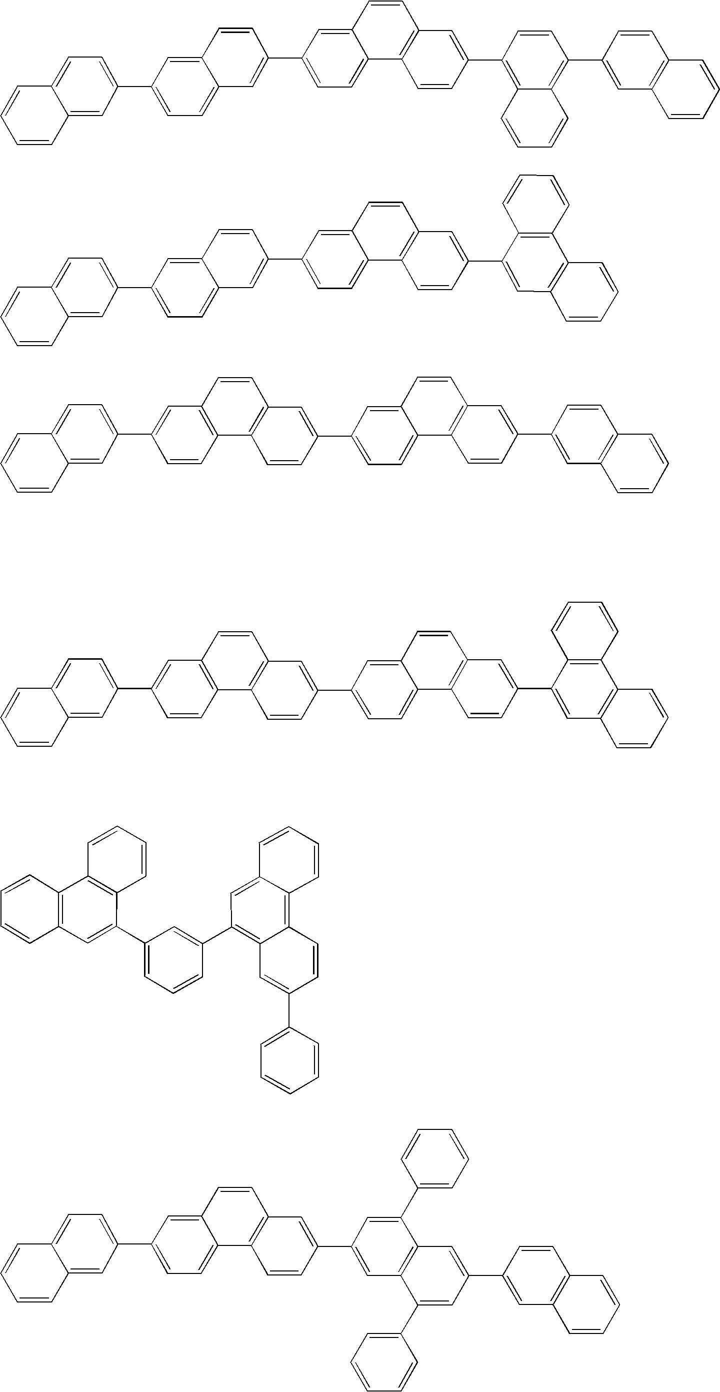

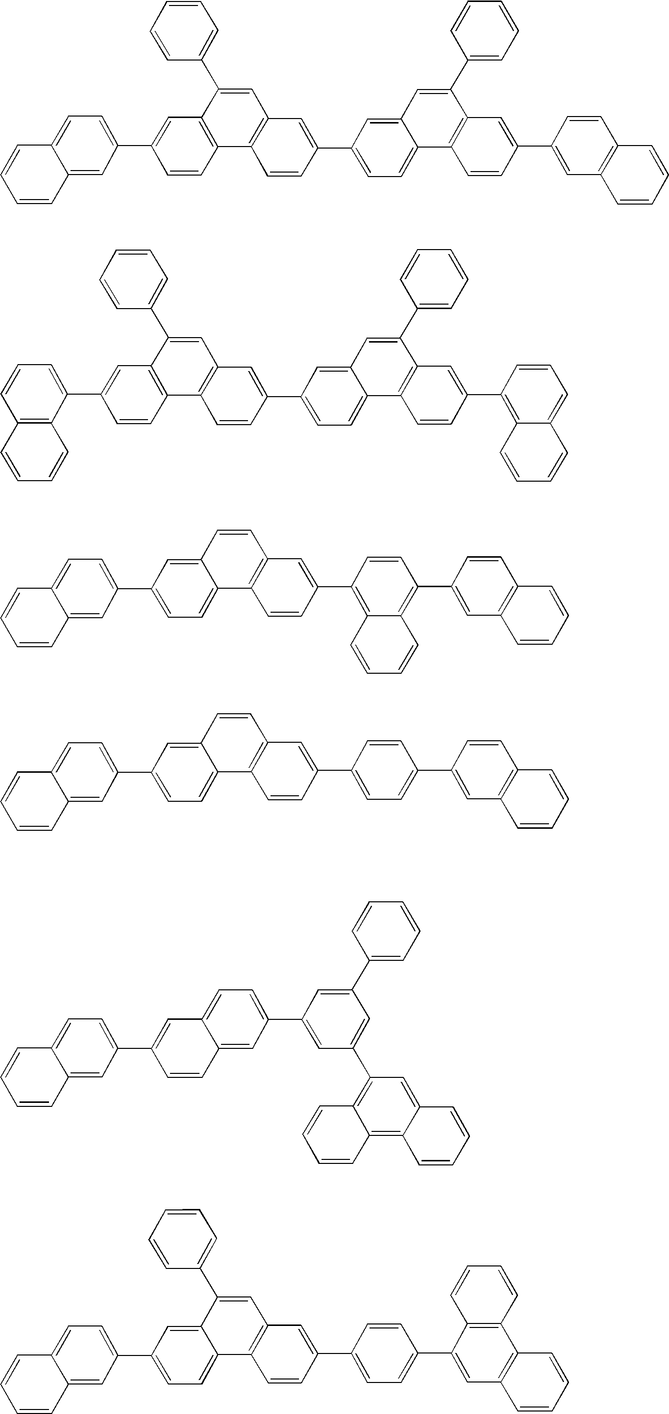

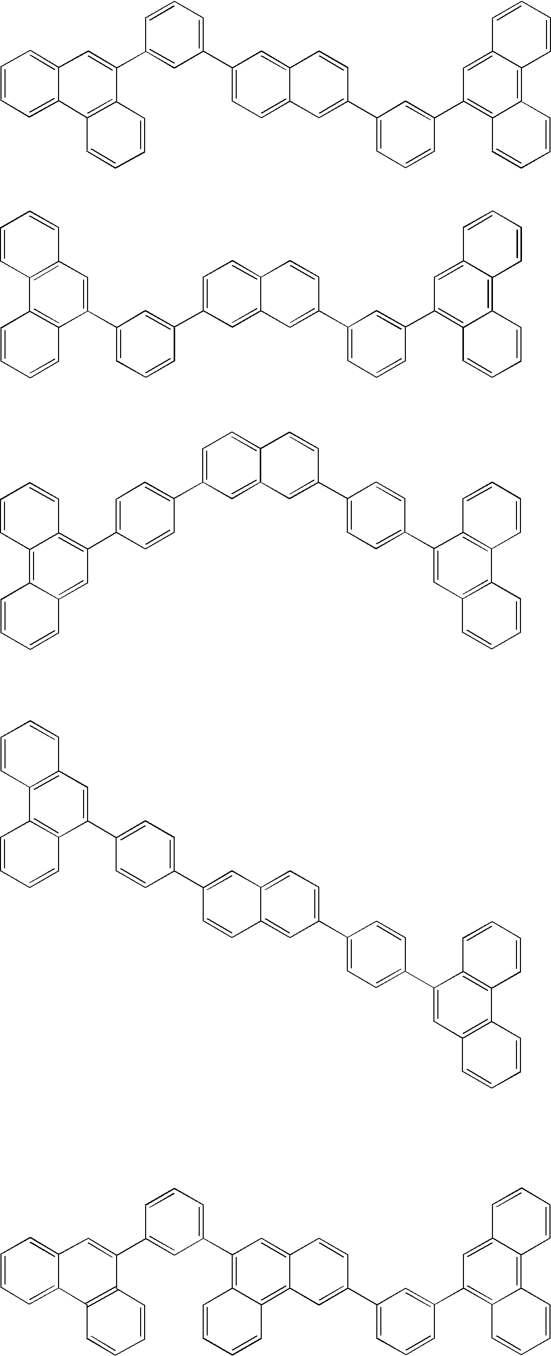

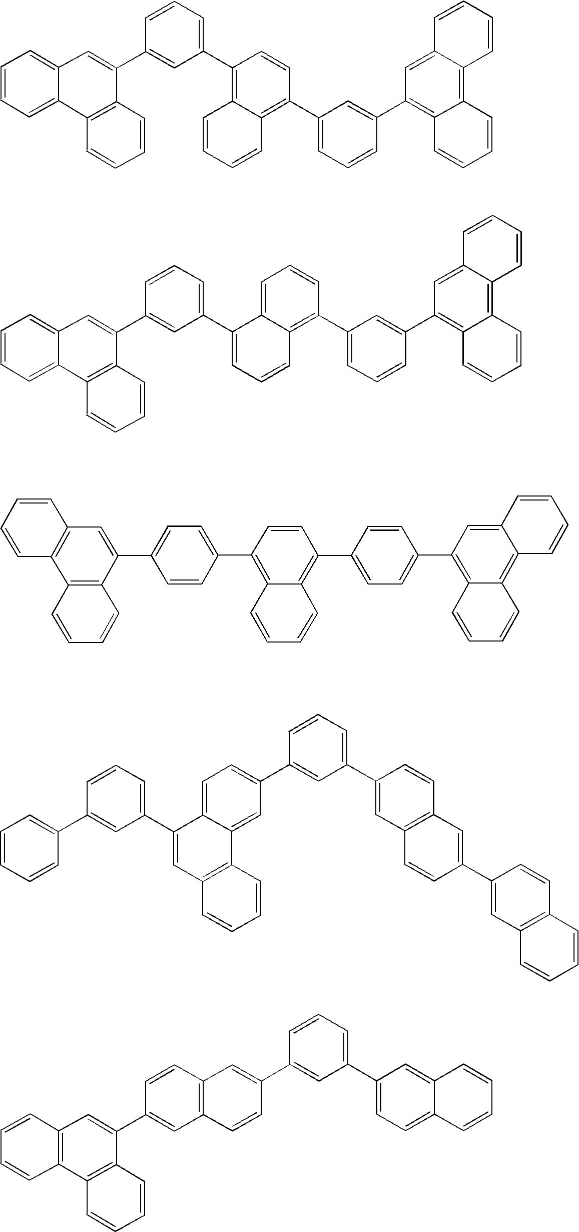

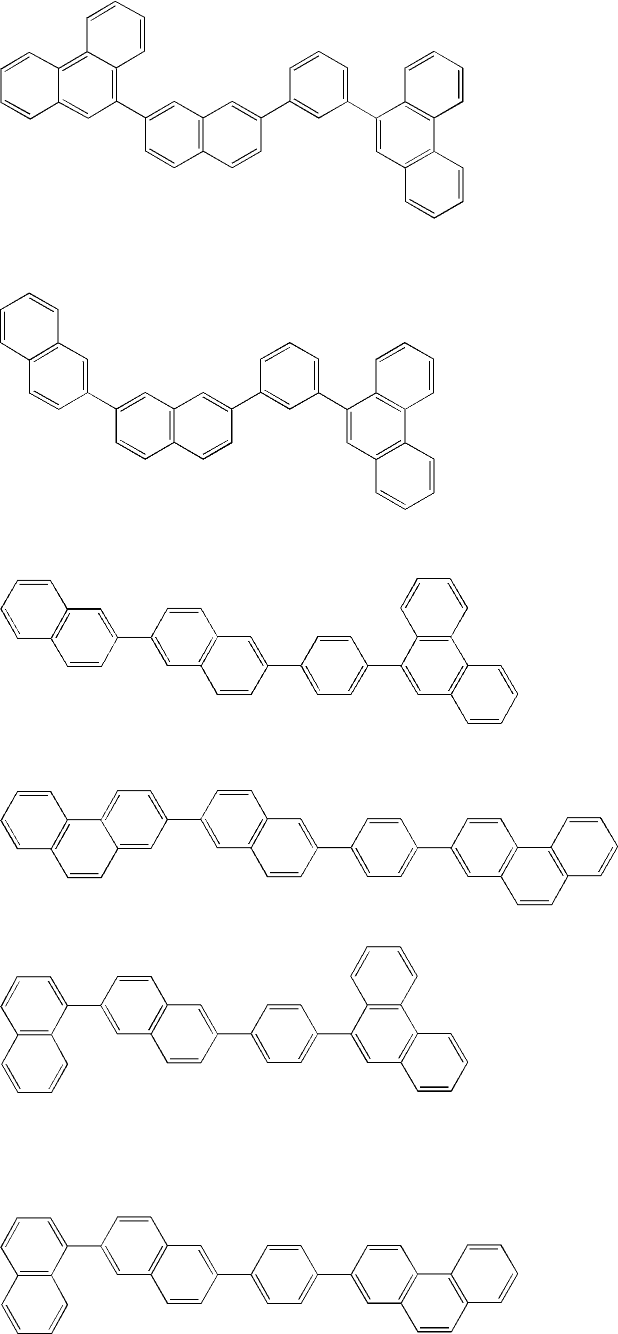

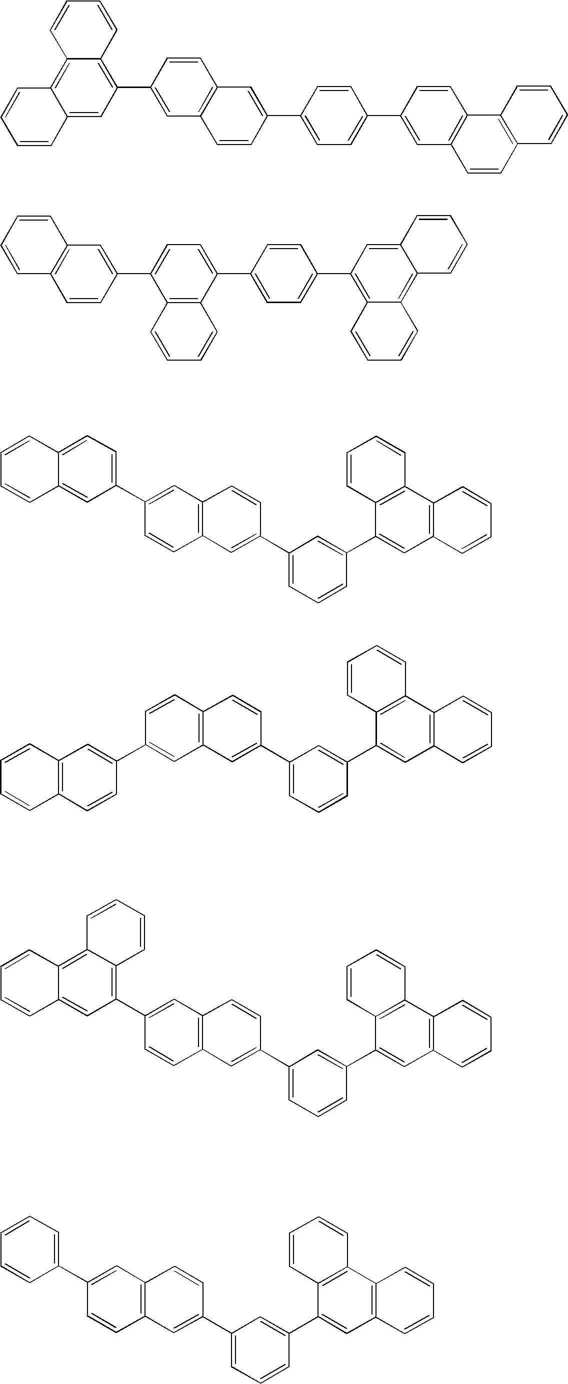

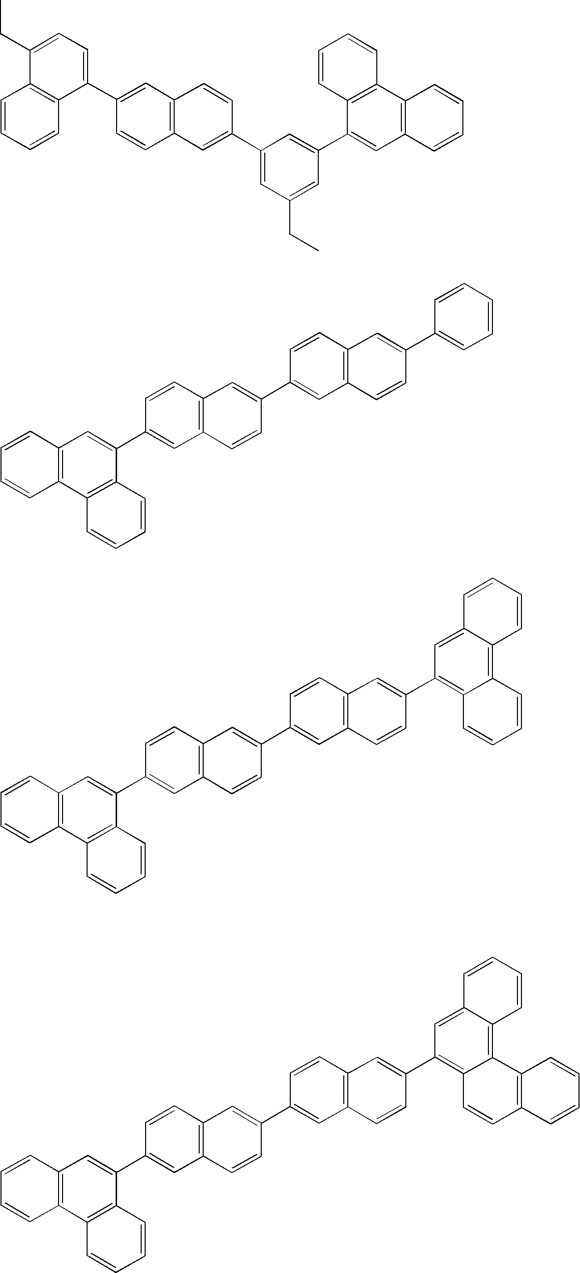

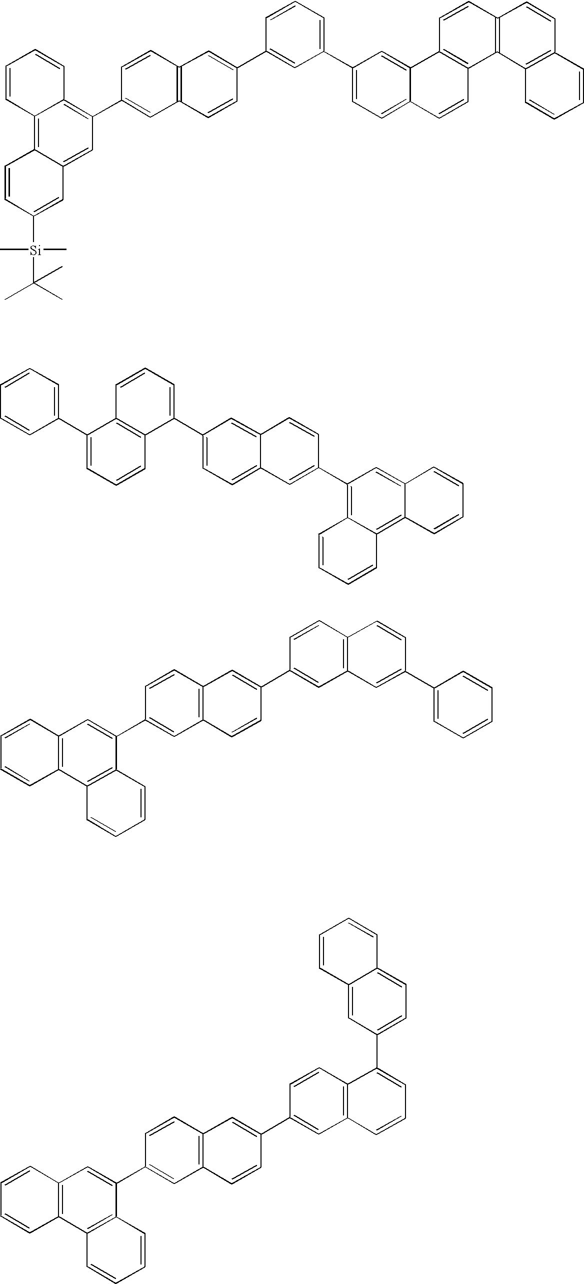

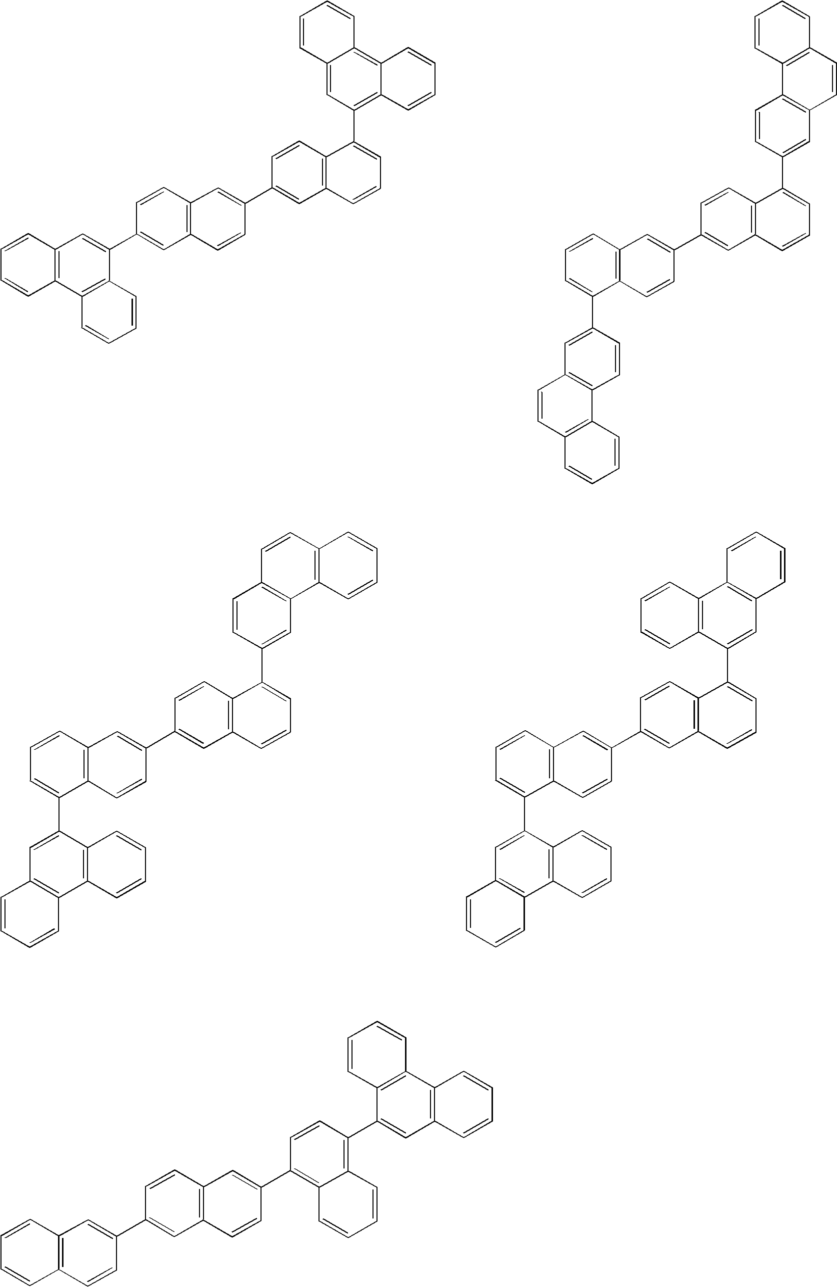

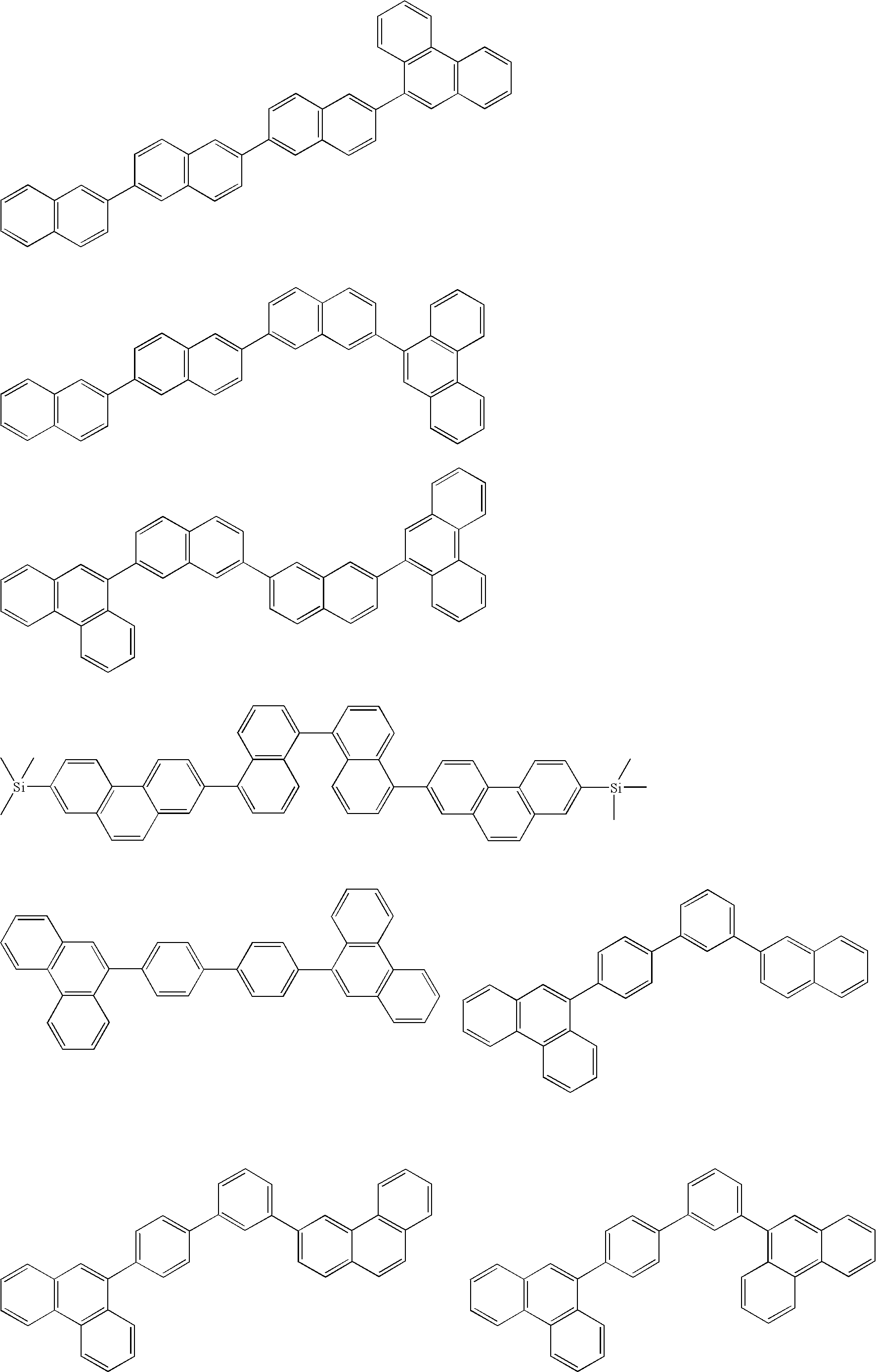

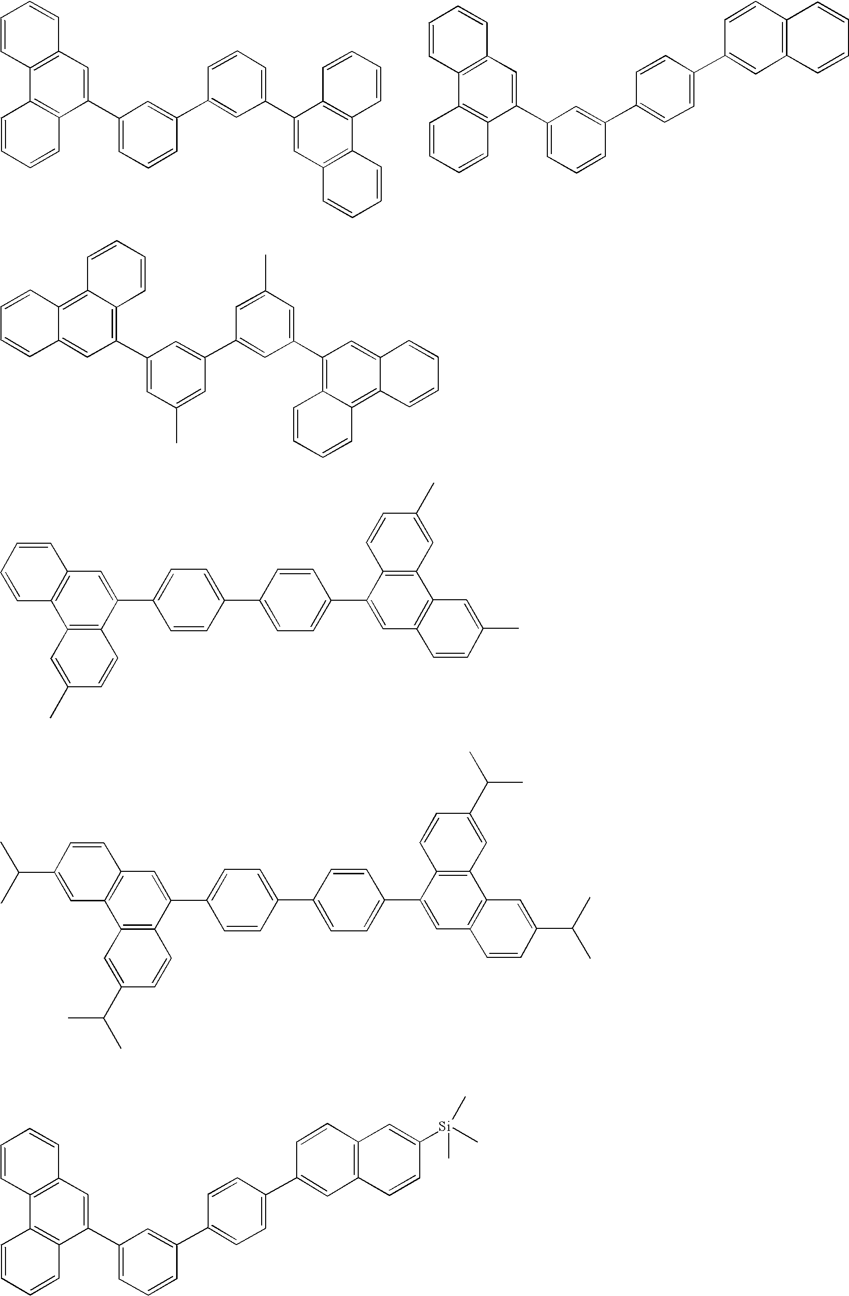

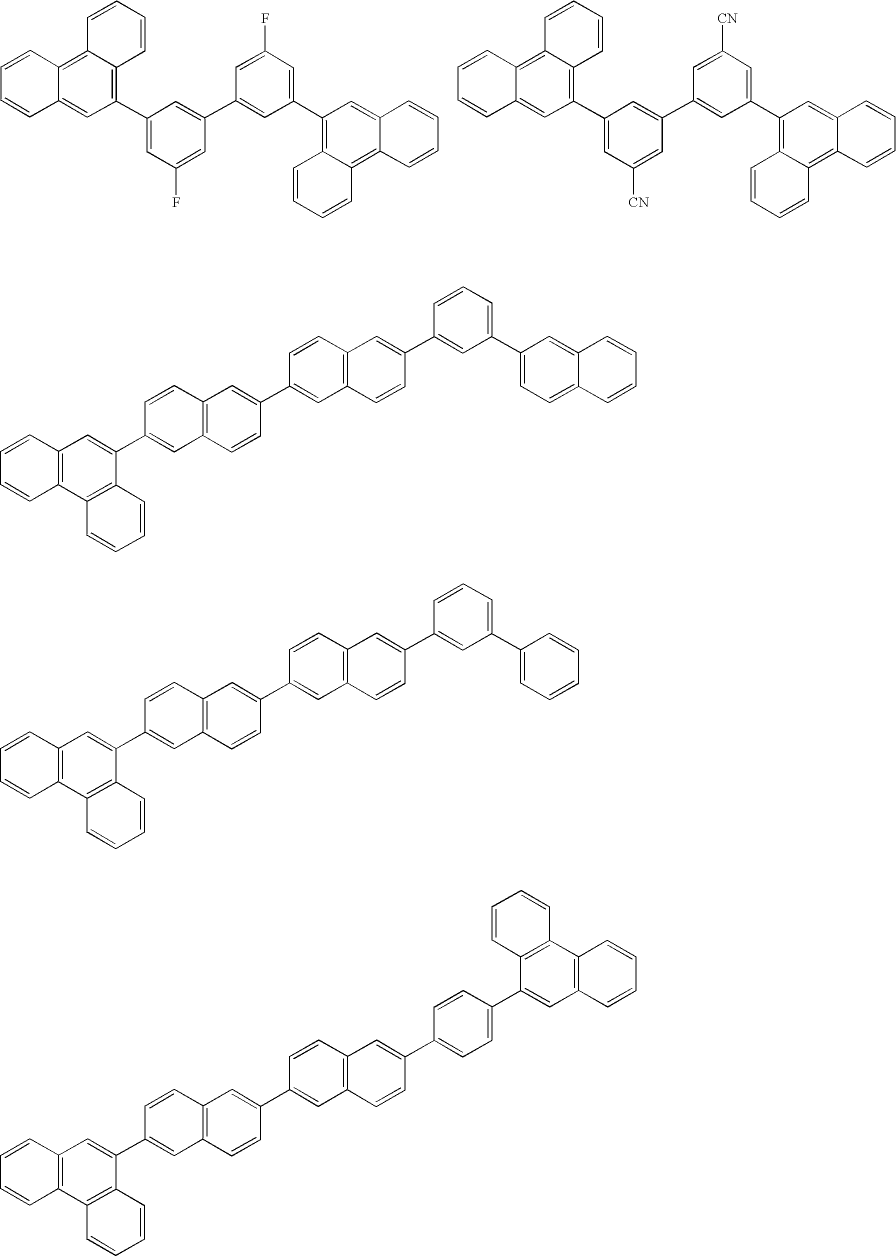

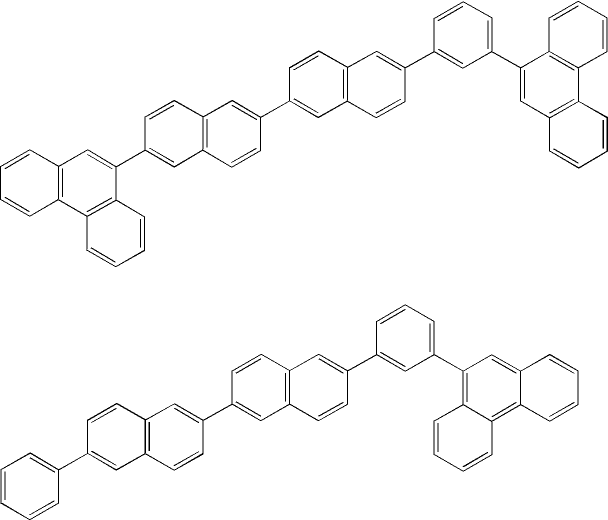

In the aspect of the invention, the polycyclic fused aromatic skeleton is preferably the elementary substance of chrysene represented by the following formula (6) or its derivative.

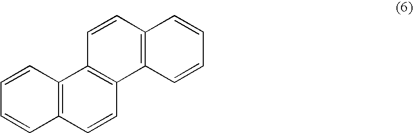

The chrysene derivative is exemplarily represented by the following formula (6A).

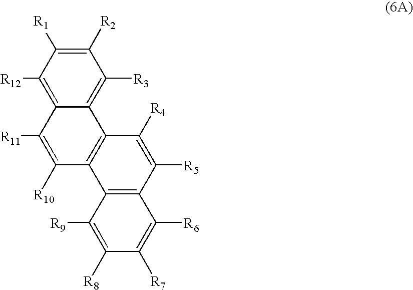

In the formula (6A), R₁ to R₁₂ each independently represent a hydrogen atom or a substituent formed by one group or a combination of two or more groups selected from a substituted or unsubstituted aryl group having 5 to 30 ring-forming carbon atoms (excluding the number of carbon atoms in the substituent), a branched or linear alkyl group having 1 to 30 carbon atoms and a substituted or unsubstituted cycloalkyl group having 3 to 20 carbon atoms.

Examples of the chrysene derivative represented by the formula (6) are as follows.

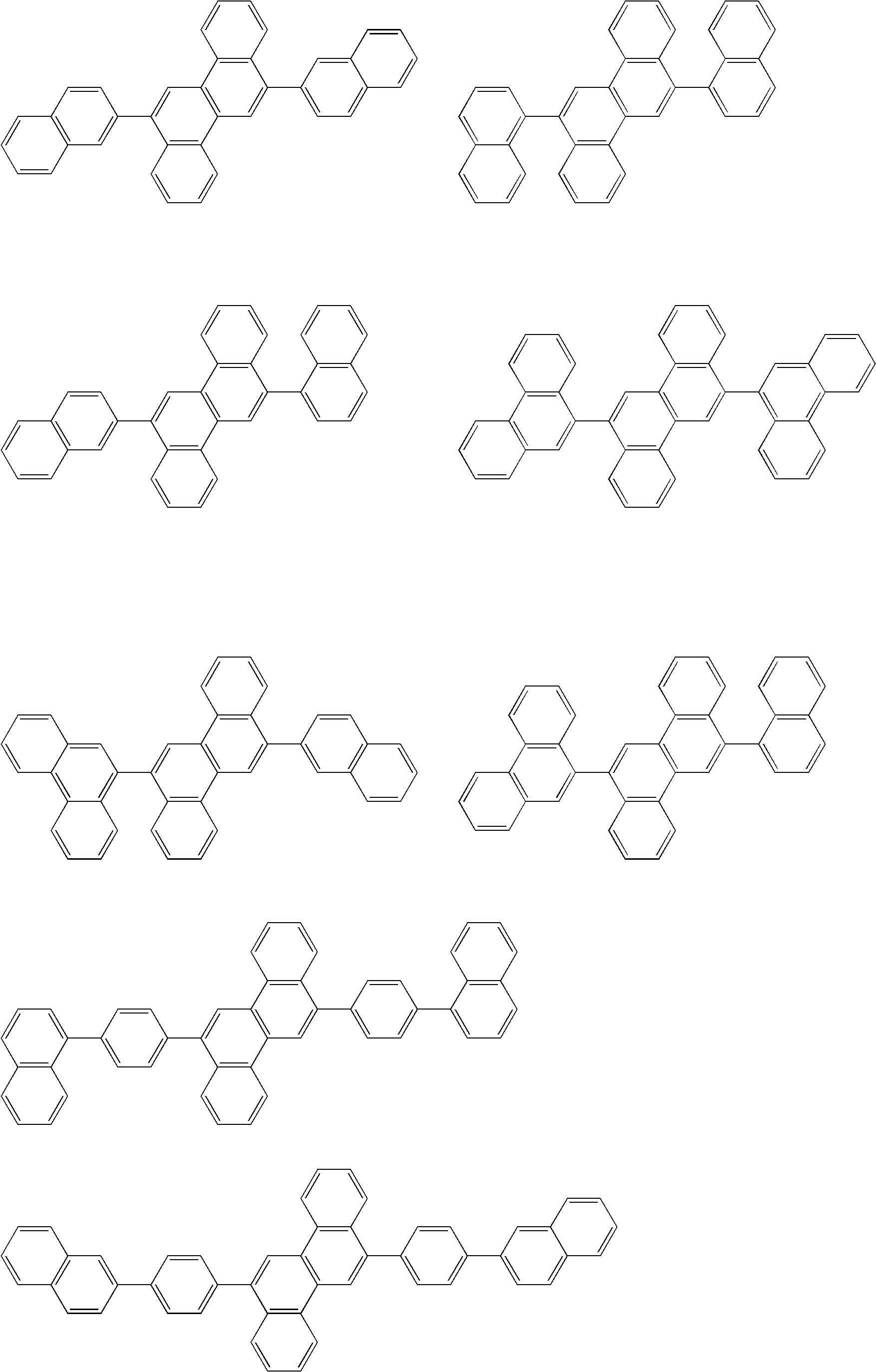

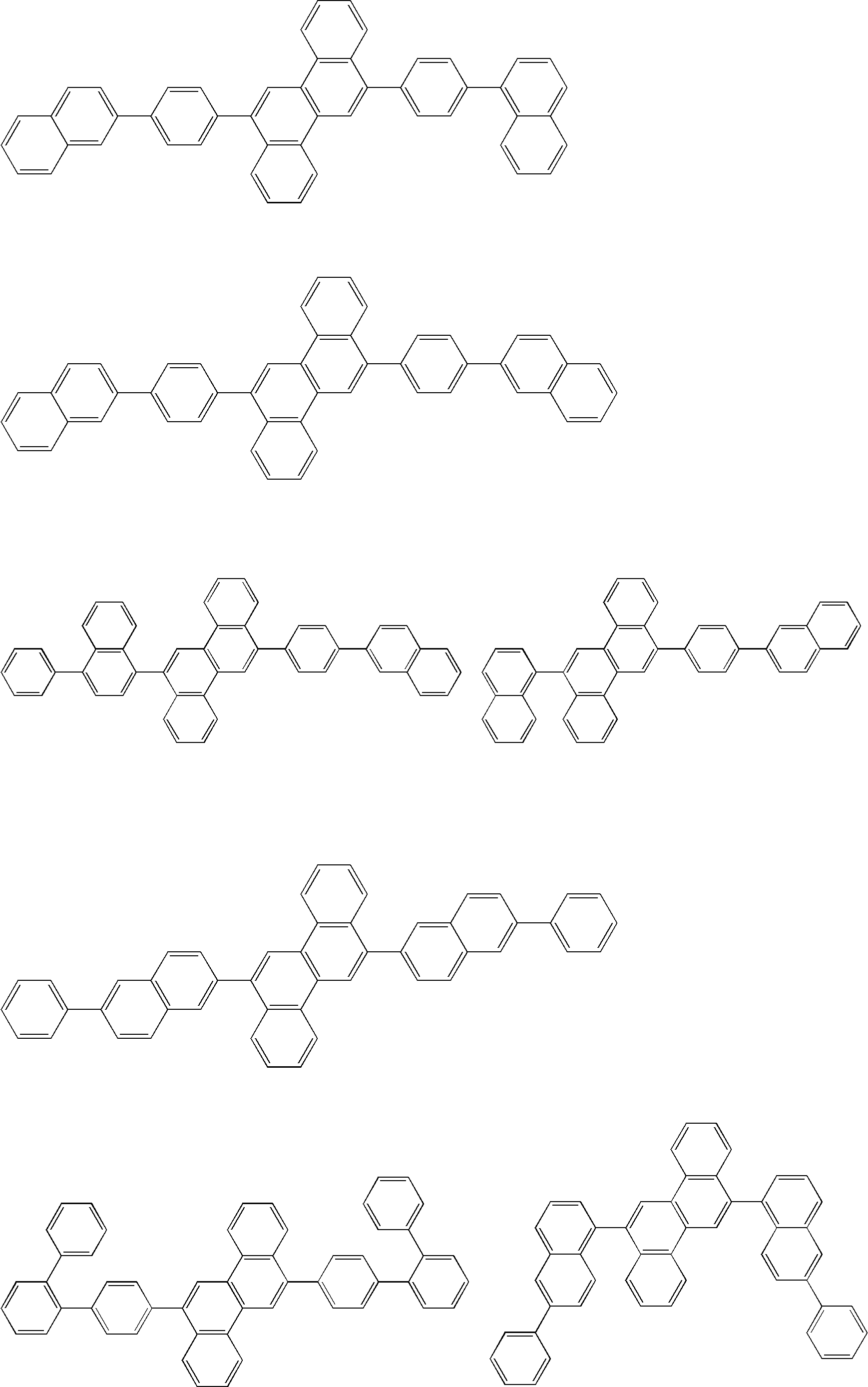

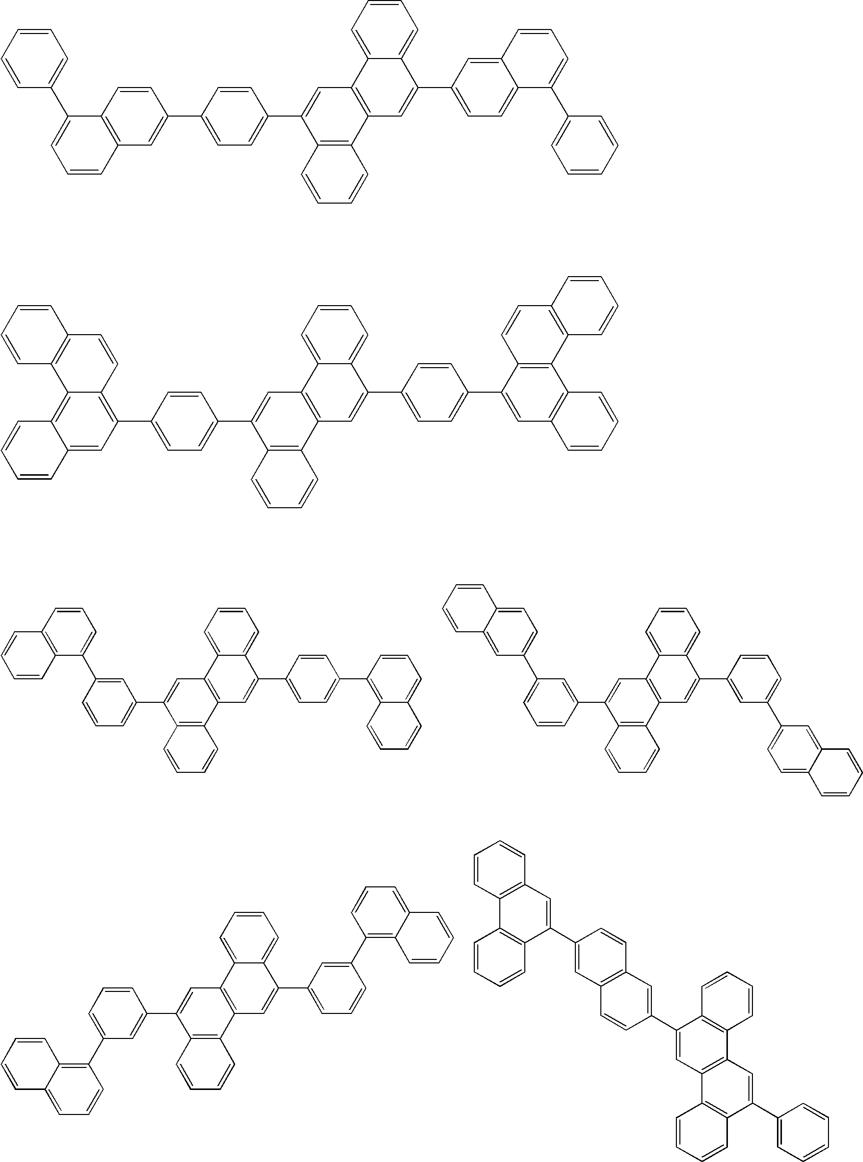

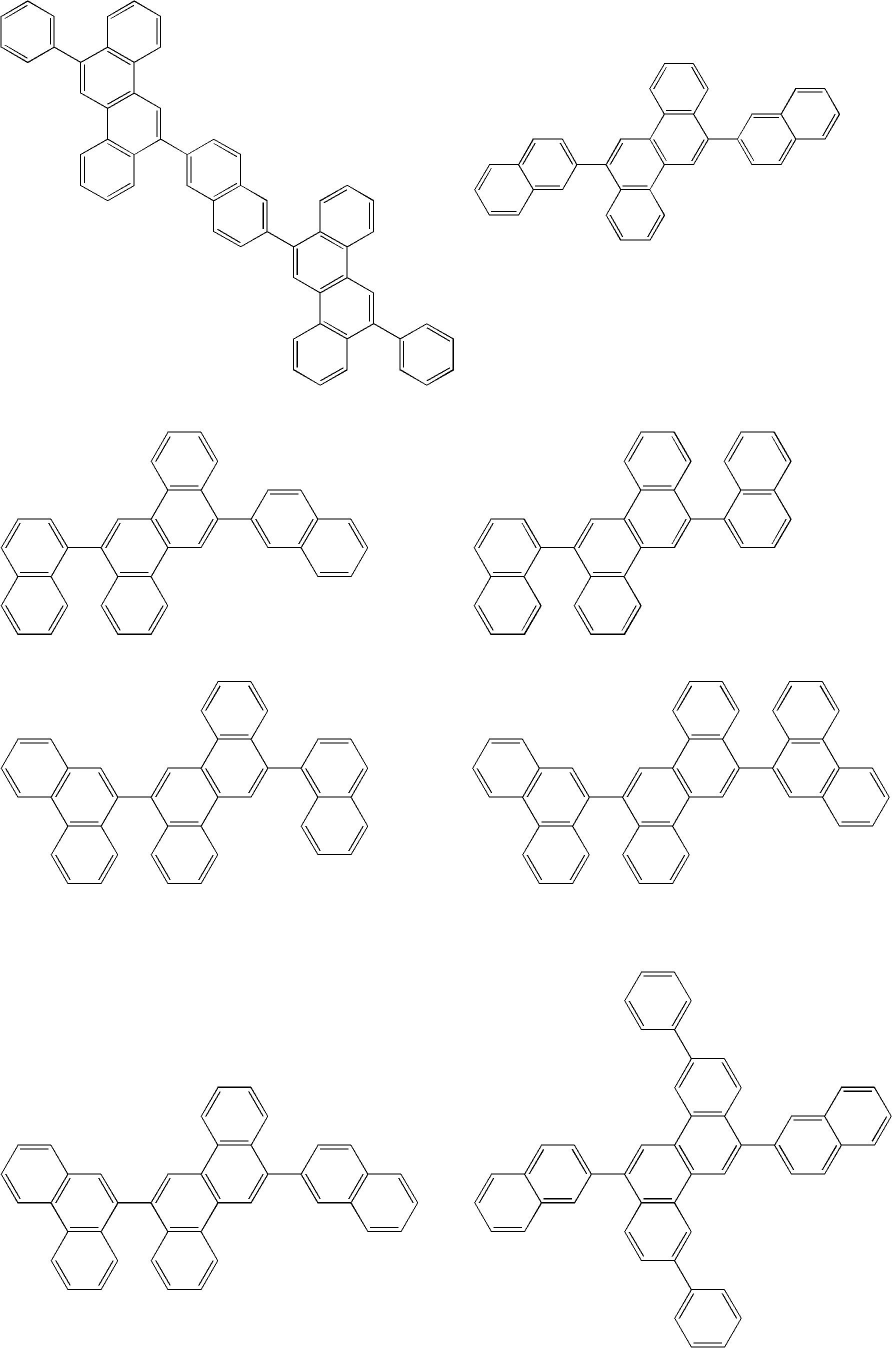

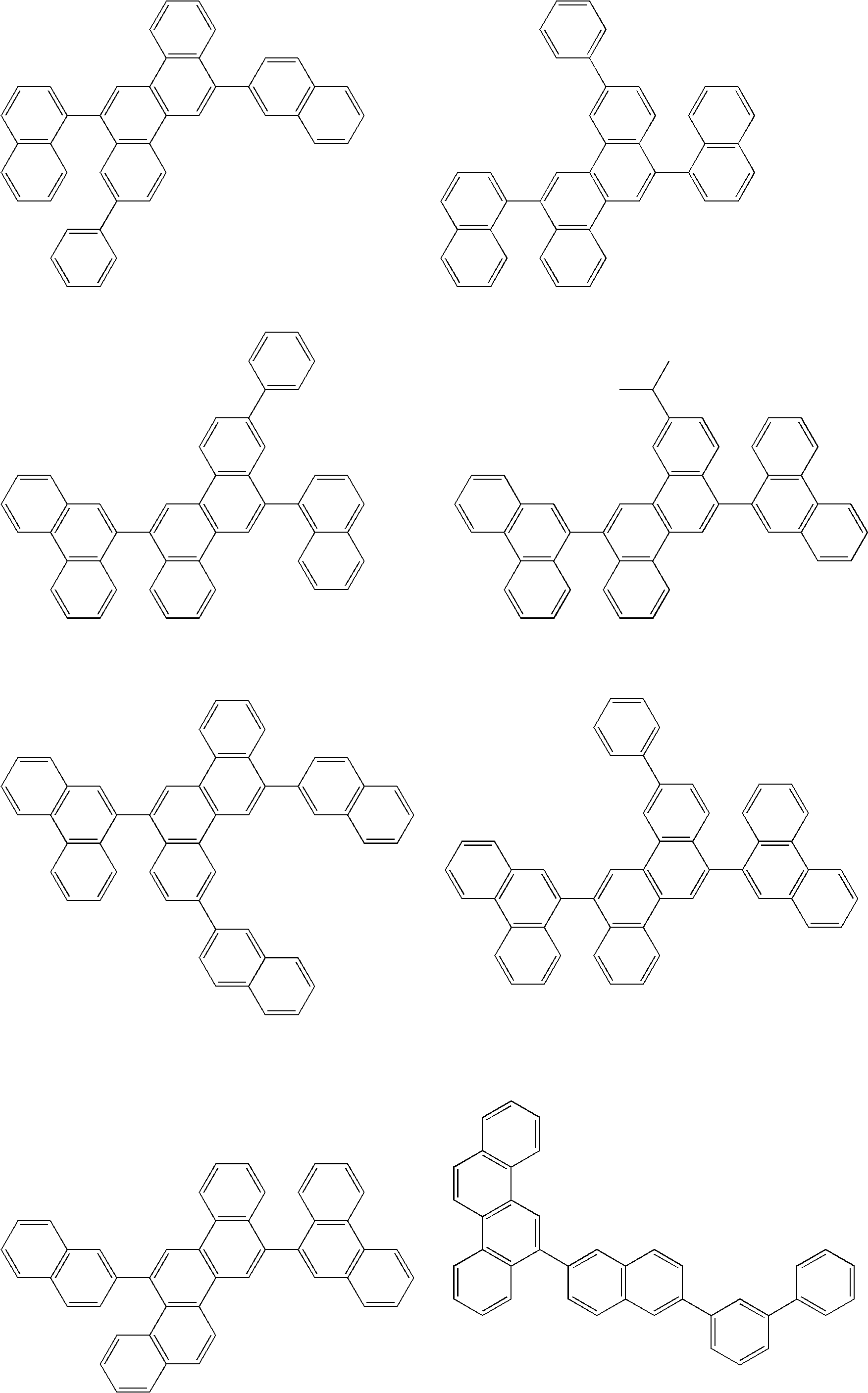

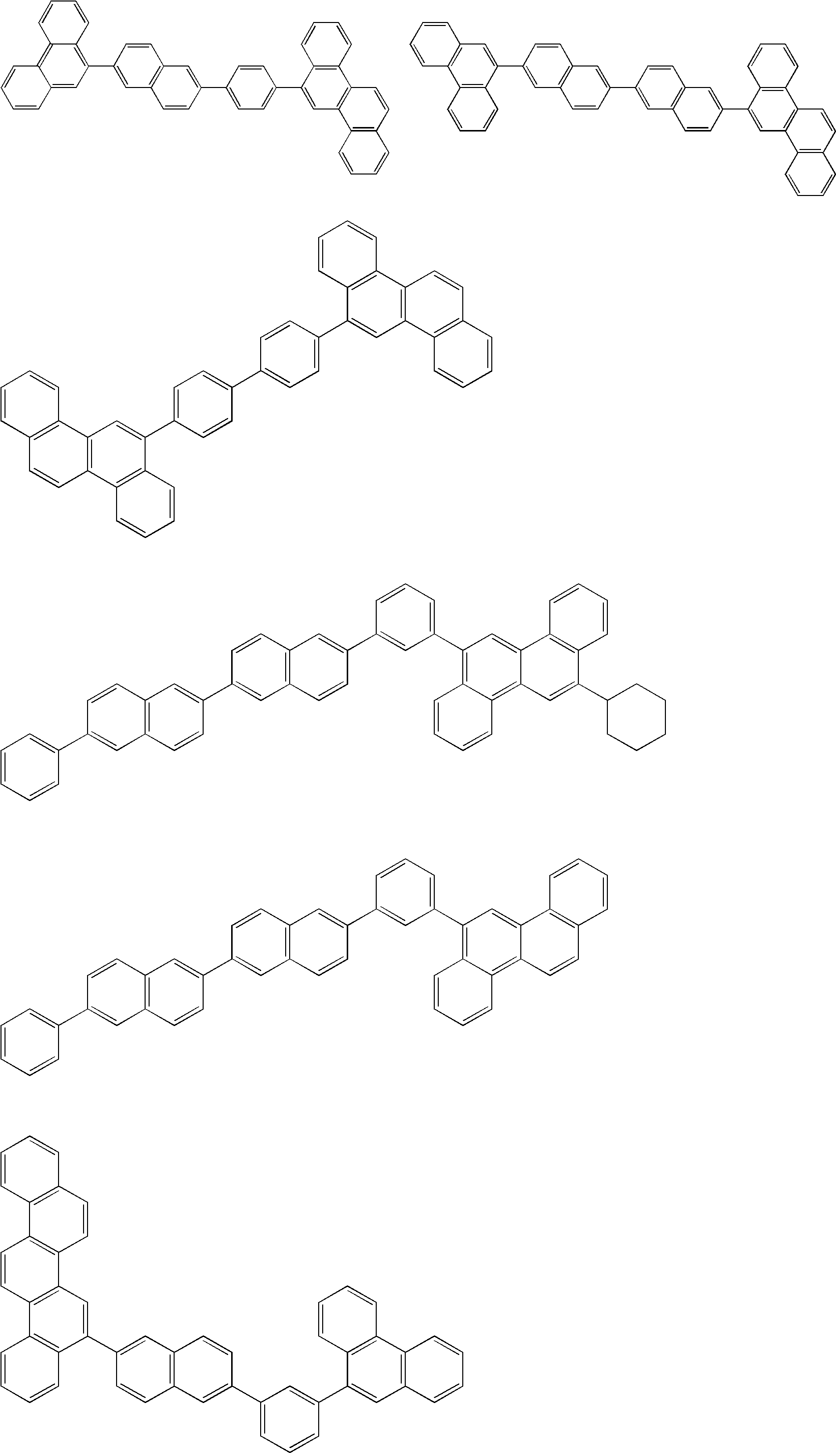

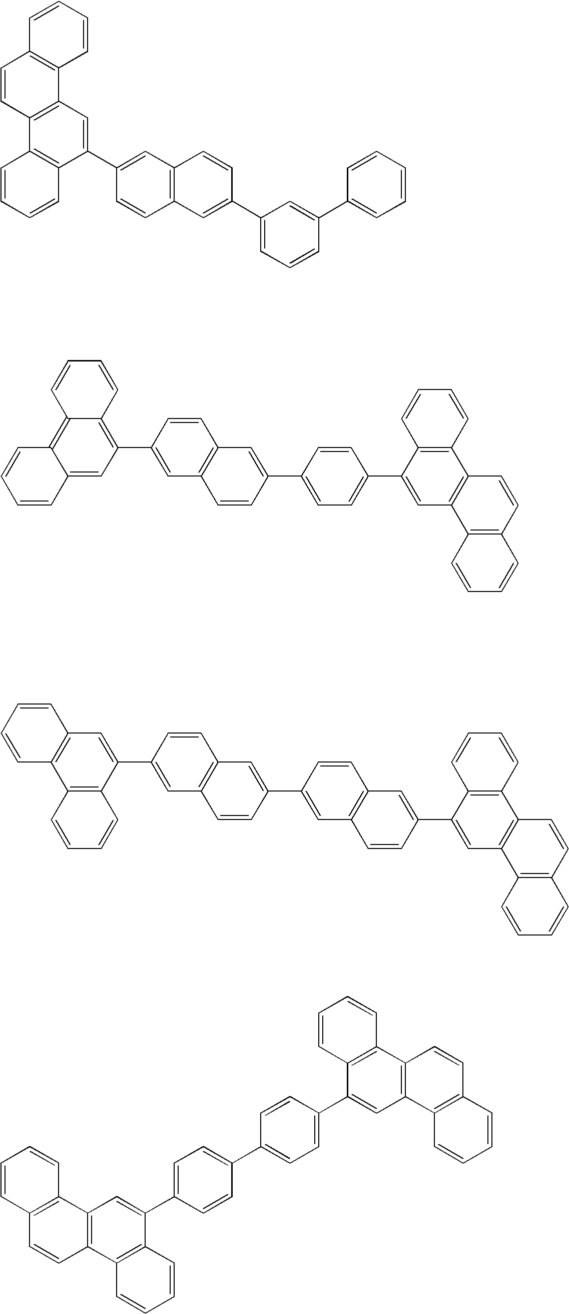

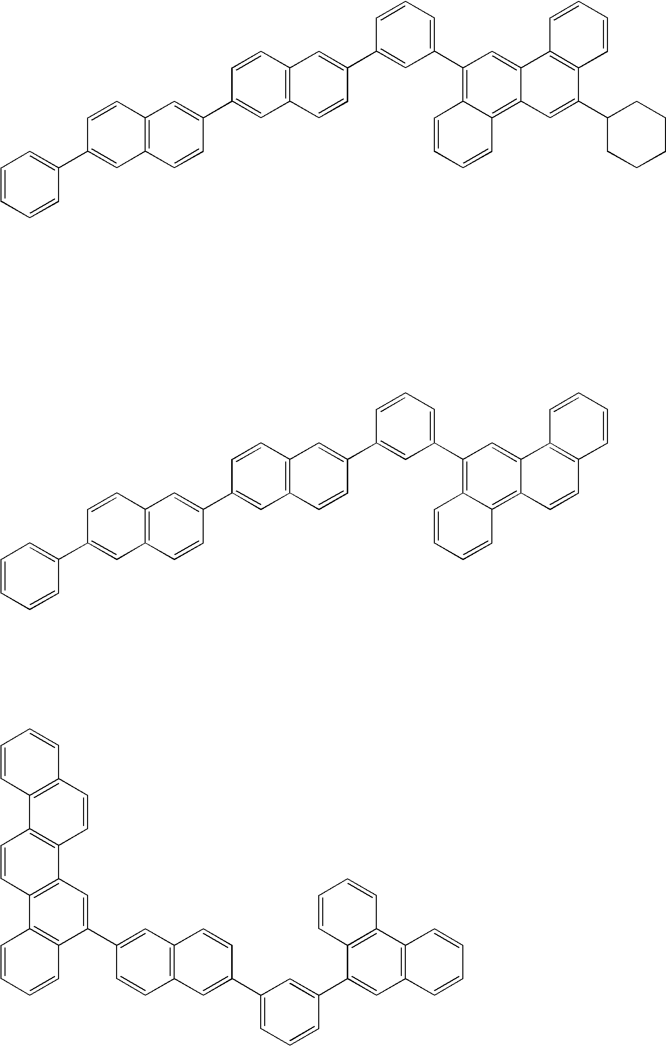

In the aspect of the invention, the polycyclic fused aromatic skeleton is preferably the elementary substance of a compound represented by the following formula (7) (benzo[c]phenanthrene) or its derivative.

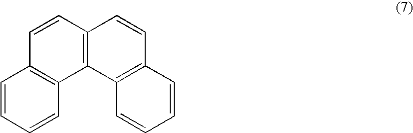

The benzo[c]phenanthrene derivative is exemplarily represented by the following formula (7A).

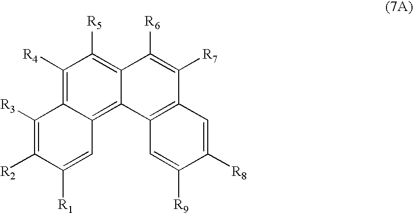

In the formula (7A), R₁ to R₉ each independently represent a hydrogen atom or a substituent formed by one group or a combination of two or more groups selected from a substituted or unsubstituted aryl group having 5 to 30 ring-forming carbon atoms (excluding the number of carbon atoms in the substituent), a branched or linear alkyl group having 1 to 30 carbon atoms and a substituted or unsubstituted cycloalkyl group having 3 to 20 carbon atoms.

Examples of the benzo[c]phenanthrene derivative represented by the formula (7) are as follows.

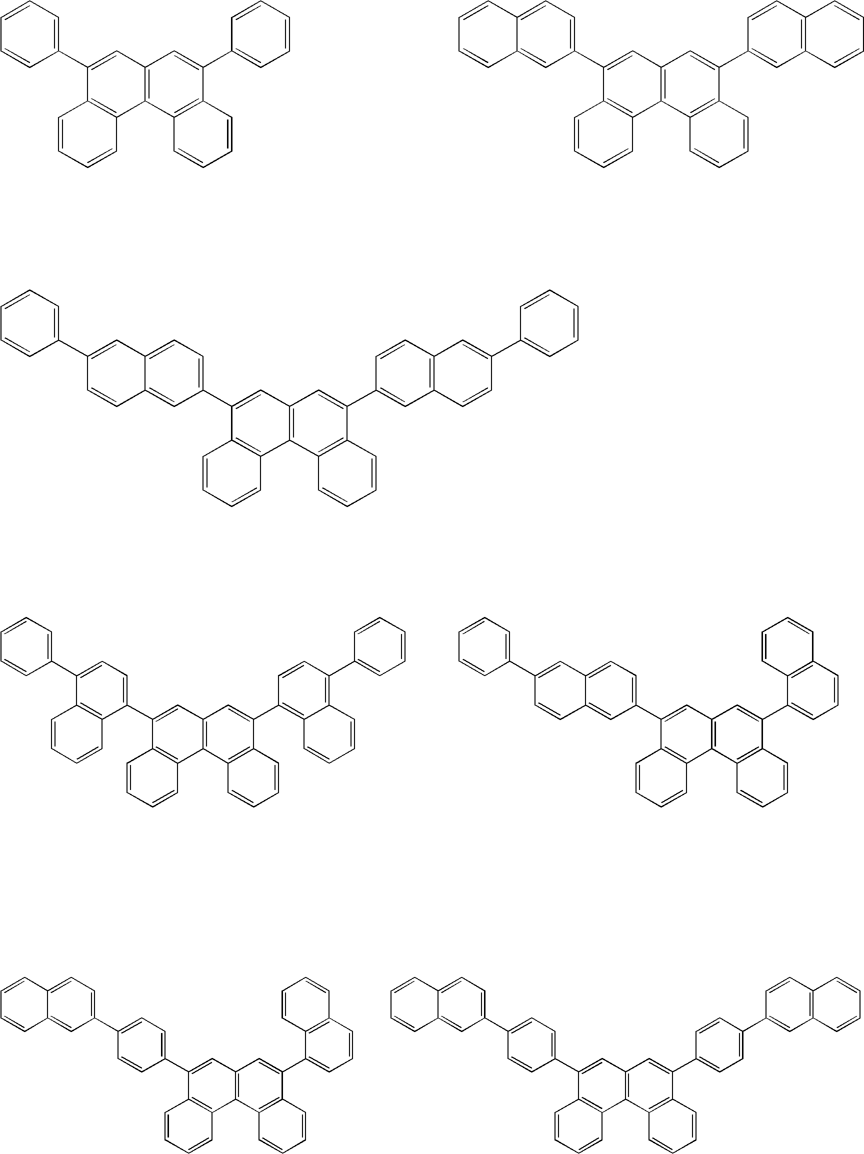

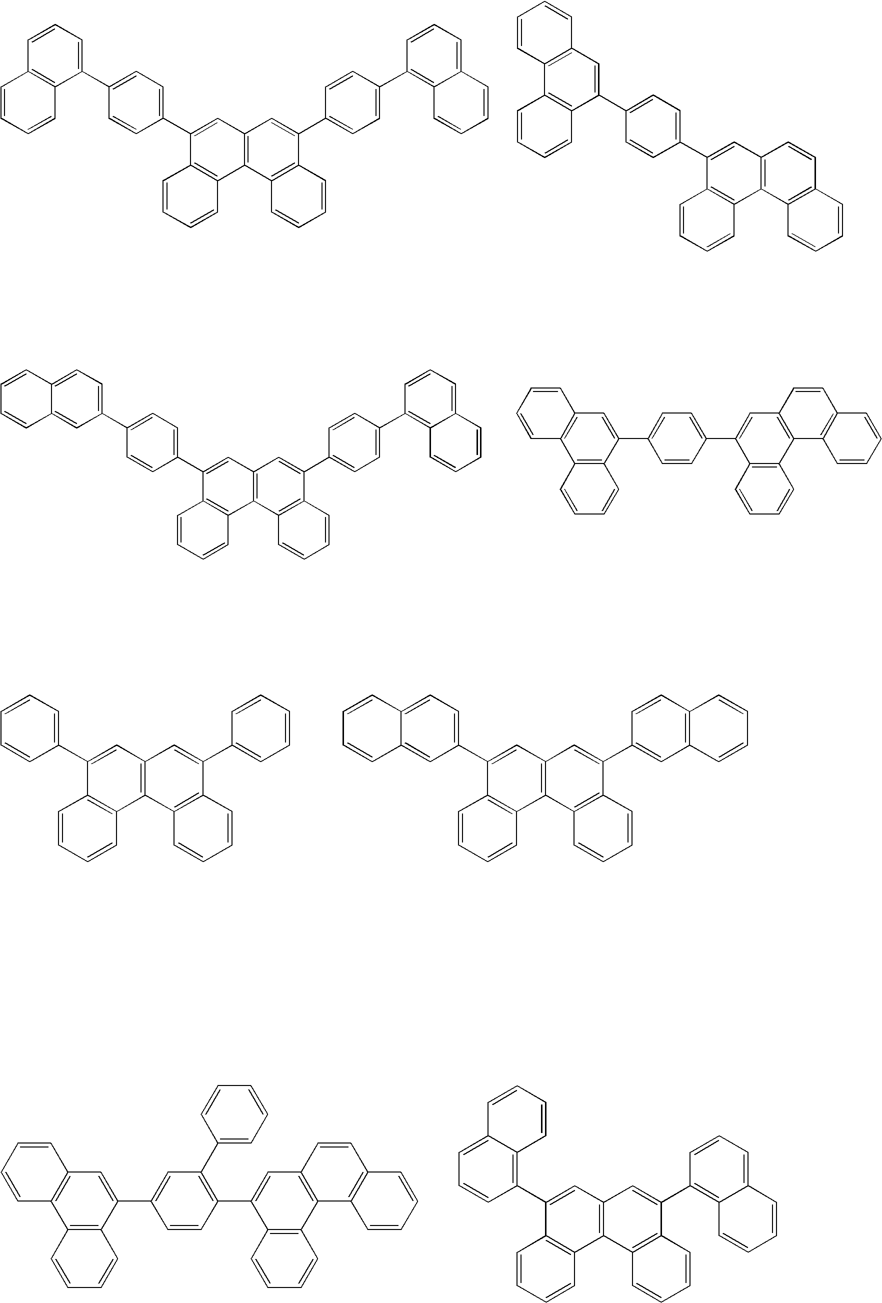

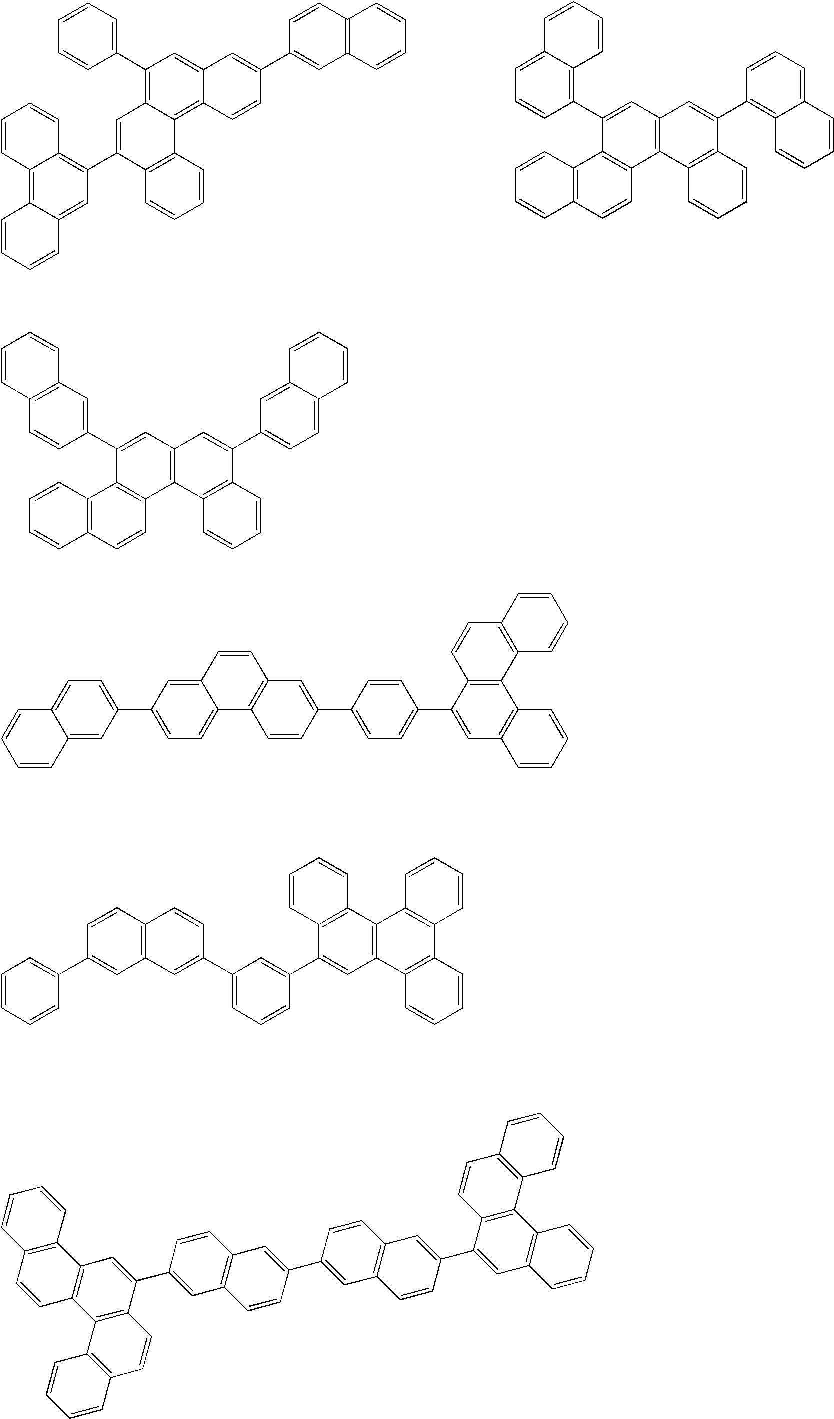

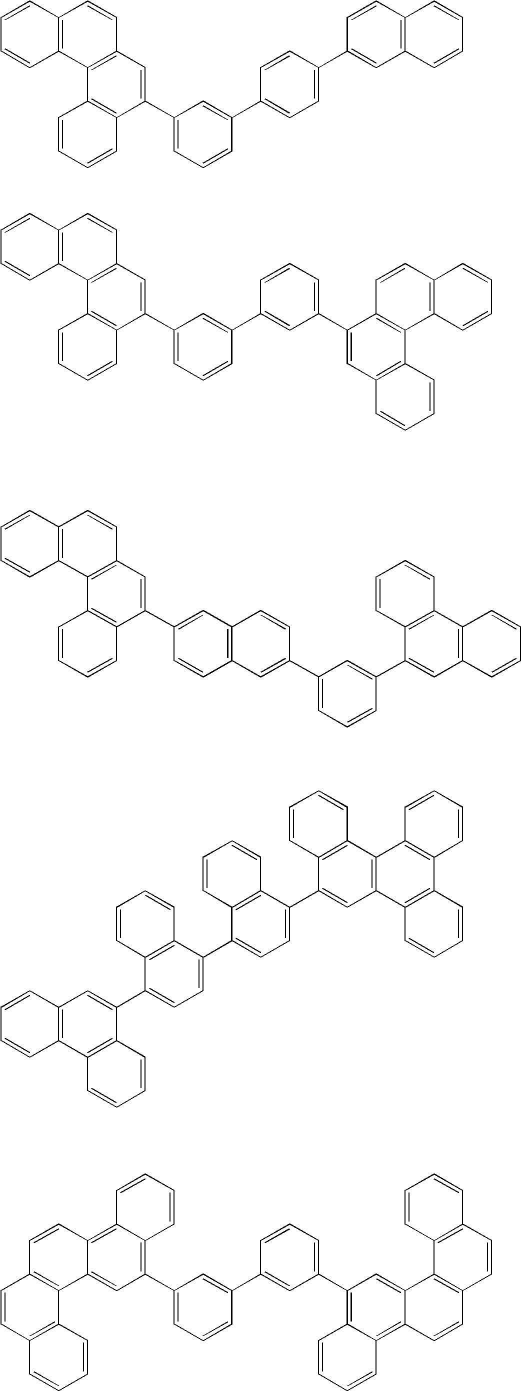

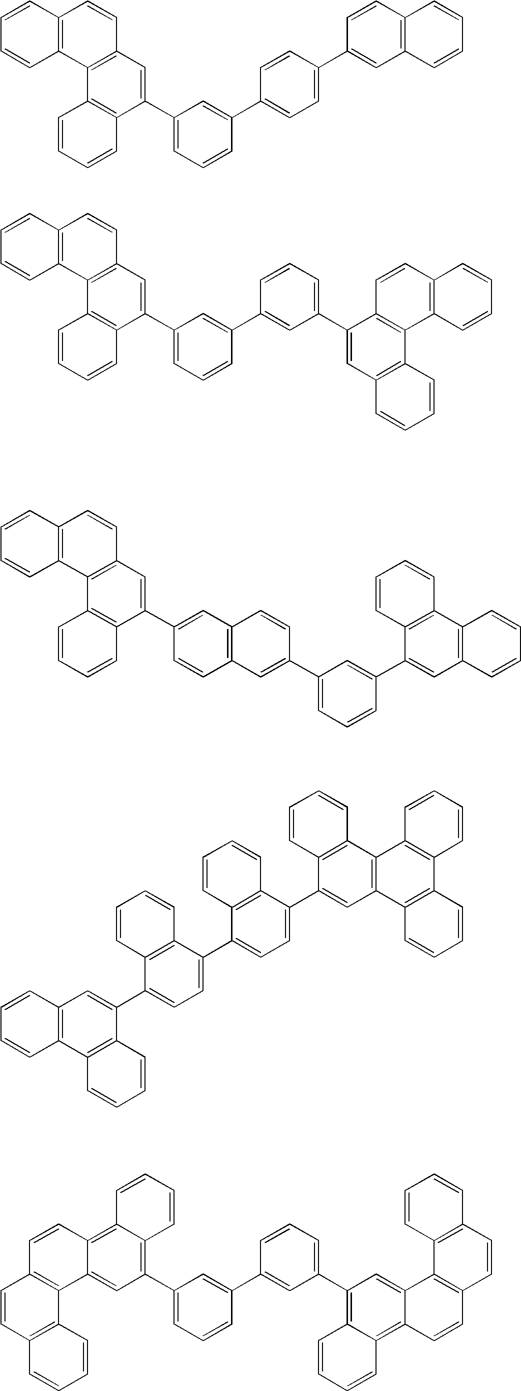

In the aspect of the invention, the polycyclic fused aromatic skeleton is preferably the elementary substance of a compound represented by the following formula (8) (benzo[c]chrysene) or its derivative.

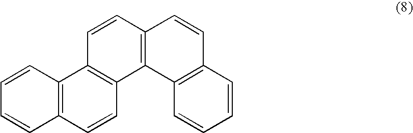

The benzo[c]chrysene derivative is exemplarily represented by the following formula (8A).

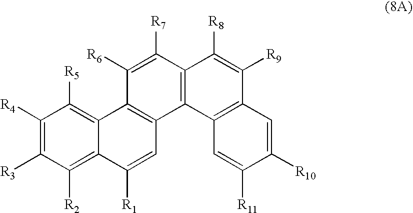

In the formula (8A), R₁ to R₁₁ each independently represent a hydrogen atom or a substituent formed by one group or a combination of two or more groups selected from a substituted or unsubstituted aryl group having 5 to 30 ring-forming carbon atoms (excluding the number of carbon atoms in the substituent), a branched or linear alkyl group having 1 to 30 carbon atoms and a substituted or unsubstituted cycloalkyl group having 3 to 20 carbon atoms.

Examples of the benzo[c]chrysene derivative represented by the formula (8) are as follows.

Examples of the derivative of such a compound are as follows.

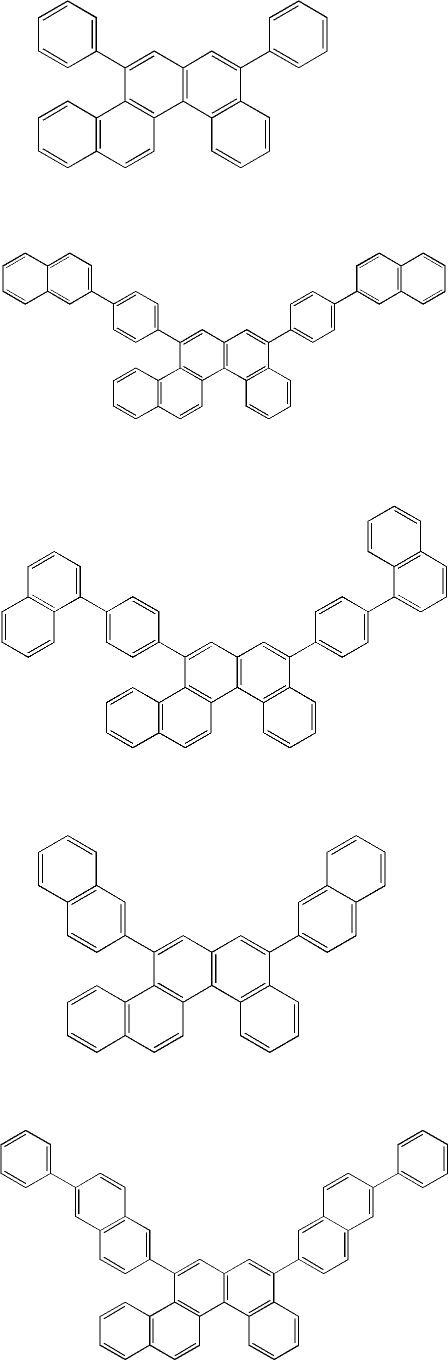

In the aspect of the invention, the polycyclic fused aromatic skeleton is preferably the elementary substance of a compound represented by the following formula (9) (benzo[c,g]phenanthrene) or its derivative.

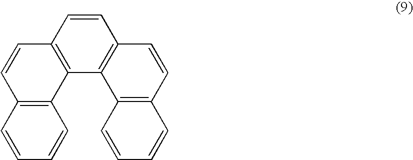

Examples of the derivative of such a compound are as follows.

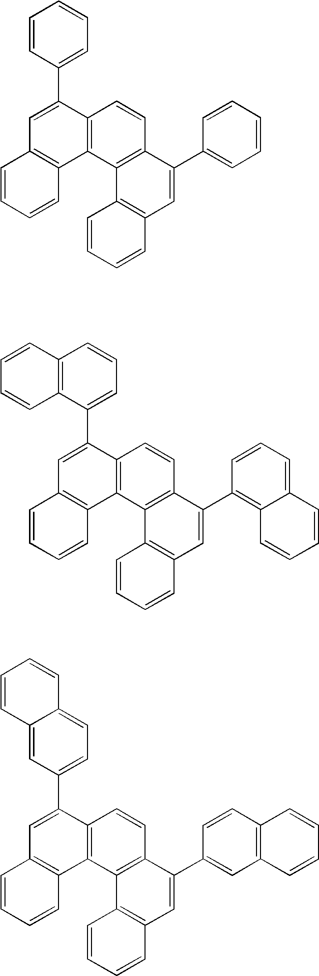

In the aspect of the invention, the polycyclic fused aromatic skeleton is preferably the elementary substance of fluoranthene represented by the following formula (10) or its derivative.

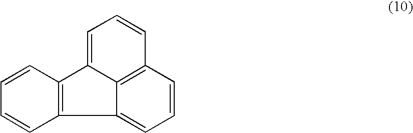

The fluoranthene derivative is exemplarily represented by the following formula (10A).

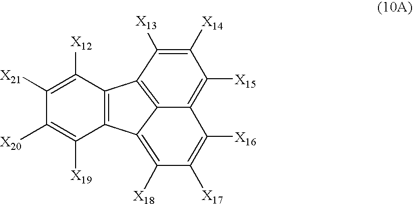

In the formula (10A), X₁₂ to X₂₁ each represent a hydrogen atom, a halogen atom, a linear, branched or cyclic alkyl group, a linear, branched or cyclic alkoxy group, or a substituted or unsubstituted aryl group.

The aryl group represents a carbocyclic aromatic group such as a phenyl group and a naphthyl group, or a heterocyclic aromatic group such as a furyl group, a thienyl group and a pyridyl group.

X₁₂ to X₂₁ each preferably represent hydrogen atom, halogen atom (such as fluorine atom, chlorine atom, or bromine atom), linear, branched or cyclic alkyl group having 1 to 16 carbon atoms (such as methyl group, ethyl group, n-propyl group, isopropyl group, n-butyl group, isobutyl group, sec-butyl group, tert-butyl group, n-pentyl group, isopentyl group, neopentyl group, tert-pentyl group, cyclopentyl group, n-hexyl group, 3,3-dimethylbutyl group, cyclohexyl group, n-heptyl group, cyclohexylmethyl group, n-octyl group, tert-octyl group, 2-ethylhexyl group, n-nonyl group, n-decyl group, n-dodecyl group, n-tetradecyl group, or n-hexadecyl group), linear, branched or cyclic alkoxy group having 1 to 16 carbon atoms (such as methoxy group, ethoxy group, n-propoxy group, isopropoxy group, n-butoxy group, isobutoxy group, sec-butoxy group, n-pentyloxy group, neopentyloxy group, cyclopentyloxy group, n-hexyloxy group, 3,3-dimethylbutyloxy group, cyclohexyloxy group, n-heptyloxy group, n-octyloxy group, 2-ethylhexyloxy group, n-nonyloxy group, n-decyloxy group, n-dodecyloxy group, n-tetradecyloxy group, or n-hexadecyloxy group), or substituted or unsubstituted aryl group having 4 to 16 carbon atoms (such as phenyl group, 2-methylphenyl group, 3-methylphenyl group, 4-methylphenyl group, 4-ethylphenyl group, 4-n-propylphenyl group, 4-isopropylphenyl group, 4-n-butylphenyl group, 4-tert-butylphenyl group, 4-isopentylphenyl group, 4-tert-pentylphenyl group, 4-n-hexylphenyl group, 4-cyclohexylphenyl group, 4-n-octylphenyl group, 4-n-decylphenyl group, 2,3-dimethylphenyl group, 2,4-dimethylphenyl group, 2,5-dimethylphenyl group, 3,4-dimethylphenyl group, 5-indanyl group, 1,2,3,4-tetrahydro-5-naphthyl group, 1,2,3,4-tetrahydro-6-naphthyl group, 2-methoxyphenyl group, 3-methoxyphenyl group, 4-methoxyphenyl group, 3-ethoxyphenyl group, 4-ethoxyphenyl group, 4-n-propoxyphenyl group, 4-isopropoxyphenyl group, 4-n-butoxyphenyl group, 4-n-pentyloxyphenyl group, 4-n-hexyloxyphenyl group, 4-cyclohexyloxyphenyl group, 4-n-heptyloxyphenyl group, 4-n-octyloxyphenyl group, 4-n-decyloxyphenyl group, 2,3-dimethoxyphenyl group, 2,5-dimethoxyphenyl group, 3,4-dimethoxyphenyl group, 2-methoxy-5-methylphenyl group, 3-methyl-4-methoxyphenyl group, 2-fluorophenyl group, 3-fluorophenyl group, 4-fluorophenyl group, 2-chlorophenyl group, 3-chlorophenyl group, 4-chlorophenyl group, 4-bromophenyl group, 4-trifluoromethylphenyl group, 3,4-dichlorophenyl group, 2-methyl-4-chlorophenyl group, 2-chloro-4-methylphenyl group, 3-chloro-4-methylphenyl group, 2-chloro-4-methoxyphenyl group, 4-phenylphenyl group, 3-phenylphenyl group, 4-(4′-methylphenyl)phenyl group, 4-(4′-methoxyphenyl)phenyl group, 1-naphthyl group, 2-naphthyl group, 4-ethoxy-1-naphthyl group, 6-methoxy-2-naphthyl group, 7-ethoxy-2-naphthyl group, 2-furyl group, 2-thienyl group, 3-thienyl group, 2-pyridyl group, 3-pyridyl group, or 4-pyridyl group), more preferably hydrogen atom, fluorine atom, chlorine atom, alkyl group having 1 to 10 carbon atoms, alkoxy group having 1 to 10 carbon atoms or aryl group having 6 to 12 carbon atoms, further more preferably hydrogen atom, fluorine atom, chlorine atom, alkyl group having 1 to 6 carbon atoms, alkoxy group having 1 to 6 carbon atoms or carbocyclic aromatic group having 6 to 10 carbon atoms.

Examples of the fluoranthene derivative represented by the formula (10) are as follows.

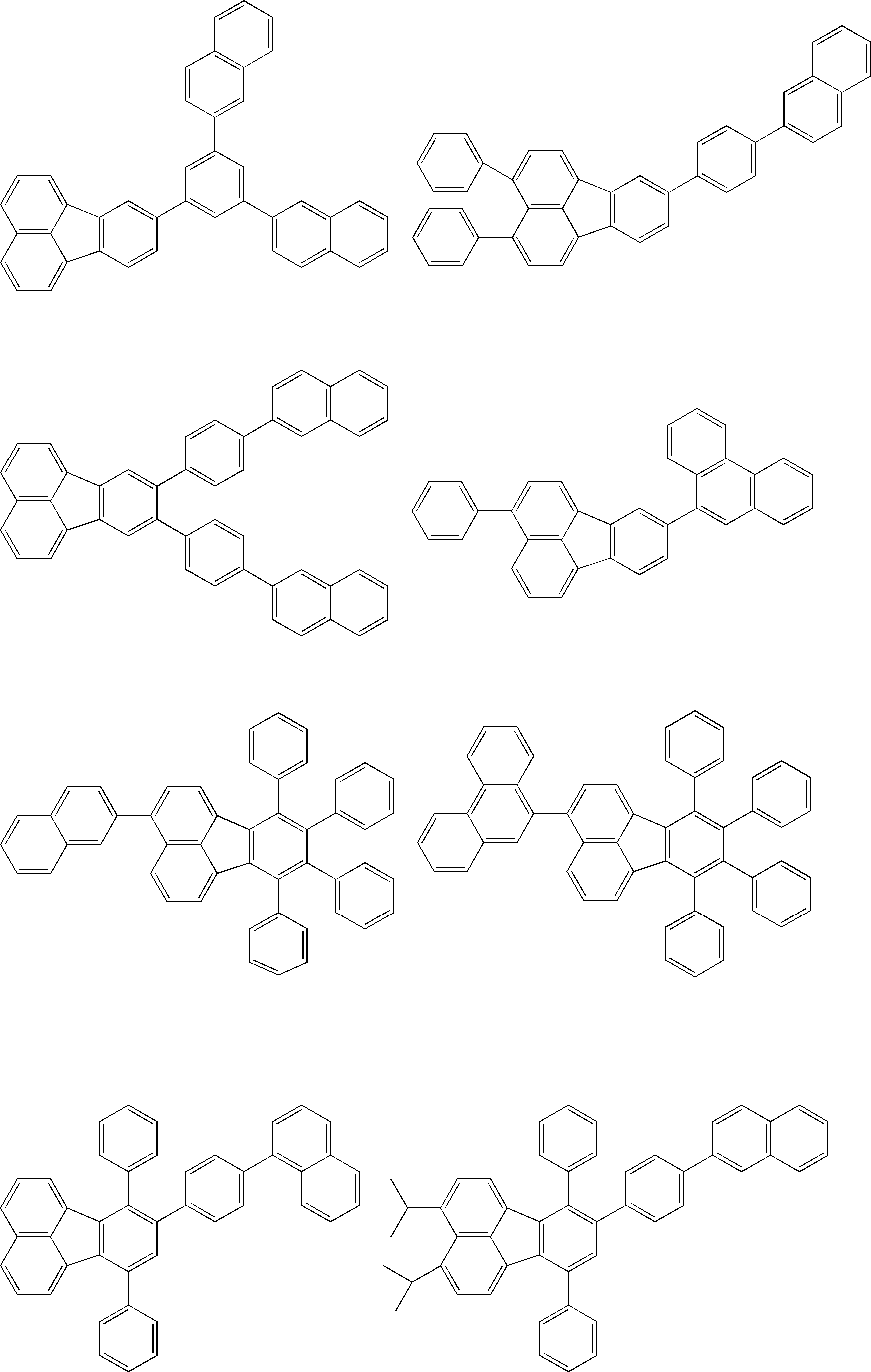

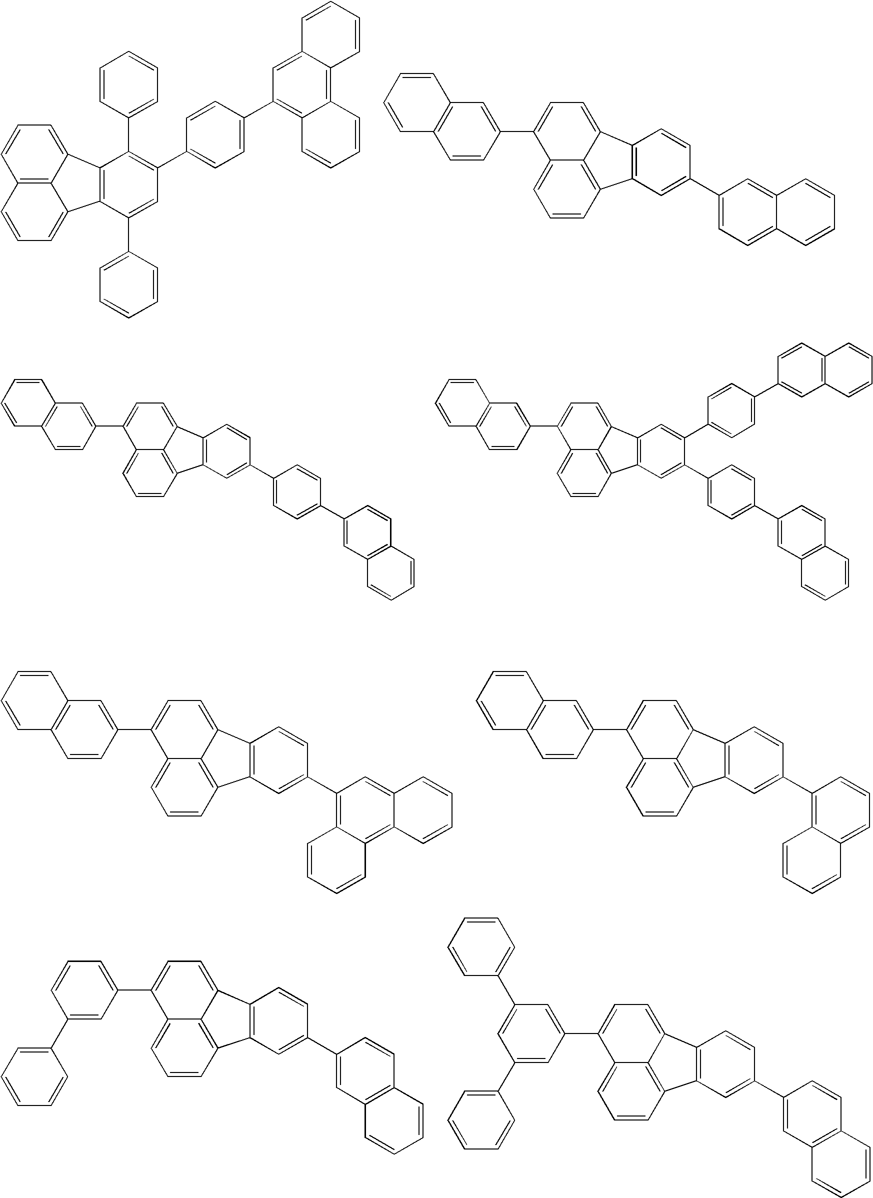

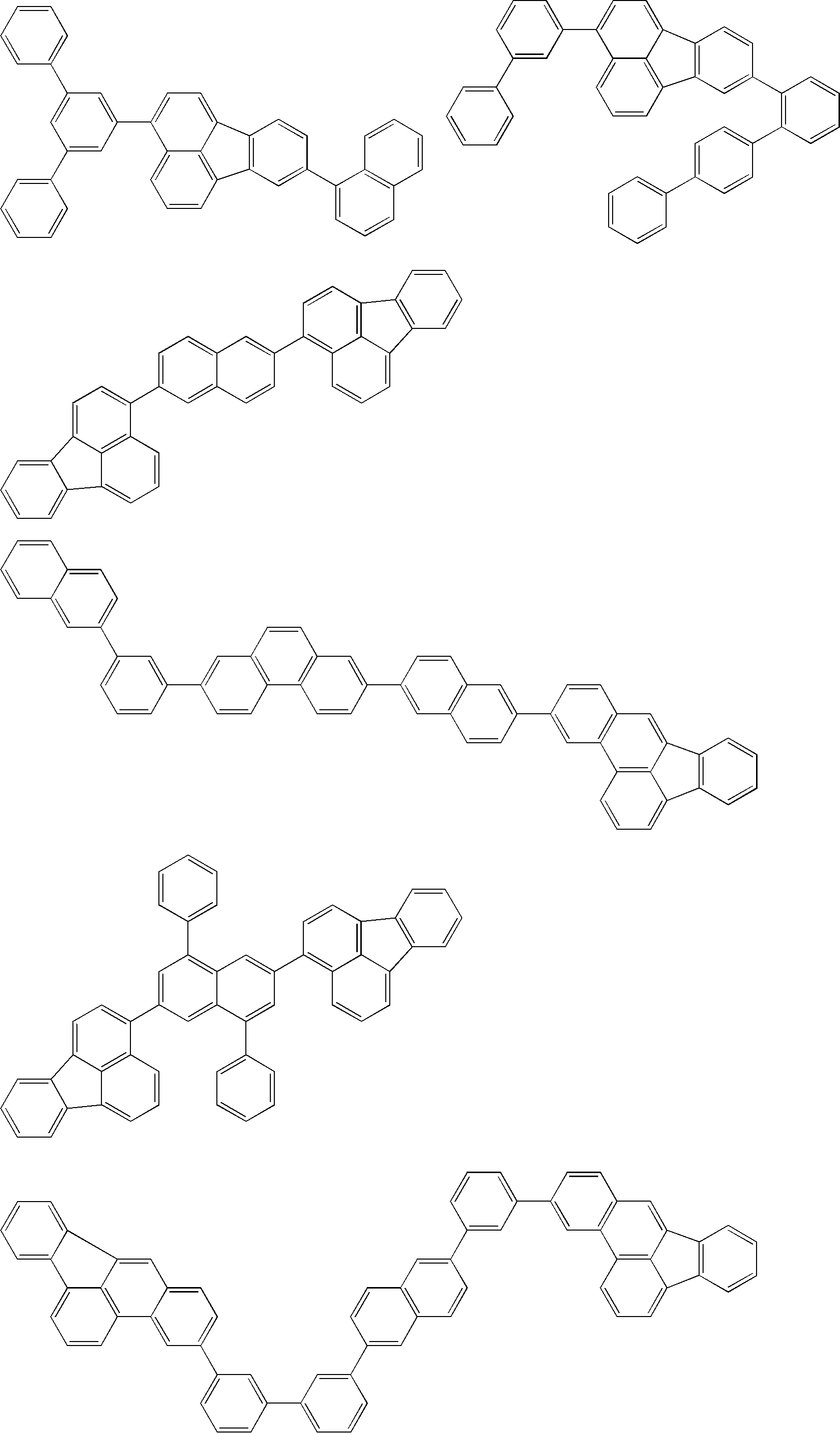

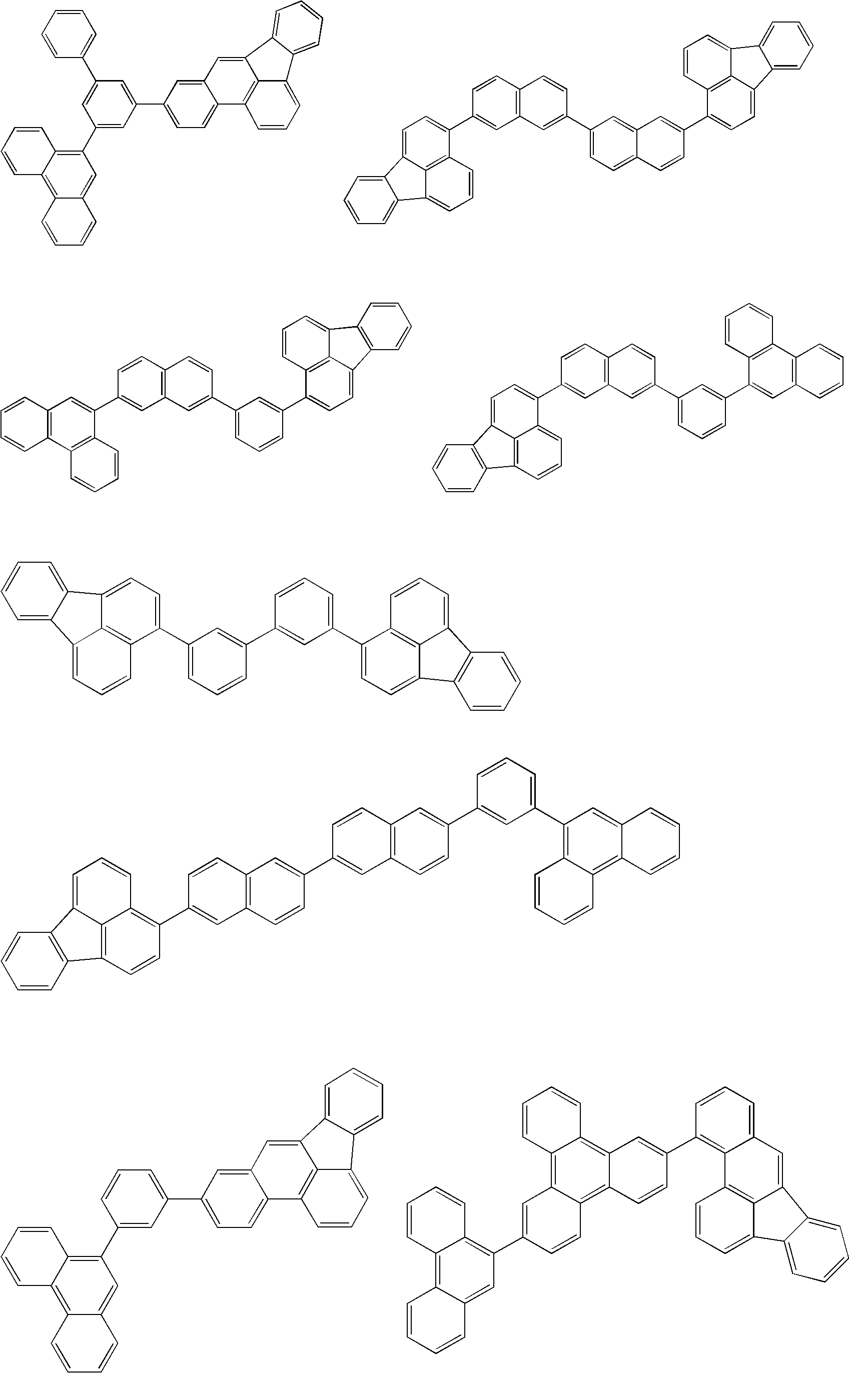

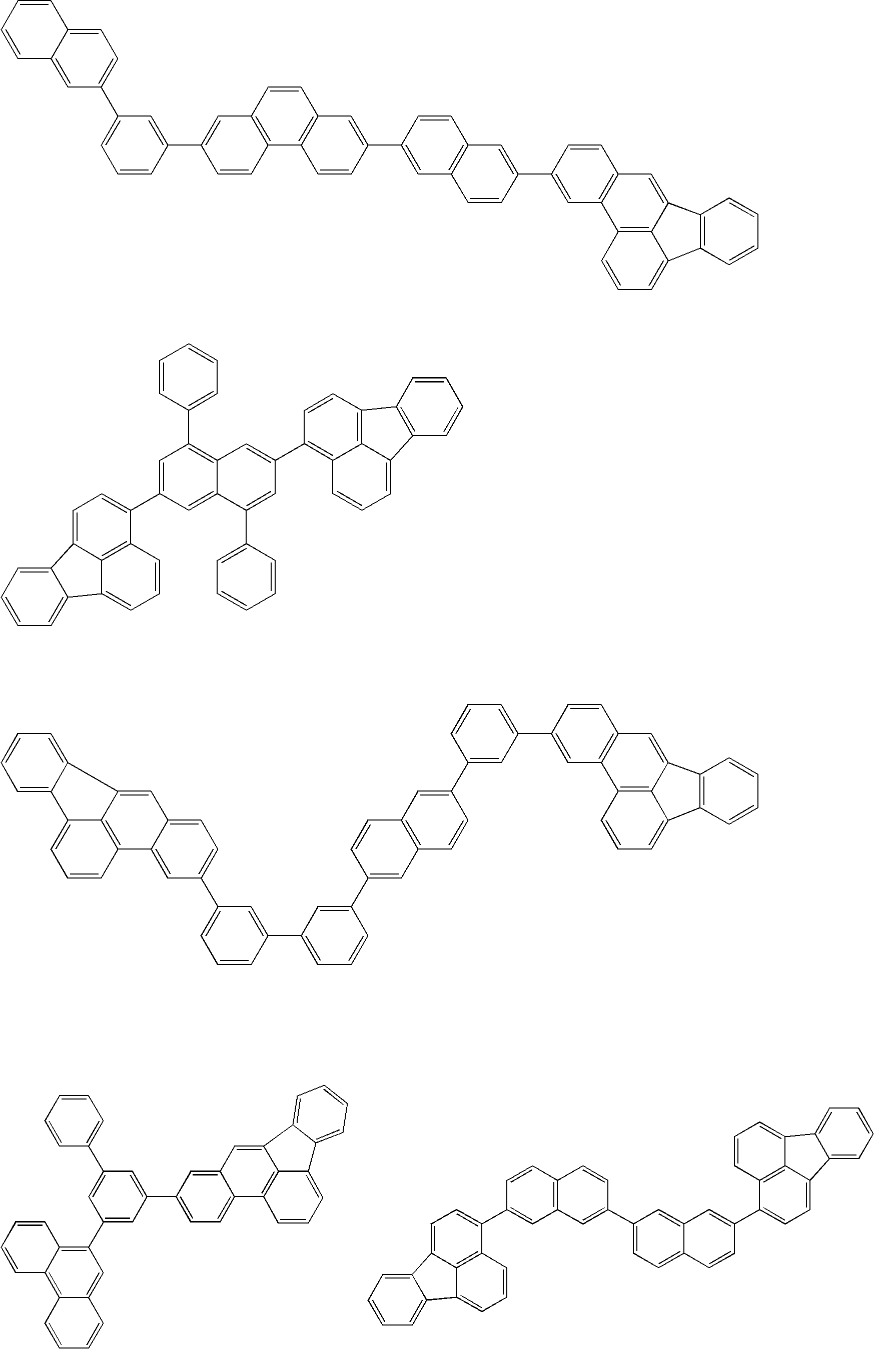

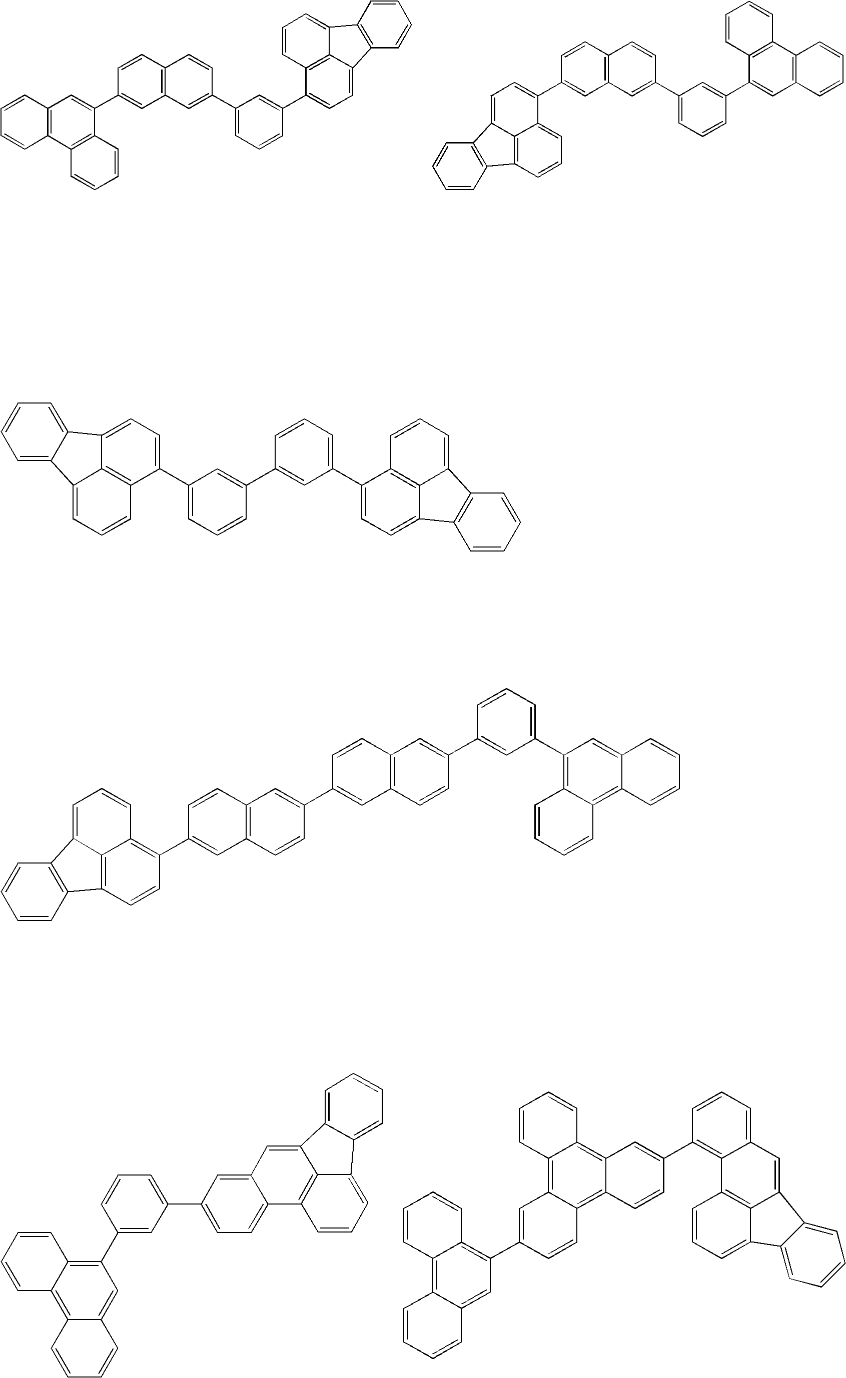

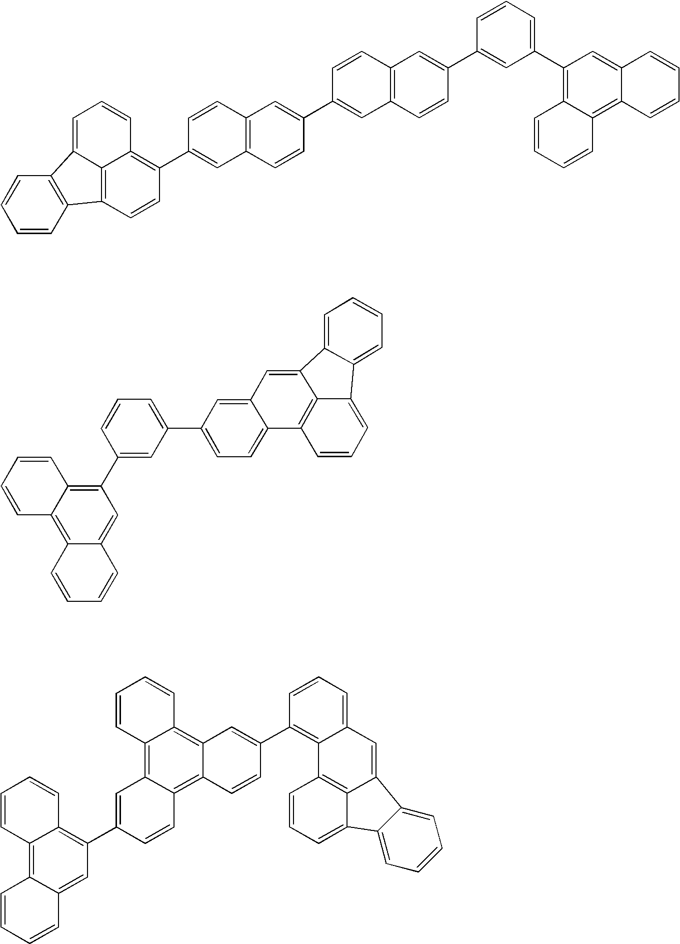

Examples of the substituted or unsubstituted benzofluoranthene are the elementary substance of benzo[b]fluoranthene represented by the following formula (101) or its derivative and the elementary substance of benzo[k]fluoranthene represented by a formula (102) or its derivative.

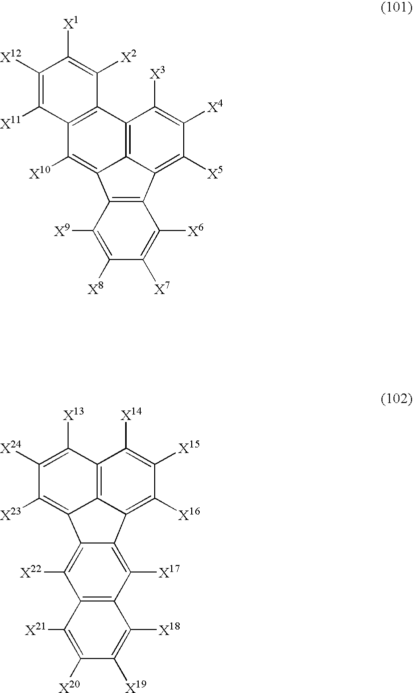

In the formulae (101) and (102), X¹ to X²⁴ each represent a hydrogen atom, a halogen atom, a linear, branched or cyclic alkyl group, a linear, branched or cyclic alkoxy group, or a substituted or unsubstituted aryl group.

The aryl group represents a carbocyclic aromatic group such as a phenyl group and a naphthyl group, or a heterocyclic aromatic group such as a furyl group, a thienyl group and a pyridyl group.

X¹ to X²⁴ each preferably represent hydrogen atom, halogen atom (such as fluorine atom, chlorine atom, or bromine atom), linear, branched or cyclic alkyl group having 1 to 16 carbon atoms (such as methyl group, ethyl group, n-propyl group, isopropyl group, n-butyl group, isobutyl group, sec-butyl group, tert-butyl group, n-pentyl group, isopentyl group, neopentyl group, tert-pentyl group, cyclopentyl group, n-hexyl group, 3,3-dimethylbutyl group, cyclohexyl group, n-heptyl group, cyclohexylmethyl group, n-octyl group, tert-octyl group, 2-ethylhexyl group, n-nonyl group, n-decyl group, n-dodecyl group, n-tetradecyl group, or n-hexadecyl group), linear, branched or cyclic alkoxy group having 1 to 16 carbon atoms (such as methoxy group, ethoxy group, n-propoxy group, isopropoxy group, n-butoxy group, isobutoxy group, sec-butoxy group, n-pentyloxy group, neopentyloxy group, cyclopentyloxy group, n-hexyloxy group, 3,3-dimethylbutyloxy group, cyclohexyloxy group, n-heptyloxy group, n-octyloxy group, 2-ethylhexyloxy group, n-nonyloxy group, n-decyloxy group, n-dodecyloxy group, n-tetradecyloxy group, or n-hexadecyloxy group), or substituted or unsubstituted aryl group having 4 to 16 carbon atoms (such as phenyl group, 2-methylphenyl group, 3-methylphenyl group, 4-methylphenyl group, 4-ethylphenyl group, 4-n-propylphenyl group, 4-isopropylphenyl group, 4-n-butylphenyl group, 4-tert-butylphenyl group, 4-isopentylphenyl group, 4-tert-pentylphenyl group, 4-n-hexylphenyl group, 4-cyclohexylphenyl group, 4-n-octylphenyl group, 4-n-decylphenyl group, 2,3-dimethylphenyl group, 2,4-dimethylphenyl group, 2,5-dimethylphenyl group, 3,4-dimethylphenyl group, 5-indanyl group, 1,2,3,4-tetrahydro-5-naphthyl group, 1,2,3,4-tetrahydro-6-naphthyl group, 2-methoxyphenyl group, 3-methoxyphenyl group, 4-methoxyphenyl group, 3-ethoxyphenyl group, 4-ethoxyphenyl group, 4-n-propoxyphenyl group, 4-isopropoxyphenyl group, 4-n-butoxyphenyl group, 4-n-pentyloxyphenyl group, 4-n-hexyloxyphenyl group, 4-cyclohexyloxyphenyl group, 4-n-heptyloxyphenyl group, 4-n-octyloxyphenyl group, 4-n-decyloxyphenyl group, 2,3-dimethoxyphenyl group, 2,5-dimethoxyphenyl group, 3,4-dimethoxyphenyl group, 2-methoxy-5-methylphenyl group, 3-methyl-4-methoxyphenyl group, 2-fluorophenyl group, 3-fluorophenyl group, 4-fluorophenyl group, 2-chlorophenyl group, 3-chlorophenyl group, 4-chlorophenyl group, 4-bromophenyl group, 4-trifluoromethylphenyl group, 3,4-dichlorophenyl group, 2-methyl-4-chlorophenyl group, 2-chloro-4-methylphenyl group, 3-chloro-4-methylphenyl group, 2-chloro-4-methoxyphenyl group, 4-phenylphenyl group, 3-phenylphenyl group, 4-(4′-methylphenyl)phenyl group, 4-(4′-methoxyphenyl)phenyl group, 1-naphthyl group, 2-naphthyl group, 4-ethoxy-1-naphthyl group, 6-methoxy-2-naphthyl group, 7-ethoxy-2-naphthyl group, 2-furyl group, 2-thienyl group, 3-thienyl group, 2-pyridyl group, 3-pyridyl group, or 4-pyridyl group), more preferably hydrogen atom, fluorine atom, chlorine atom, alkyl group having 1 to 10 carbon atoms, alkoxy group having 1 to 10 carbon atoms or aryl group having 6 to 12 carbon atoms, further more preferably hydrogen atom, fluorine atom, chlorine atom, alkyl group having 1 to 6 carbon atoms, alkoxy group having 1 to 6 carbon atoms or carbocyclic aromatic group having 6 to 10 carbon atoms.

Examples of the benzo[b]fluoranthene derivative represented by the formula (101) are as follows.

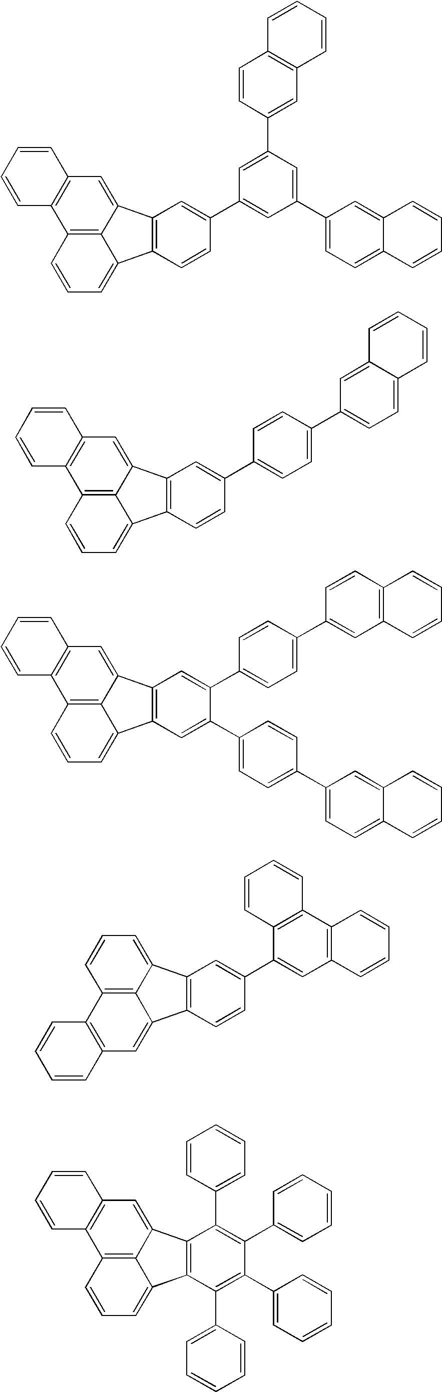

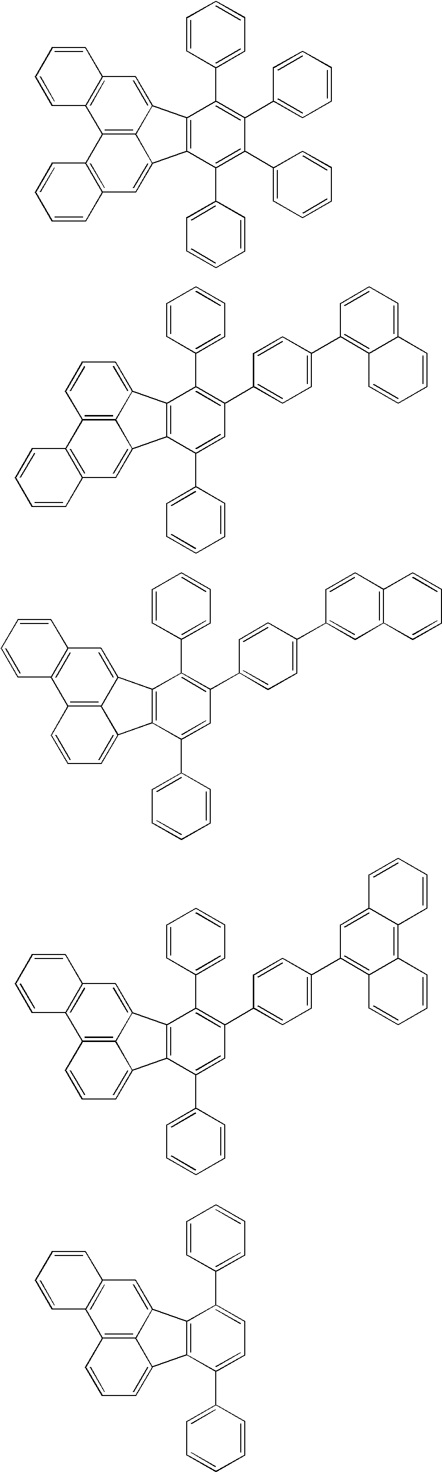

Examples of the benzo[k]fluoranthene derivative represented by the formula (102) are as follows.

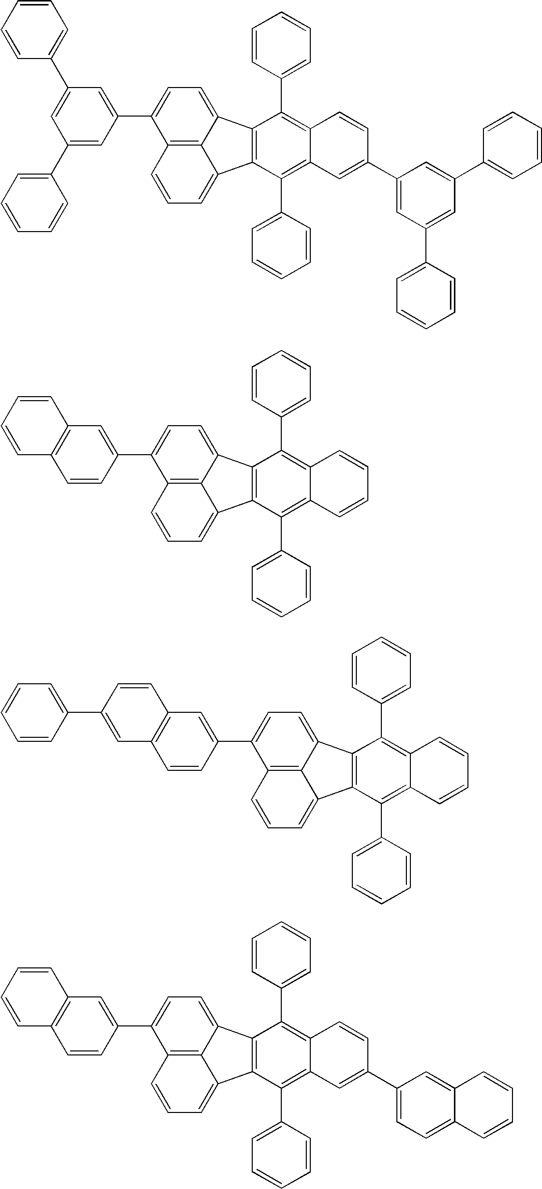

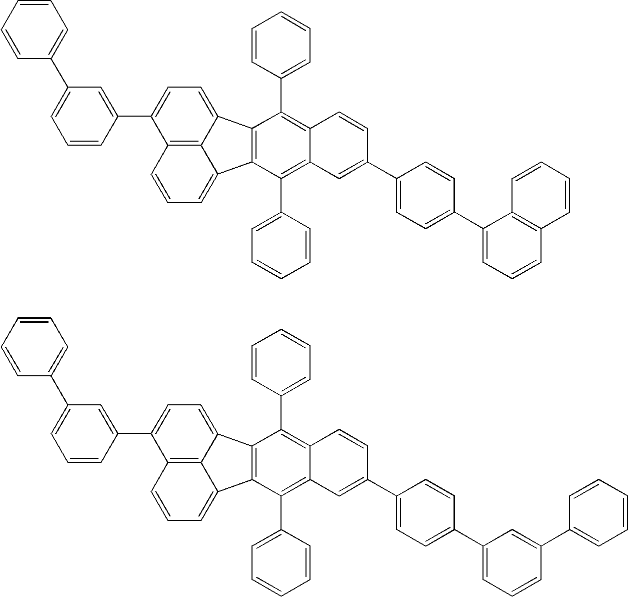

In the aspect of the invention, the polycyclic fused aromatic skeleton is preferably the elementary substance of triphenylene represented by the following formula (11) or its derivative.

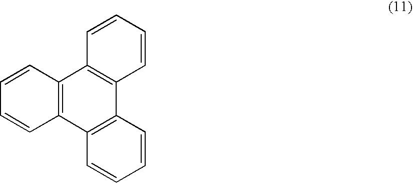

The triphenylene derivative is exemplarily represented by the following formula (11A).

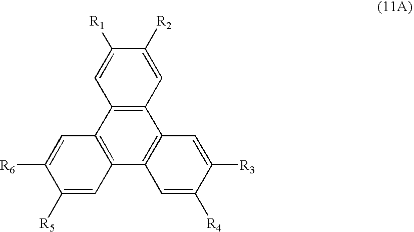

In the formula (11A), R₁ to R₆ each independently represent a hydrogen atom or a substituent formed by one group or a combination of two or more groups selected from a substituted or unsubstituted aryl group having 5 to 30 ring-forming carbon atoms (excluding the number of carbon atoms in the substituent), a branched or linear alkyl group having 1 to 30 carbon atoms and a substituted or unsubstituted cycloalkyl group having 3 to 20 carbon atoms.

Examples of the triphenylene derivative represented by the formula (11) are as follows.

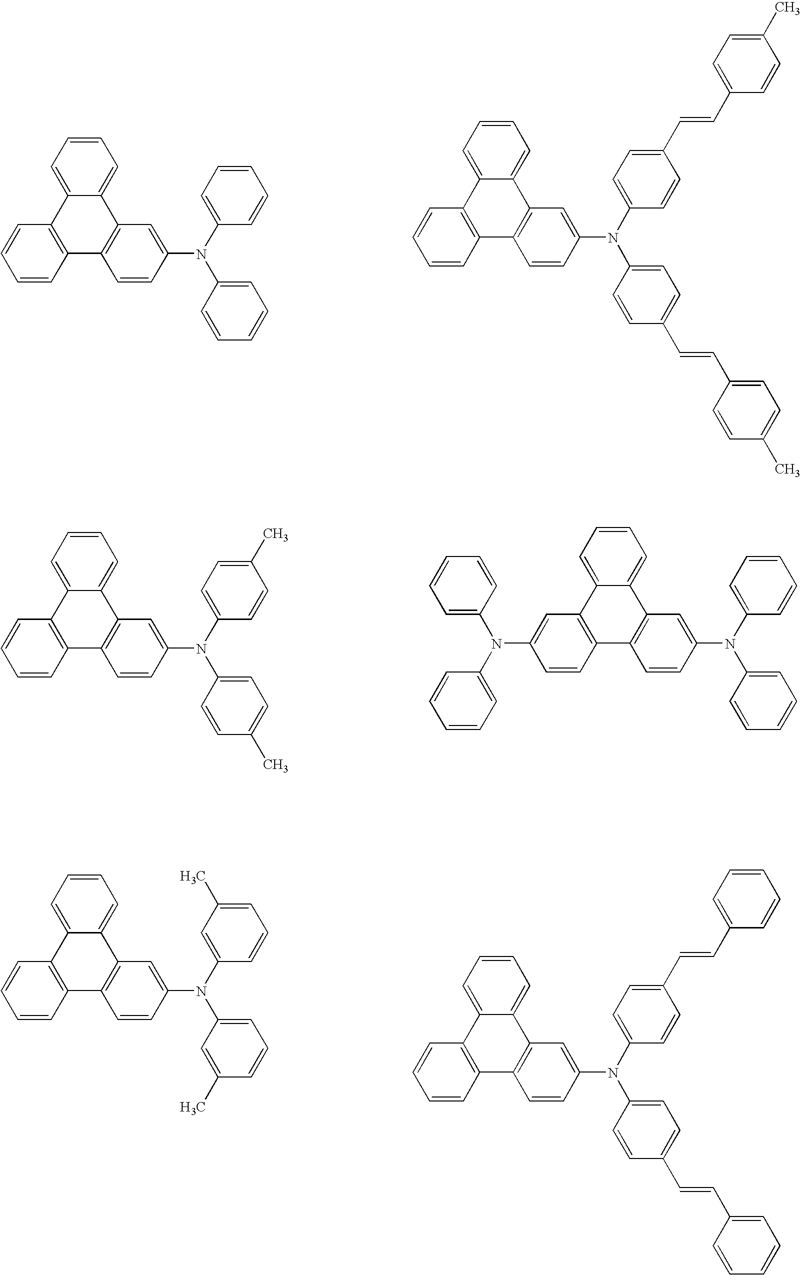

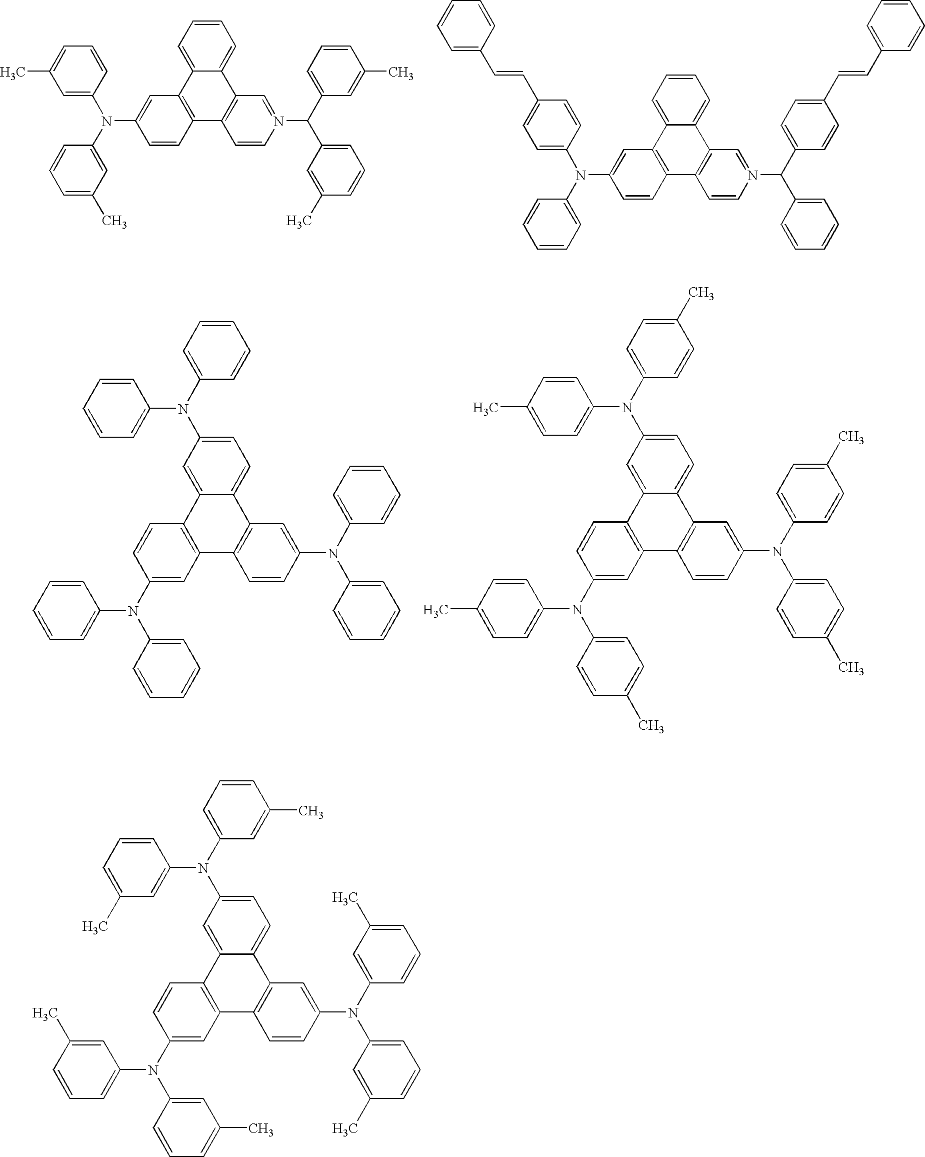

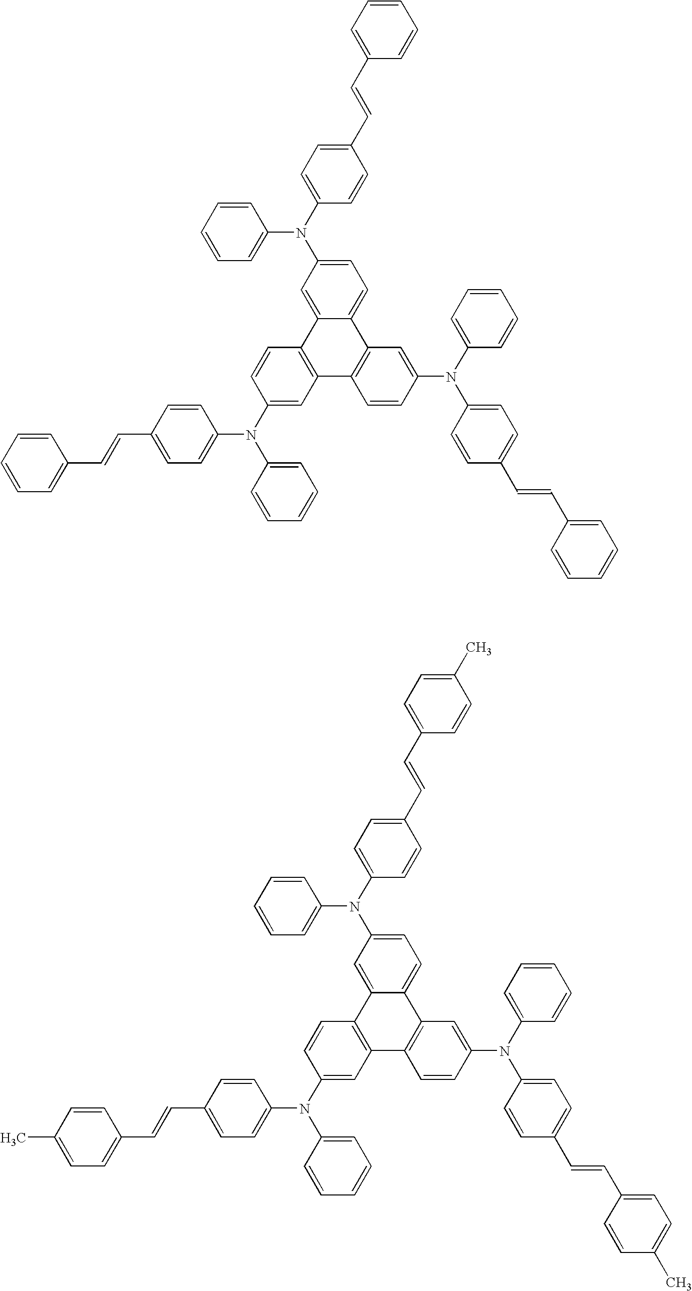

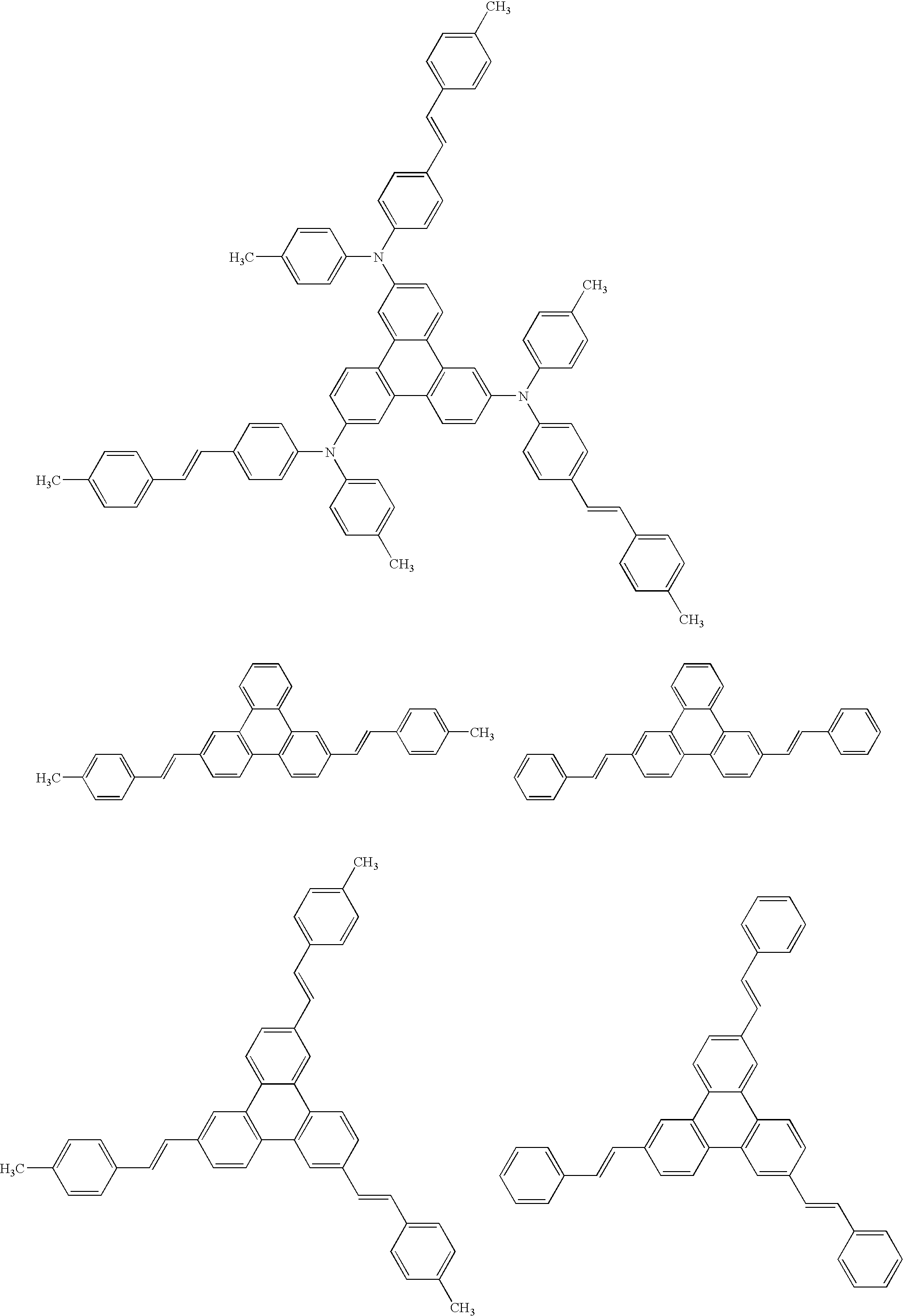

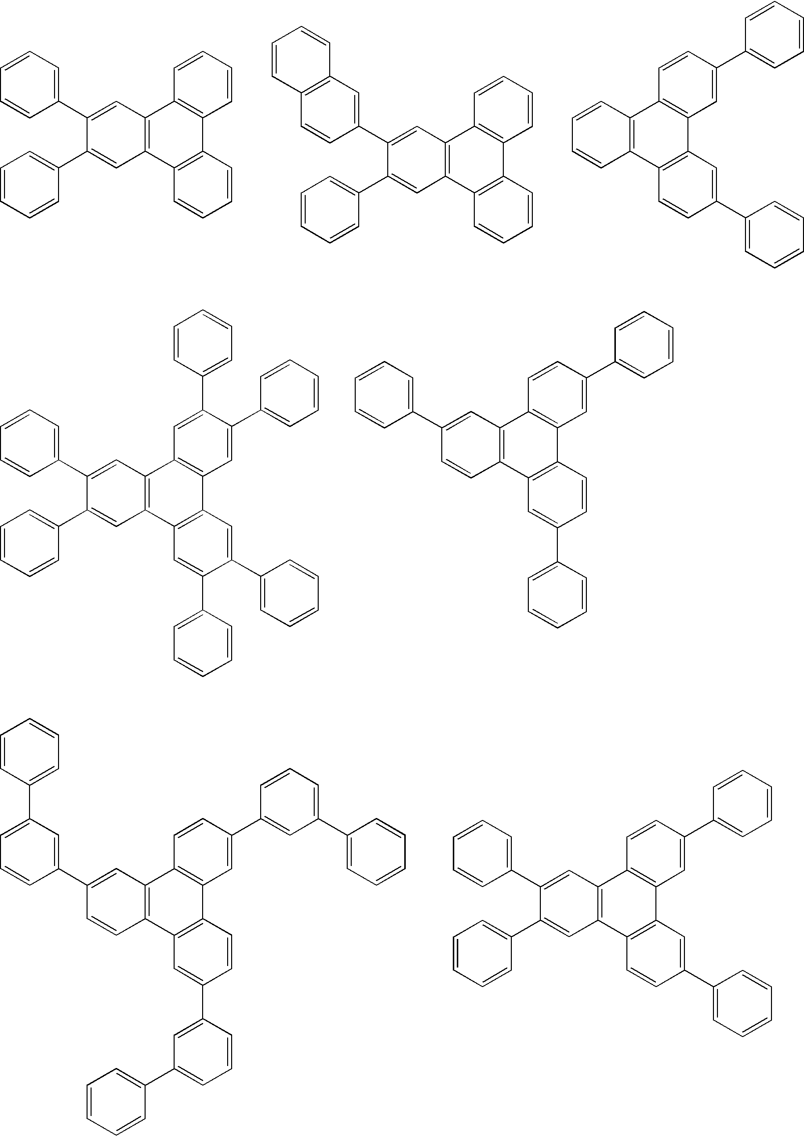

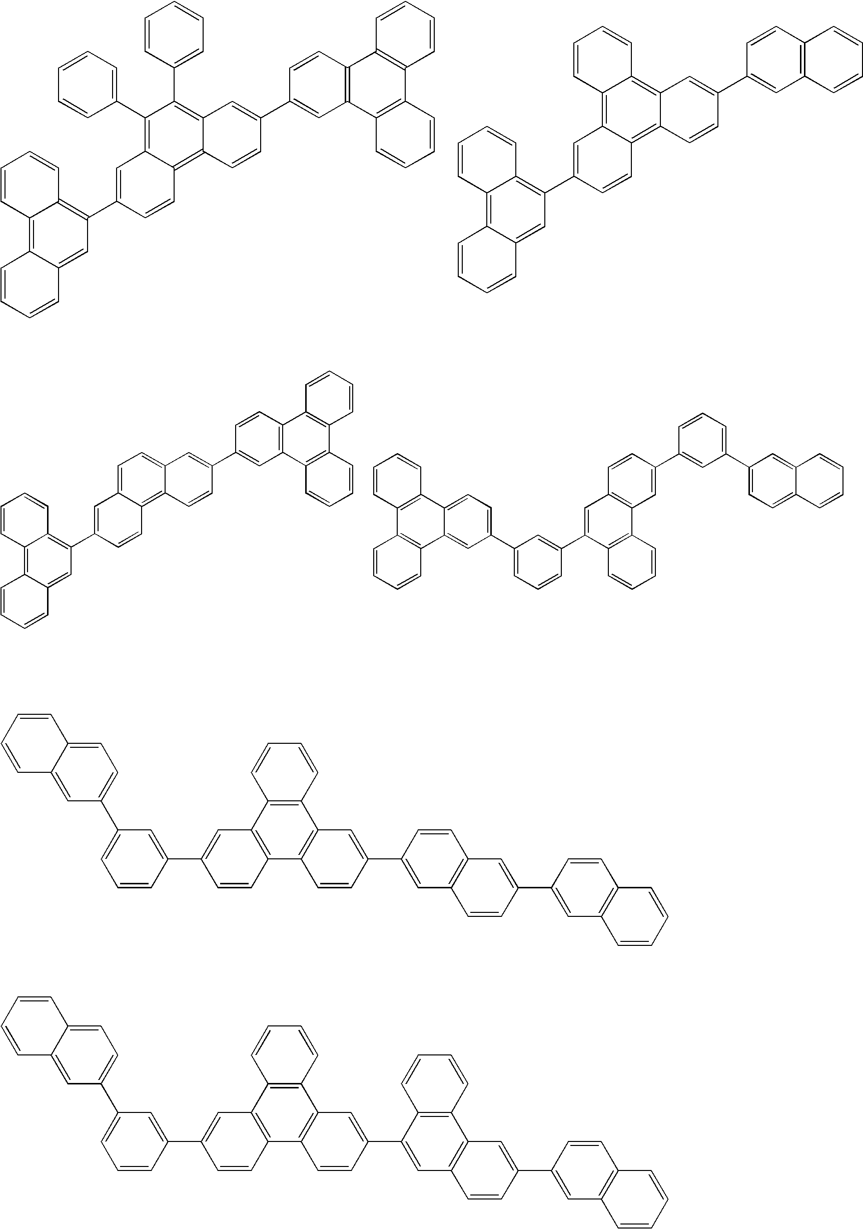

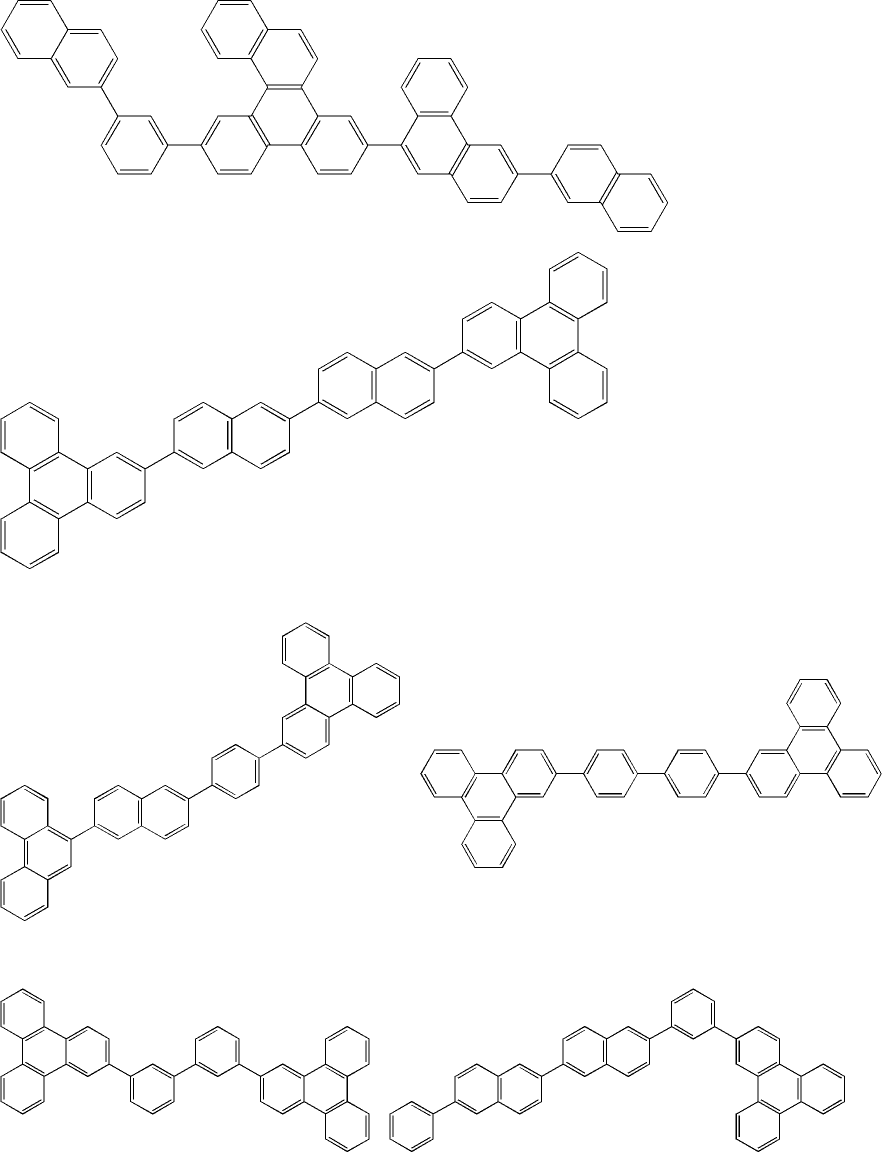

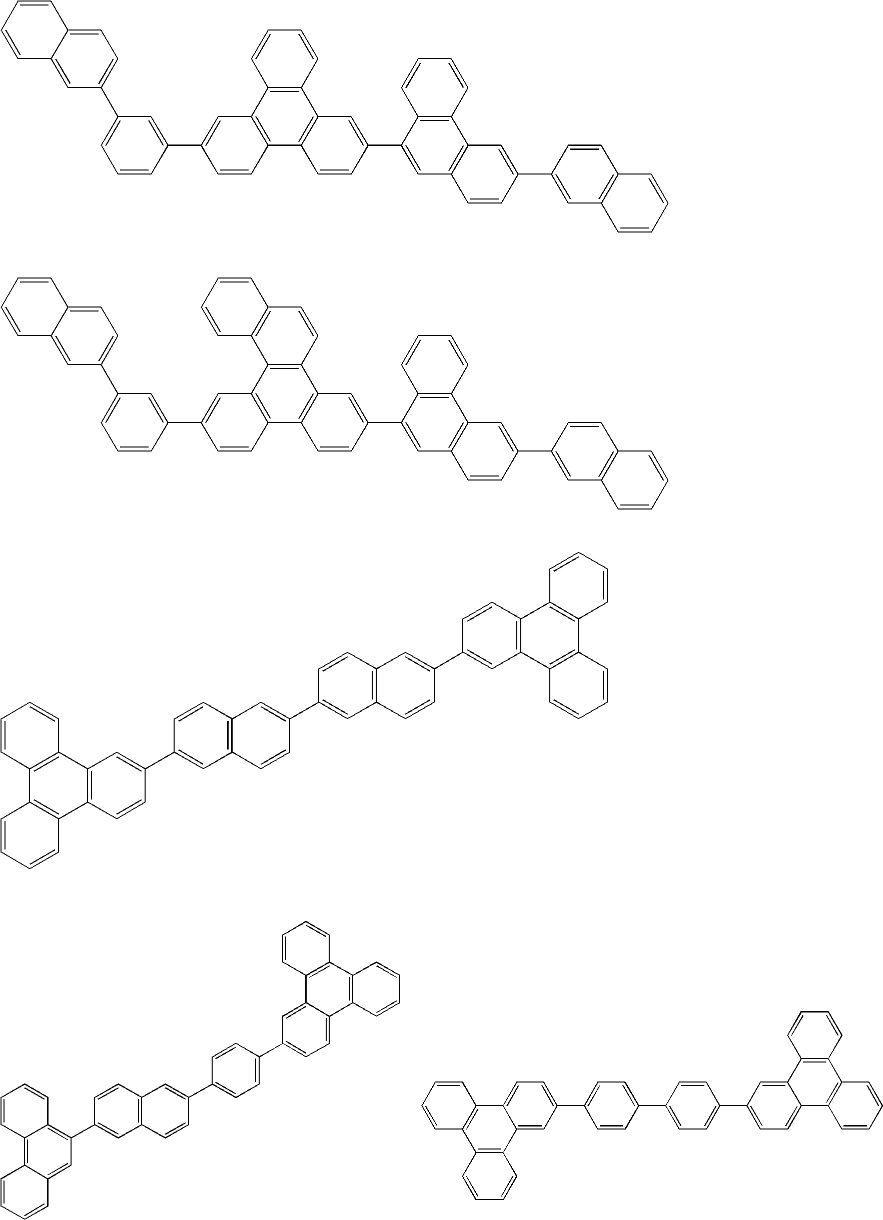

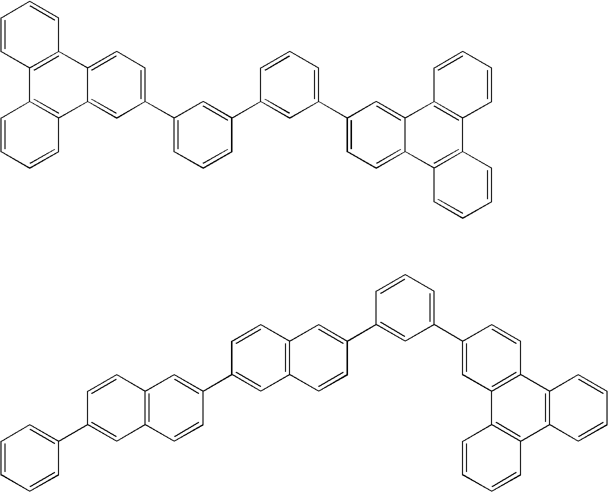

The polycyclic fused aromatic skeleton may contain nitrogen atom, examples of which are shown below.

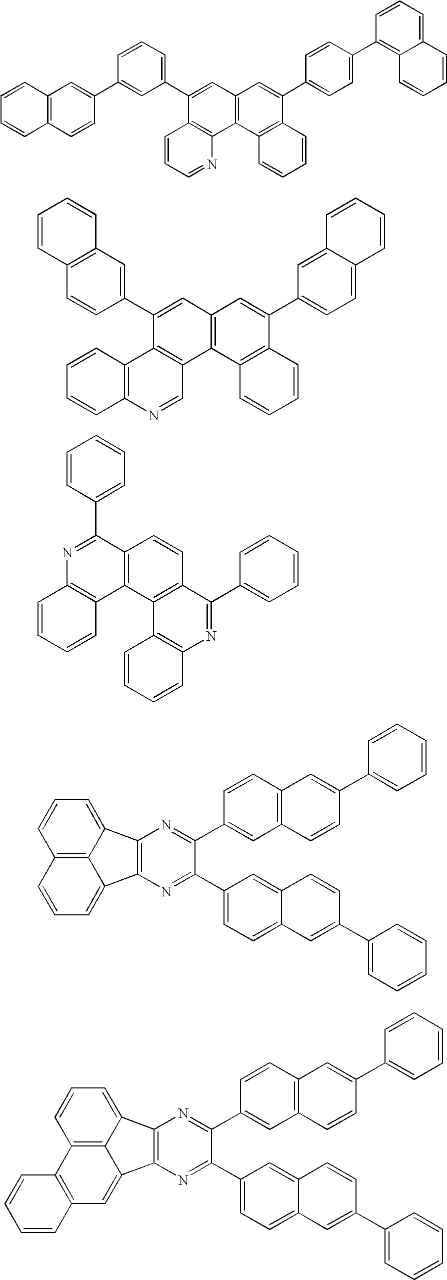

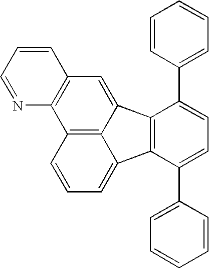

Preferably in the aspect of the invention, at least either one of the first phosphorescent material and the second phosphorescent material contains a metal complex comprising: a metal selected from Ir, Pt, Os, Au, Cu, Re and Ru; and a ligand.

Examples of the emitting material are PQIr(iridium(III)bis(2-phenyl quinolyl-N,C^{2′}) acetylacetonate) and Ir(ppy)₃(fac-tris(2-phenylpyridine)iridium). Further examples are compounds shown below.

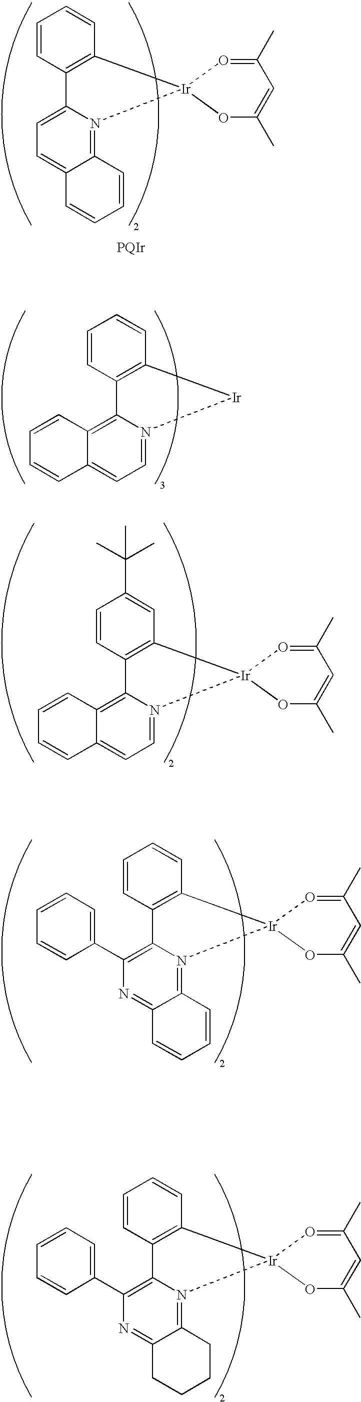

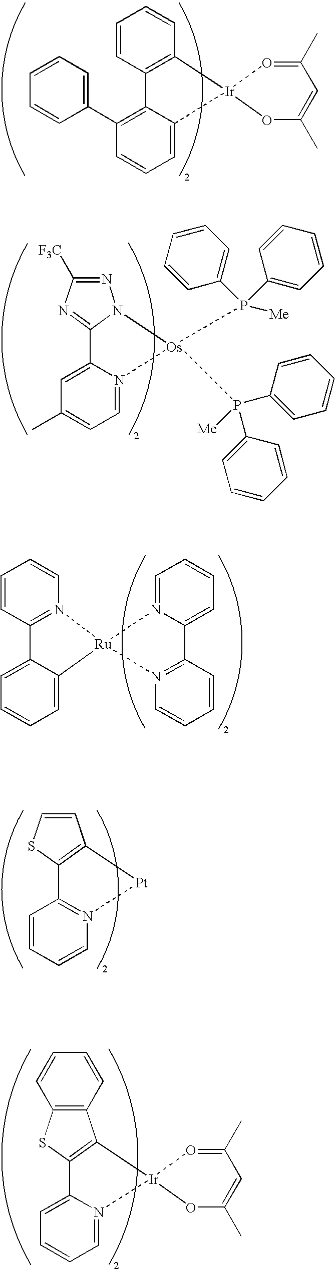

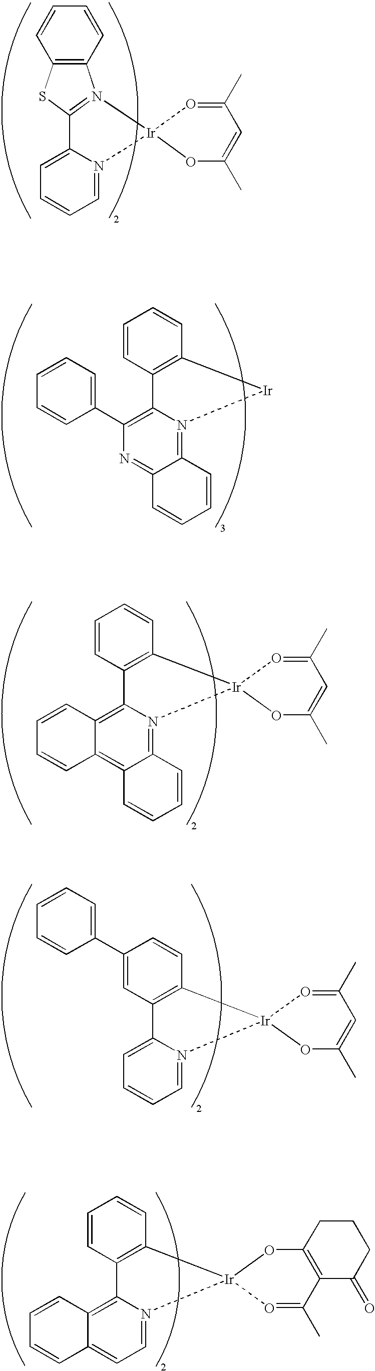

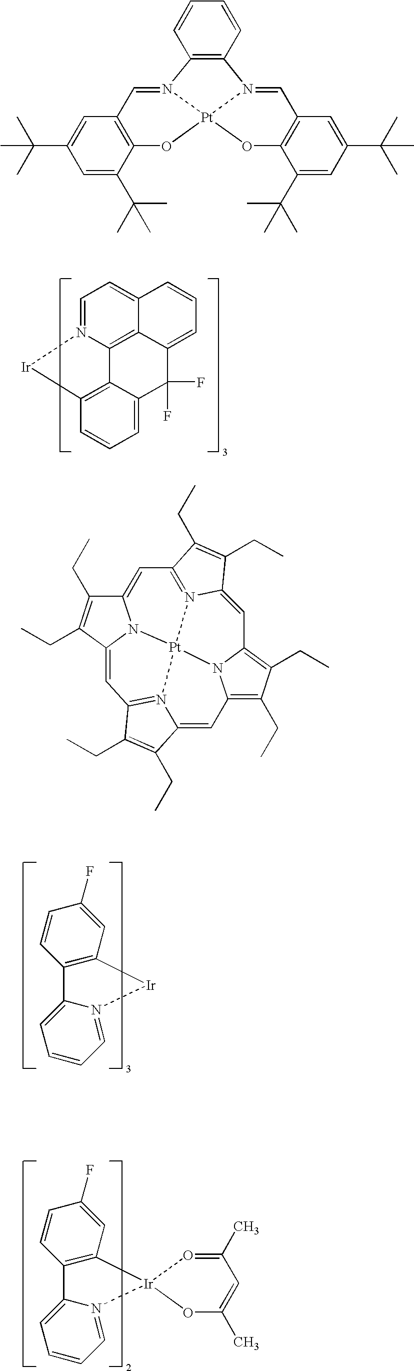

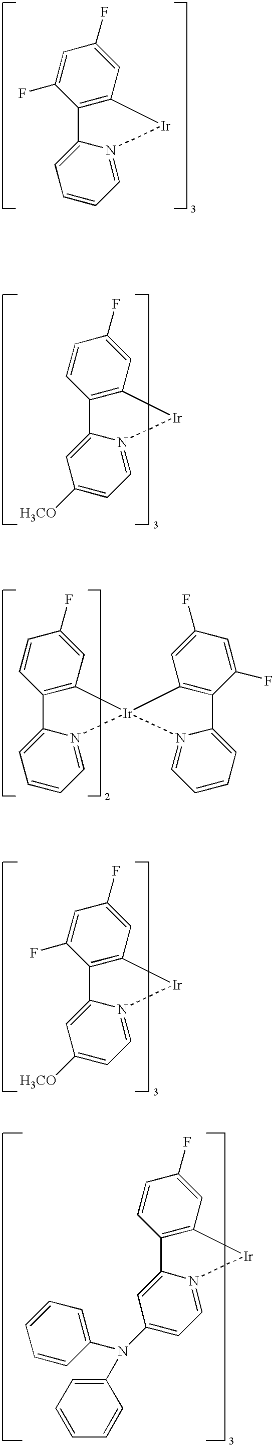

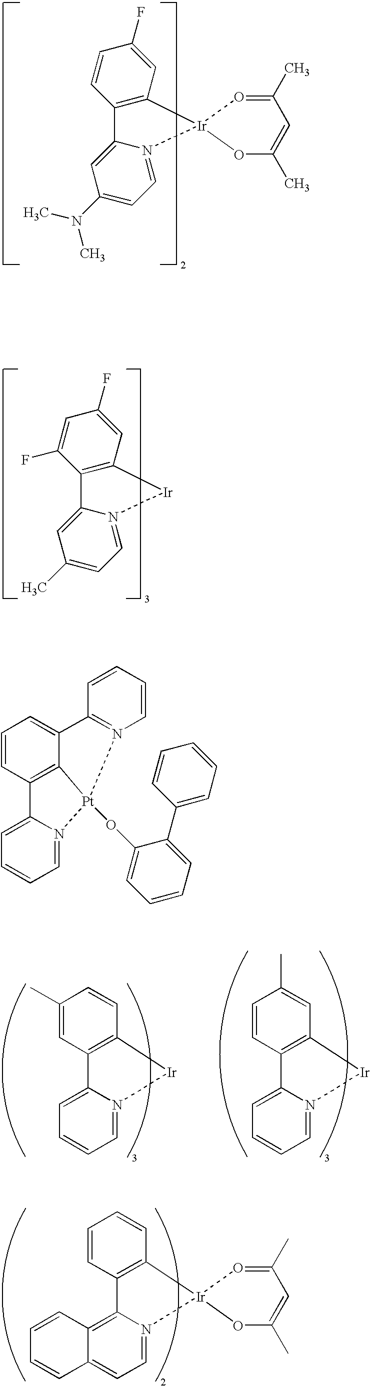

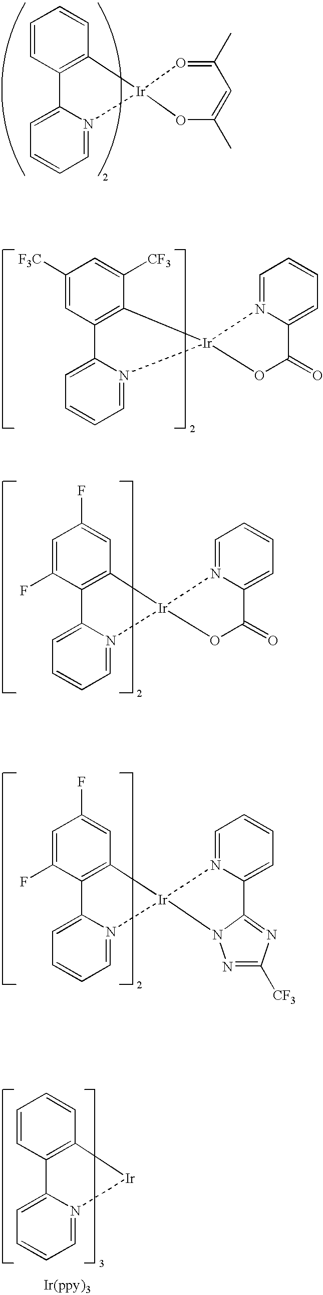

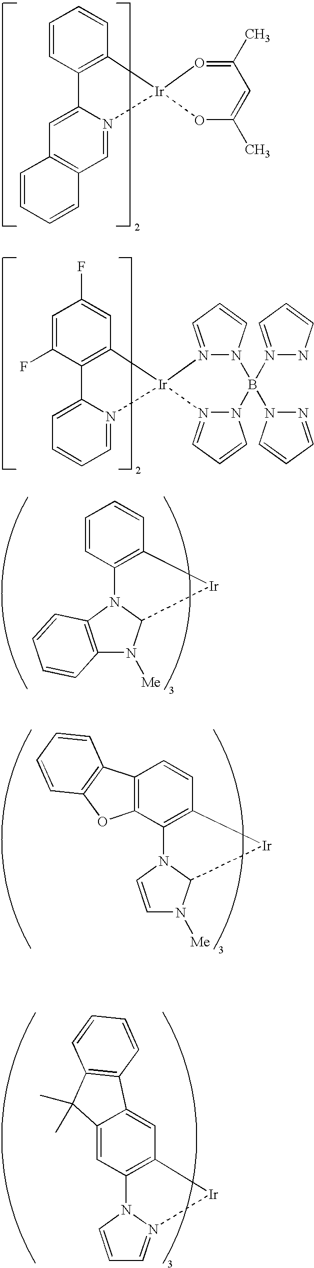

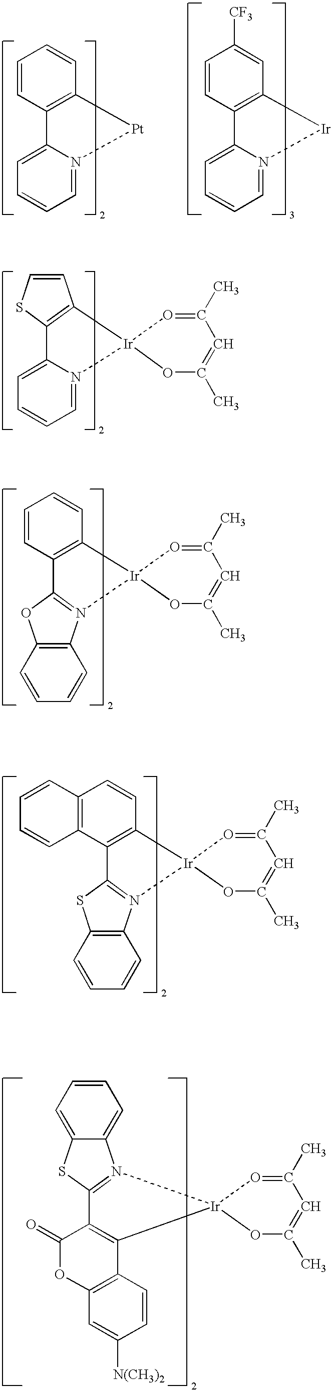

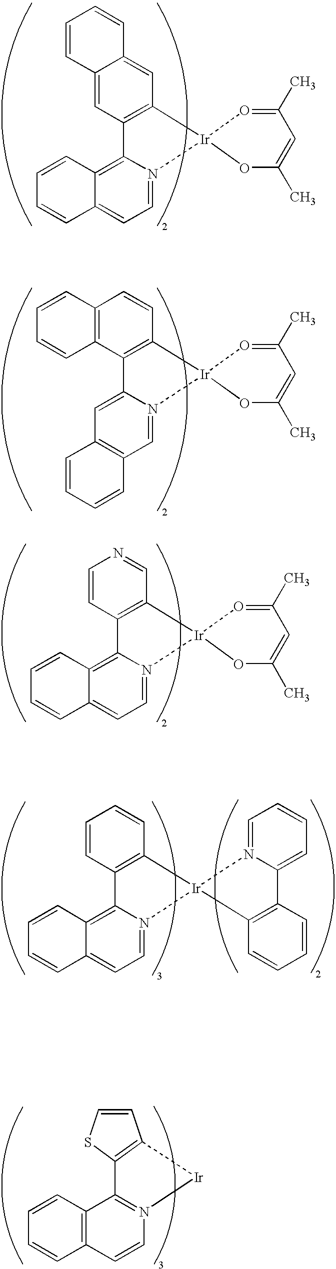

Preferably in the aspect of the invention, wavelength of maximum emission luminance of the first phosphorescent material and the second phosphorescent material is in a range of 470 nm to 700 nm.

A wavelength of the maximum emission luminance is more preferably in a range of 480 nm to 680 nm, further preferably in a range of 500 nm to 650 nm.

By forming the first emitting layer and the second emitting layer by doping the phosphorescent material for emitting light of such wavelength to the host material of the polycyclic fused aromatic compound of which the minimum excited triplet energy gap is in a range of 2.1 eV to 2.7 eV, light emission of high efficiency can be obtained.

The first emitting layer and the second emitting layer may be blue-emitting layers. Alternatively, the first emitting layer and the second emitting layer may be green-emitting layers. Further alternatively, the first emitting layer and the second emitting layer may be red-emitting layers.

In other words, the first emitting layer and the second emitting layer according to the aspect of the invention may be the same color-emitting layers.

When the first emitting layer and the second emitting layer are blue-emitting layers, light having wavelength of 470 nm to 500 nm is emitted. When the first emitting layer and the second emitting layer are green-emitting layers, light having wavelength of 500 nm to 580 nm is emitted. When the first emitting layer and the second emitting layer are red-emitting layers, light having wavelength of 580 nm to 700 nm is emitted.

Preferably in the aspect of the invention, a difference in wavelength of maximum emission luminance between the first phosphorescent material and the second phosphorescent material is within plus or minus 20 nm.

While the first emitting layer and the second emitting layer emit the same color light as described above, a difference in wavelength between the first emitting layer and the second emitting layer is within plus or minus 20 nm.

Preferably in the aspect of the invention, the organic thin-film layer further includes an electron injecting layer between the cathode and the organic layer, and the electron injecting layer contains a nitrogen-containing heterocyclic derivative.

The electron injecting layer or the electron transporting layer, which aids injection of the electrons into the emitting layer, has a high electron mobility. The electron injecting layer is provided for adjusting energy level, by which, for instance, sudden changes of the energy level can be reduced. As a material for the electron injecting layer or the electron transporting layer, 8-hydroxyquinoline or a metal complex of its derivative, an oxadiazole derivative and a nitrogen-containing heterocyclic derivative are preferable. An example of the 8-hydroxyquinoline or the metal complex of its derivative is a metal chelate oxinoid compound containing a chelate of oxine (typically 8-quinolinol or 8-hydroxyquinoline). For instance, tris(8-quinolinol) aluminum can be used. Examples of the oxadiazole derivative are as follows.

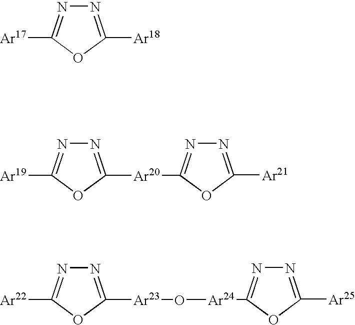

In the formula, Ar¹⁷, Ar¹⁸, Ar¹⁹, Ar²¹, Ar²² and Ar²⁵ each represent a substituted or unsubstituted aryl group. Ar¹⁷, Ar¹⁹ and Ar²² may be the same as or different from Ar¹⁸, Ar²¹ and Ar²⁵ respectively. Ar²⁰, Ar²³ and Ar²⁴ each represent a substituted or unsubstituted arylene group. Ar²³ and Ar²⁴ may be mutually the same or different.

Examples of the arylene group are a phenylene group, a naphthylene group, a biphenylene group, an anthranylene group, a perylenylene group and a pyrenylene group. Examples of the substituent therefor are an alkyl group having 1 to 10 carbon atoms, an alkoxy group having 1 to 10 carbon atoms and a cyano group. Such an electron transport compound is preferably an electron transport compound that can be favorably formed into a thin film(s). Examples of the electron transport compounds are as follows.

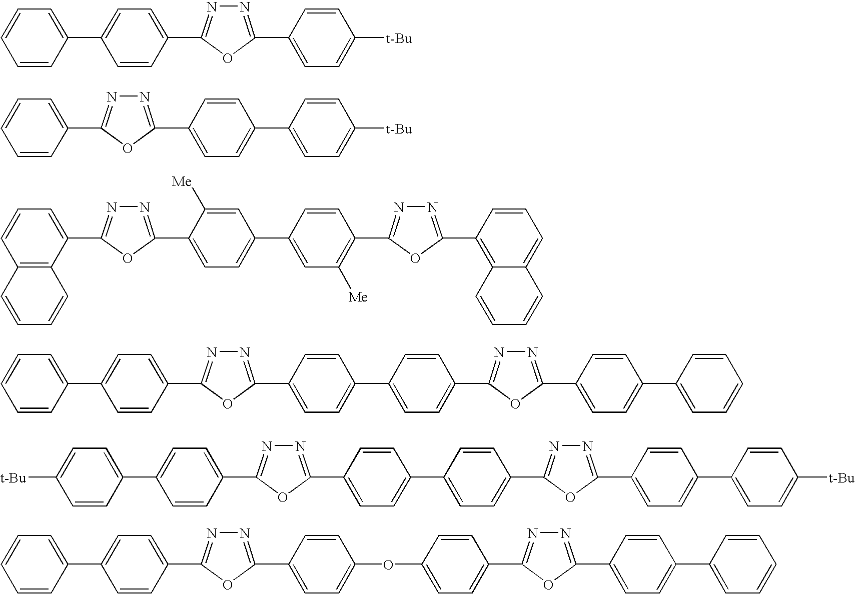

An example of the nitrogen-containing heterocyclic derivative is a nitrogen-containing heterocyclic derivative that is not a metal complex, the derivative being formed of an organic compound represented by either one of the following general formulae. Examples of the nitrogen-containing heterocyclic derivative are five-membered ring or six-membered ring derivative having a skeleton represented by the formula (A) and a derivative having a structure represented by the formula (B).

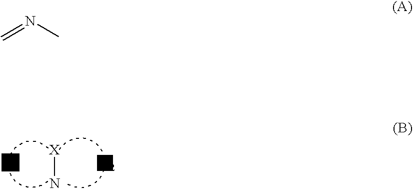

In the formula (B), X represents a carbon atom or a nitrogen atom. Z₁ and Z₂ each independently represent an atom group from which a nitrogen-containing heterocycle can be formed.

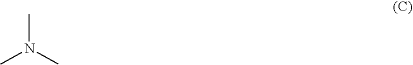

Preferably, the nitrogen-containing heterocyclic derivative is an organic compound having nitrogen-containing aromatic polycyclic series having a five-membered ring or six-membered ring. When the nitrogen-containing heterocyclic derivative includes such nitrogen-containing aromatic polycyclic series having plural nitrogen atoms, the nitrogen-containing heterocyclic derivative may be a nitrogen-containing aromatic polycyclic organic compound having a skeleton formed by a combination of the skeletons respectively represented by the formulae (A) and (B), or by a combination of the skeletons respectively represented by the formulae (A) and (C).

A nitrogen-containing group of the nitrogen-containing organic compound is selected from nitrogen-containing heterocyclic groups respectively represented by the following general formulae.

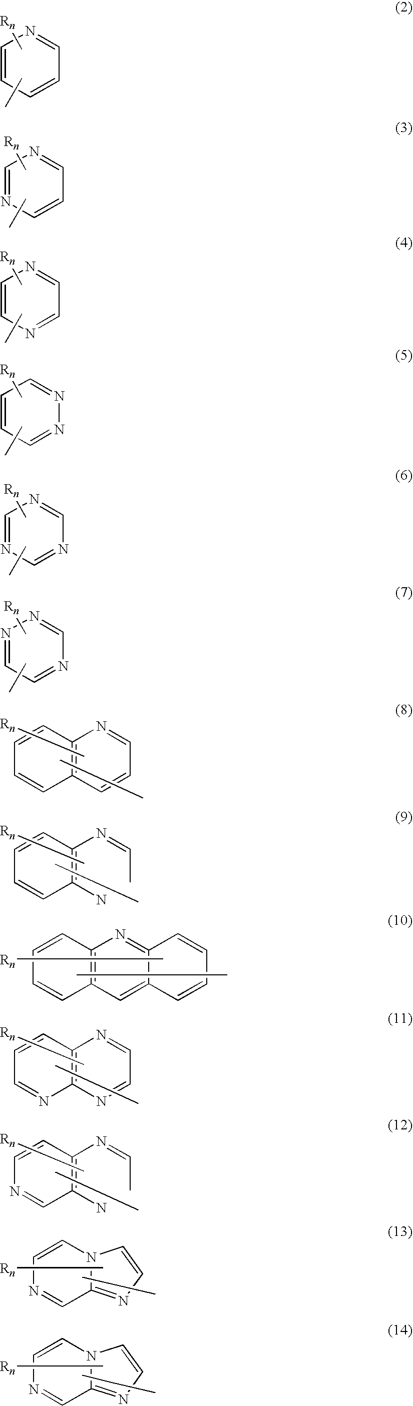

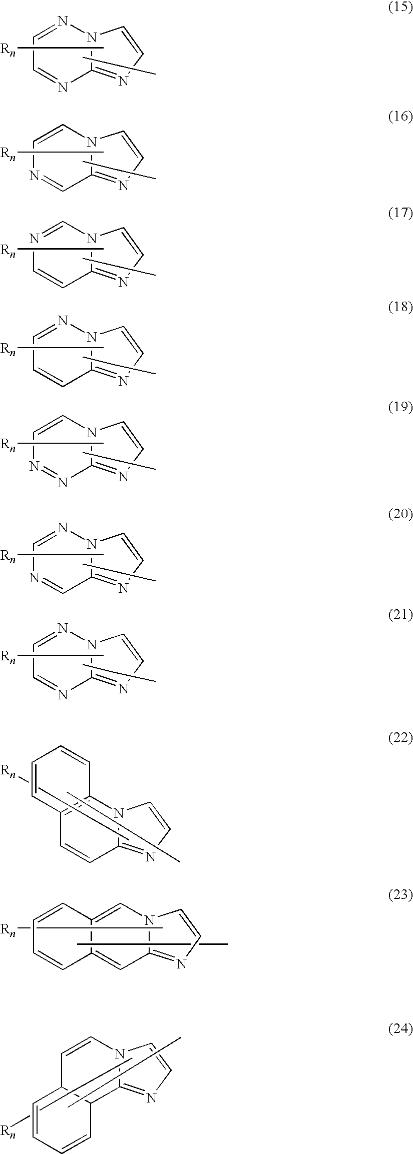

In the formulae (2) to (24): R represents an aryl group having 6 to 40 carbon atoms, a heteroaryl group having 3 to 40 carbon atoms, an alkyl group having 1 to 20 carbon atoms or an alkoxy group having 1 to 20 carbon atoms; and n represents an integer in a range of 0 to 5. When n is an integer of 2 or more, the plurality of R may be mutually the same or different.

A preferable specific compound is a nitrogen-containing heterocyclic derivative represented by the following formula.

HAr-L¹-Ar¹—Ar²

In the formula, HAr represents a substituted or unsubstituted nitrogen-containing heterocycle having 3 to 40 carbon atoms; L¹ represents a single bond, a substituted or unsubstituted arylene group having 6 to 40 carbon atoms, or a substituted or unsubstituted heteroarylene group having 3 to 40 carbon atoms; Ar¹ represents a substituted or unsubstituted divalent aromatic hydrocarbon group having 6 to 40 carbon atoms; and Ar² represents a substituted or unsubstituted aryl group having 6 to 40 carbon atoms, or a substituted or unsubstituted heteroaryl group having 3 to 40 carbon atoms.

HAr is exemplarily selected from the following group.

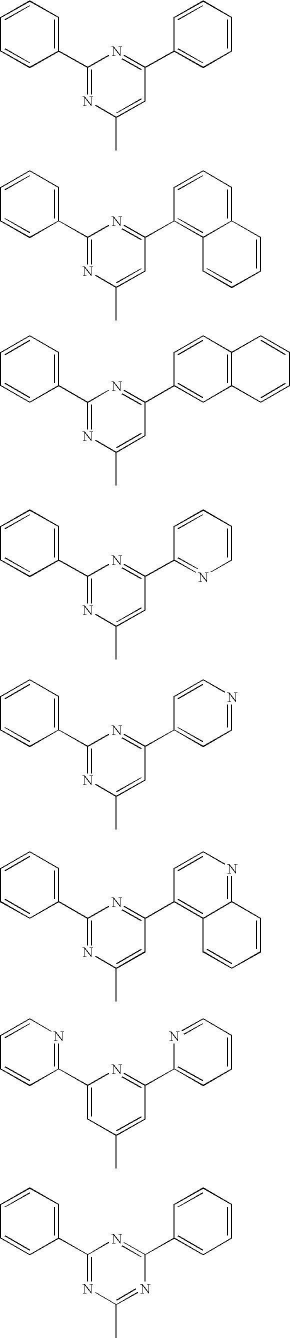

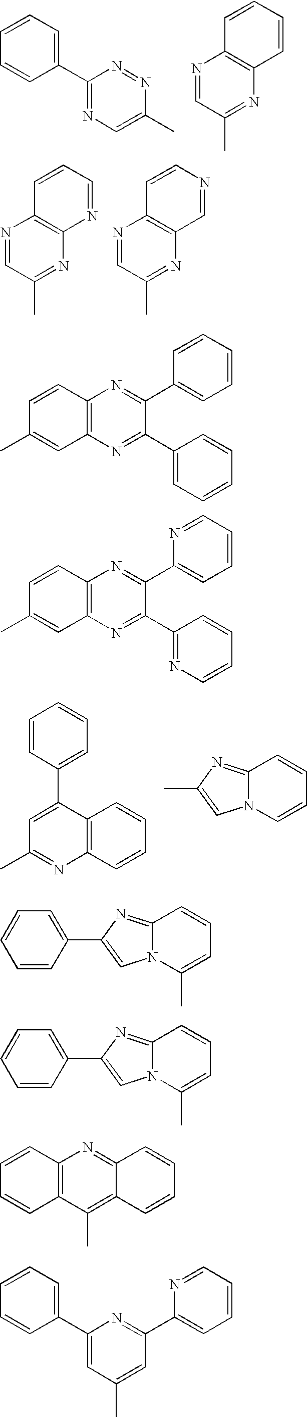

L¹ is exemplarily selected from the following group.

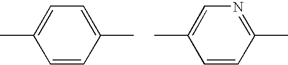

Ar² is exemplarily selected from the following group.

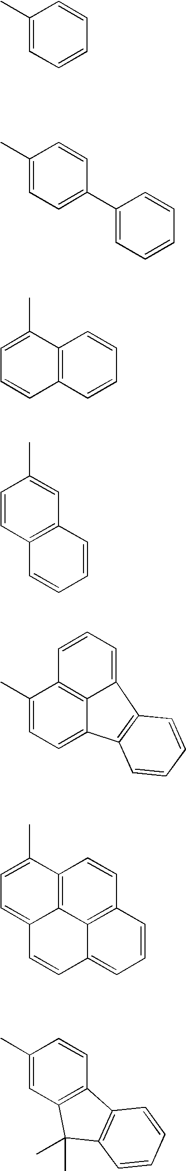

Ar¹ is exemplarily selected from the following arylanthranil groups.

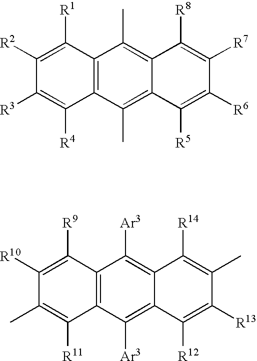

In the formula, R¹ to R¹⁴ each independently represent a hydrogen atom, a halogen atom, an alkyl group having 1 to 20 carbon atoms, an alkoxy group having 1 to 20 carbon atoms, an aryloxy group having 6 to 40 carbon atoms, a substituted or unsubstituted aryl group having 6 to 40 carbon atoms, or a heteroaryl group having 3 to 40 carbon atoms. Ar³ represents a substituted or unsubstituted aryl group having 6 to 40 carbon atoms, or a heteroaryl group having 3 to 40 carbon atoms.

The nitrogen-containing heterocyclic derivative may be a nitrogen-containing heterocyclic derivative in which R¹ to R⁸ in the structure of Ar¹ represented by the above formula each represent a hydrogen atom.

Other than the above, the following compound (see JP-A-9-3448) can be favorably used.

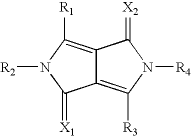

In the formula, R₁ to R₄ each independently represent a hydrogen atom, a substituted or unsubstituted aliphatic group, a substituted or unsubstituted alicyclic group, a substituted or unsubstituted carbocyclic aromatic cyclic group, or substituted or unsubstituted heterocyclic group. X₁ and X₂ each independently represent an oxygen atom, a sulfur atom or a dicyanomethylene group.

Alternatively, the following compound (see JP-A-2000-173774) can also be favorably used.

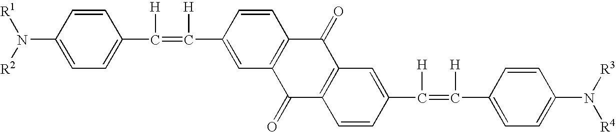

In the formula, R¹, R², R³ and R⁴, which may be mutually the same or different, each are an aryl group represented by the following formula.

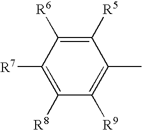

In the formula, R⁵, R⁶, R⁷, R⁸ and R⁹, which may be mutually the same or different, each represent a hydrogen atom, a saturated or unsaturated alkoxyl group, an alkyl group, an amino group or an alkylamino group. At least one of R⁵, R⁶, R⁷, R⁸ and R⁹ represents a saturated or unsaturated alkoxyl group, an alkyl group, an amino group or an alkylamino group.

Examples of the nitrogen-containing heterocyclic derivative are compounds represented by the following formulae (201) to (203).

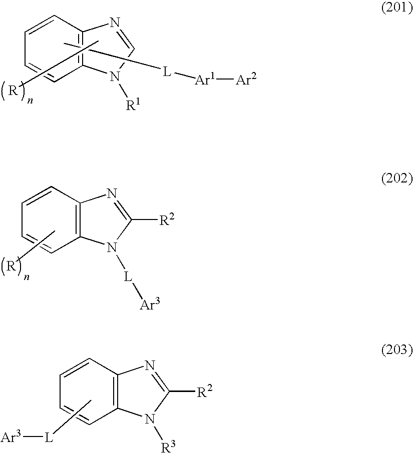

In the formulae (201) to (203): R represents a hydrogen atom, a substituted or unsubstituted aryl group having 6 to 60 carbon atoms, a substituted or unsubstituted pyridyl group, substituted or unsubstituted quinolyl group, a substituted or unsubstituted alkyl group having 1 to 20 carbon atoms, or a substituted or unsubstituted alkoxy group having 1 to 20 carbon atoms; and n represents an integer in a range of 0 to 4.

R¹ represents a substituted or unsubstituted aryl group having 6 to 60 carbon atoms, a substituted or unsubstituted pyridyl group, a substituted or unsubstituted quinolyl group, a substituted or unsubstituted alkyl group having 1 to 20 carbon atoms, or an alkoxy group having 1 to 20 carbon atoms.

R² and R³ each independently represents a hydrogen atom, a substituted or unsubstituted aryl group having 6 to 60 carbon atoms, a substituted or unsubstituted pyridyl group, substituted or unsubstituted quinolyl group, a substituted or unsubstituted alkyl group having 1 to 20 carbon atoms, or a substituted or unsubstituted alkoxy group having 1 to 20 carbon atoms.

L represents a substituted or unsubstituted arylene group having 6 to 60 carbon atoms, a substituted or unsubstituted pyridinylene group, a substituted or unsubstituted quinolinylene group, or a substituted or unsubstituted fluorenylene group.

Ar¹ represents a substituted or unsubstituted arylene group having 6 to 60 carbon atoms, a substituted or unsubstituted pyridinylene group, or a substituted or unsubstituted quinolinylene group.

Ar² represents a substituted or unsubstituted aryl group having 6 to 60 carbon atoms, a substituted or unsubstituted pyridyl group, a substituted or unsubstituted quinolyl group, a substituted or unsubstituted alkyl group having 1 to 20 carbon atoms, or a substituted or unsubstituted alkoxy group having 1 to 20 carbon atoms.

Ar³ represents a substituted or unsubstituted aryl group having 6 to 60 carbon atoms, a substituted or unsubstituted pyridyl group, a substituted or unsubstituted quinolyl group, a substituted or unsubstituted alkyl group having 1 to 20 carbon atoms, a substituted or unsubstituted alkoxy group having 1 to 20 carbon atoms, or a group represented by —Ar¹—Ar² (Ar¹ and Ar² may be the same as the above(—Ar³=—Ar¹—Ar²)).

The substituent for Ar¹, Ar² and Ar³ is preferably an aryl group having 6 to 20 carbon atoms, a pyridyl group, a quinolyl group or an alkyl group.

When L and Ar¹ are asymmetric, either one of substitution sites of Ar¹ and Ar² bonded to L and Ar¹ may be selected.

Since the nitrogen-containing heterocyclic derivative represented by the formulae (201) to (203) each has excellent electron injectability, the electron transporting layer containing the nitrogen-containing heterocyclic derivative can contribute to lowering of voltage of the organic EL device.

By enhancing the electron injectability, a sufficient amount of electrons can be injected into the emitting layer. Thus, it is not necessary to block holes by the electron transporting layer to trap the holes in the emitting layer. Accordingly, unlike a conventional electron injecting/transporting layer formed of BAlq or the like (the electron injecting/transporting layer means at least either one of the electron injecting layer and the electron transporting layer), holes are not concentrated at an interface between the emitting layer and the electron injecting/transporting layer. Thus, the lifetime of the organic EL device can be considerably enhanced.

In the formulae (201) to (203), R represents a hydrogen atom, a substituted or unsubstituted aryl group having 6 to 60 carbon atoms, a substituted or unsubstituted pyridyl group, substituted or unsubstituted quinolyl group, a substituted or unsubstituted alkyl group having 1 to 20 carbon atoms, or a substituted or unsubstituted alkoxy group having 1 to 20 carbon atoms.

The aryl group having 6 to 60 carbon atom is preferably an aryl group having 6 to 40 carbon atoms, more preferably an aryl group having 6 to 20 carbon atoms. Examples of such an aryl group are a phenyl group, naphthyl group, anthryl group, phenanthryl group, naphthacenyl group, chrysenyl group, pyrenyl group, biphenyl group, terphenyl group, tolyl group, t-butylphenyl group, (2-phenylpropyl)phenyl group, fluoranthenyl group, fluorenyl group, a monovalent group formed of spirobifluorene, perfluorophenyl group, perfluoronaphthyl group, perfluoroanthryl group, perfluorobiphenyl group, a monovalent group formed of 9-phenylanthracene, a monovalent group formed of 9-(l′naphthyl)anthracene, a monovalent group formed of 9-(2′-naphthyl)anthracene, a monovalent group formed of 6-phenylchrysene, and a monovalent group formed of 9-[4-(diphenylamine)phenyl]anthracene, among which a phenyl group, naphthyl group, biphenyl group, terphenyl group, 9-(10-phenyl)anthryl group, 9-[10-(1′-naphthyl)]anthryl group and 9-[10-(2′-naphthyl)]anthryl group are preferable.

The alkyl group having 1 to 20 carbon atoms is preferably an alkyl group having 1 to 6 carbon atoms. Examples of such an alkyl group are a methyl group, ethyl group, propyl group, butyl group, pentyl group, hexyl group, and a haloalkyl group such as trifluoromethyl group. When such an alkyl group has 3 or more carbon atoms, the alkyl group may be linear, cyclic or branched.

The alkoxy group having 1 to 20 carbon atoms is preferably an alkoxy group having 1 to 6 carbon atoms. Examples of such an alkoxy group are a methoxy group, ethoxy group, propoxy group, butoxy group, pentyloxy group, and hexyloxy group. When such an alkoxy group has 3 or more carbon atoms, the alkoxy group may be linear, cyclic or branched.

Examples of a substituent for the group represented by R are a halogen atom, a substituted or unsubstituted alkyl group having 1 to 20 carbon atoms, a substituted or unsubstituted alkoxy group having 1 to 20 carbon atoms, a substituted or unsubstituted aryloxy group having 6 to 40 carbon atoms, a substituted or unsubstituted aryl group having 6 to 40 carbon atoms, or a substituted or unsubstituted heteroaryl group having 3 to 40 carbon atoms.

Examples of the halogen atom are fluorine, chlorine, bromine, iodine and the like.

Examples for each of the alkyl group having 1 to 20 carbon atoms, the alkoxy group having 1 to 20 carbon atoms, and an aryl group having 6 to 40 carbon atoms may be the same as the above examples.

Examples of the aryloxy group having 6 to 40 carbon atoms are a phenoxy group and a biphenyloxy group.

Examples of the heteroaryl group having 3 to 40 carbon atoms are a pyrroly group, furyl group, thienyl group, silolyl group, pyridyl group, quinolyl group, isoquinolyl group, benzofuryl group, imidazolyl group, pyrimidyl group, carbazolyl group, selenophenyl group, oxadiazolyl group and triazolyl group.

n is an integer in a range of 0 to 4, preferably 0 to 2.

In the formulae (201), R¹ represents a substituted or unsubstituted aryl group having 6 to 60 carbon atoms, a substituted or unsubstituted pyridyl group, a substituted or unsubstituted quinolyl group, a substituted or unsubstituted alkyl group having 1 to 20 carbon atoms, or an alkoxy group having 1 to 20 carbon atoms.

Examples for each of the groups, the preferable number of carbon atoms contained in each of the groups, and preferable examples of the substituent for each of the groups are the same as those described in relation to R.

In the formulae (202) and (203), R² and R³ each independently represent a hydrogen atom, a substituted or unsubstituted aryl group having 6 to 60 carbon atoms, a substituted or unsubstituted pyridyl group, a substituted or unsubstituted quinolyl group, a substituted or unsubstituted alkyl group having 1 to 20 carbon atoms, or a substituted or unsubstituted alkoxy group having 1 to 20 carbon atoms.

Examples for each of the groups, the preferable number of carbon atoms contained in each of the groups, and preferable examples of the substituent for each of the groups are the same as those described in relation to R.

In the formulae (201) to (203), L represents a substituted or unsubstituted arylene group having 6 to 60 carbon atoms, a substituted or unsubstituted pyridinylene group, a substituted or unsubstituted quinolinylene group, or a substituted or unsubstituted fluorenylene group.

The arylene group having 6 to 60 carbon atoms is preferably an arylene group having 6 to 40 carbon atoms, more preferably an arylene group having 6 to 20 carbon atoms. An example of such an arylene group is a divalent group formed by removing one hydrogen atom from the aryl group having been described in relation to R. Examples of a substituent for the group represented by L are the same as those described in relation to R.

Alternatively, L is preferably a group selected from a group consisting of the following.

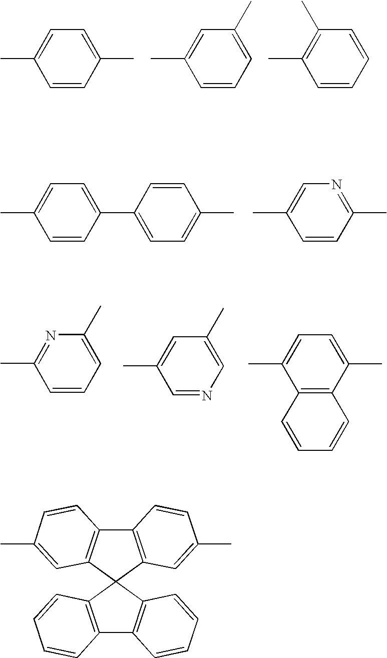

In the formulae (201), Ar¹ represents a substituted or unsubstituted arylene group having 6 to 60 carbon atoms, a substituted or unsubstituted pyridinylene group, or a substituted or unsubstituted quinolinylene group. Examples of a substituent for the groups represented by Ar¹ and Ar³ are the same as those described in relation to R.

Alternatively, Ar¹ is preferably selected from fused cyclic groups respectively represented by the following formulae (101) to (110).

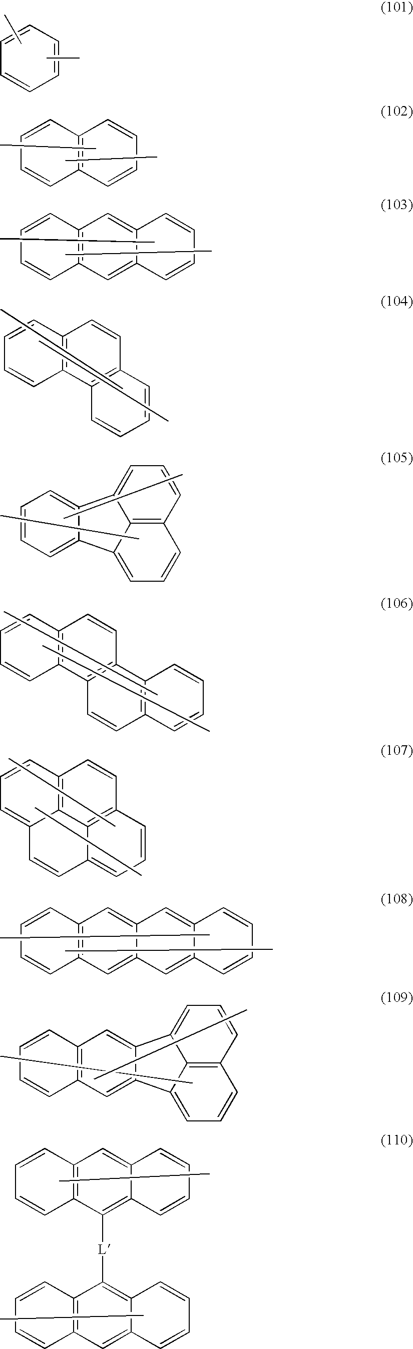

In the formulae (101) to (110), the fused rings each may be linked with a link group formed of a halogen atom, a substituted or unsubstituted alkyl group having 1 to 20 carbon atoms, a substituted or unsubstituted alkoxy group having 1 to 20 carbon atoms, a substituted or unsubstituted aryloxy group having 6 to 40 carbon atoms, a substituted or unsubstituted aryl group having 6 to 40 carbon atoms or a substituted or unsubstituted heteroaryl group having 3 to 40 carbon atoms. When the rings each are linked with plural link groups, the plural link groups may be mutually the same or different. Examples for each of the groups are the same as those described above.

In the formula (110), L′ represents a single bond or a group selected from a group consisting of the following.

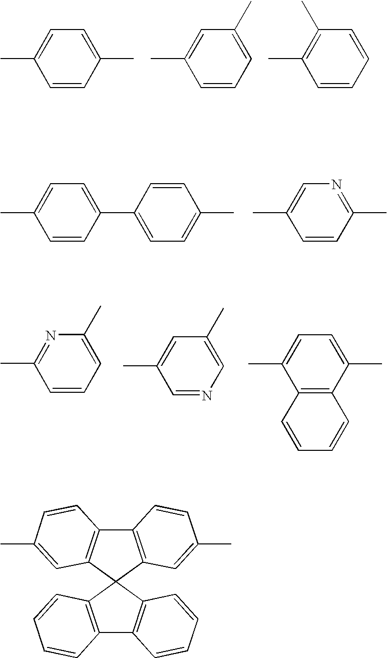

The structure of Ar¹ represented by the formula (103) is preferably a fused cyclic group represented by any one of the following formulae (111) to (125).

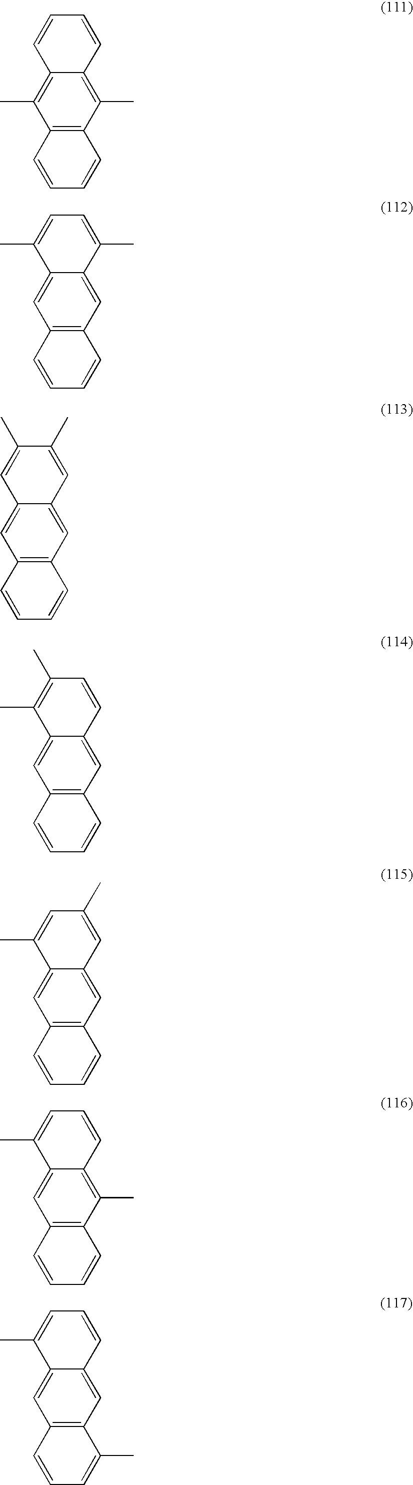

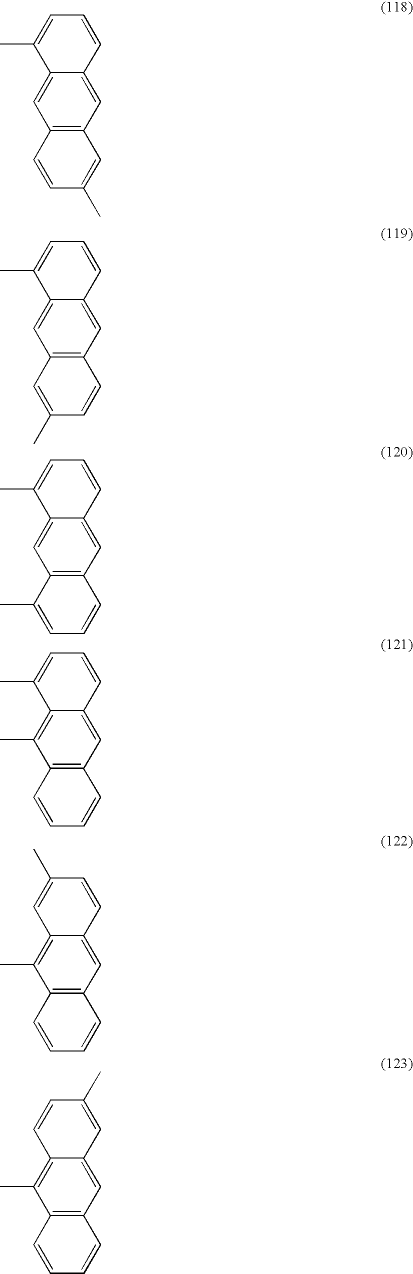

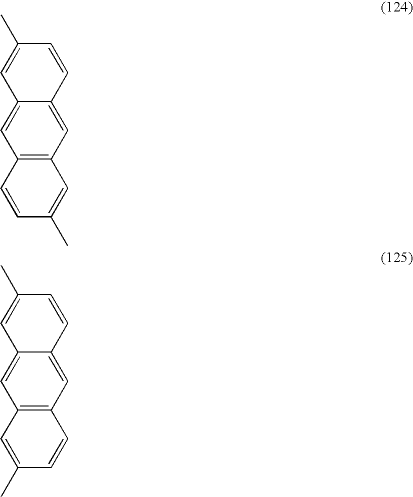

In the formulae (111) to (125), the fused rings each may be linked with a link group formed of a halogen atom, a substituted or unsubstituted alkyl group having 1 to 20 carbon atoms, a substituted or unsubstituted alkoxy group having 1 to 20 carbon atoms, a substituted or unsubstituted aryloxy group having 6 to 40 carbon atoms, a substituted or unsubstituted aryl group having 6 to 40 carbon atoms or a substituted or unsubstituted heteroaryl group having 3 to 40 carbon atoms. When the rings each are linked with plural link groups, the plural link groups may be mutually the same or different. Examples for each of the groups are the same as those described above.

In the formula (201), Ar² represents a substituted or unsubstituted aryl group having 6 to 60 carbon atoms, a substituted or unsubstituted pyridyl group, a substituted or unsubstituted quinolyl group, a substituted or unsubstituted alkyl group having 1 to 20 carbon atoms, or a substituted or unsubstituted alkoxy group having 1 to 20 carbon atoms.

Examples for each of the groups, the preferable number of carbon atoms contained in each of the groups, and preferable examples of the substituent for each of the groups are the same as those described in relation to R.

In the formulae (202) and (203), Ar³ represents a substituted or unsubstituted aryl group having 6 to 60 carbon atoms, a substituted or unsubstituted pyridyl group, a substituted or unsubstituted quinolyl group, a substituted or unsubstituted alkyl group having 1 to 20 carbon atoms, a substituted or unsubstituted alkoxy group having 1 to 20 carbon atoms, or a group represented by —Ar¹—Ar² (Ar¹ and Ar² are the same as the above).

Examples for each of the groups, the preferable number of carbon atoms contained in each of the groups, and preferable examples of the substituent for each of the groups are the same as those described in relation to R.

Alternatively, Ar³ is preferably selected from fused cyclic groups respectively represented by the following formulae (126) to (135).

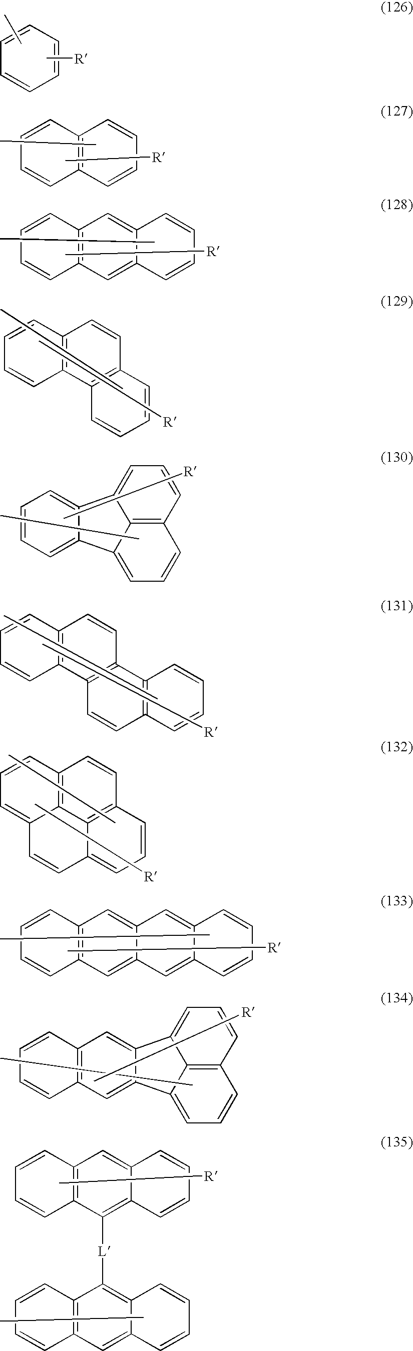

In the formulae (126) to (135), the fused rings each may be linked with a link group formed of a halogen atom, a substituted or unsubstituted alkyl group having 1 to 20 carbon atoms, a substituted or unsubstituted alkoxy group having 1 to 20 carbon atoms, a substituted or unsubstituted aryloxy group having 6 to 40 carbon atoms, a substituted or unsubstituted aryl group having 6 to 40 carbon atoms or a substituted or unsubstituted heteroaryl group having 3 to 40 carbon atoms. When the rings each are linked with plural link groups, the plural link groups may be mutually the same or different. Examples for each of the groups are the same as those described above.

In the formula (135), L′ represents the same as the above.

In the formulae (126) to (135), R′ represents a hydrogen atom, a substituted or unsubstituted alkyl group having 1 to 20 carbon atoms, a substituted or unsubstituted aryl group having 6 to 40 carbon atoms, or a substituted or unsubstituted heteroaryl group having 3 to 40 carbon atoms. Examples for each of the groups are the same as those described above.

The structure of Ar³ represented by the formula (128) is preferably a fused cyclic group represented by any one of the following formulae (136) to (158).

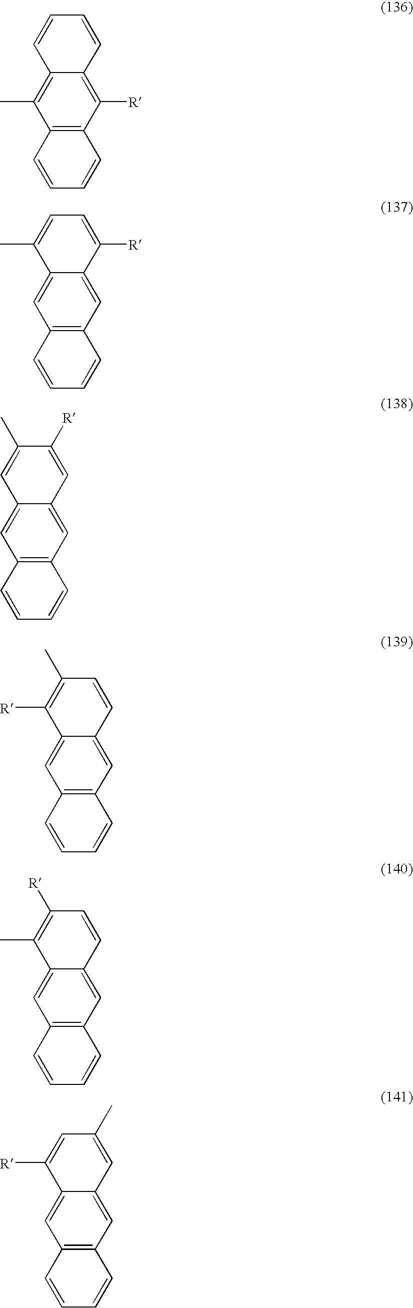

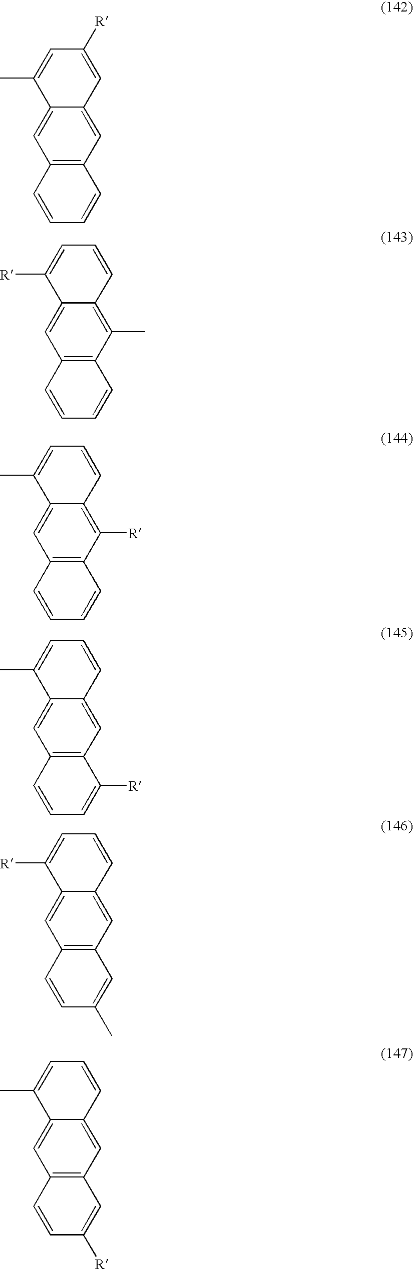

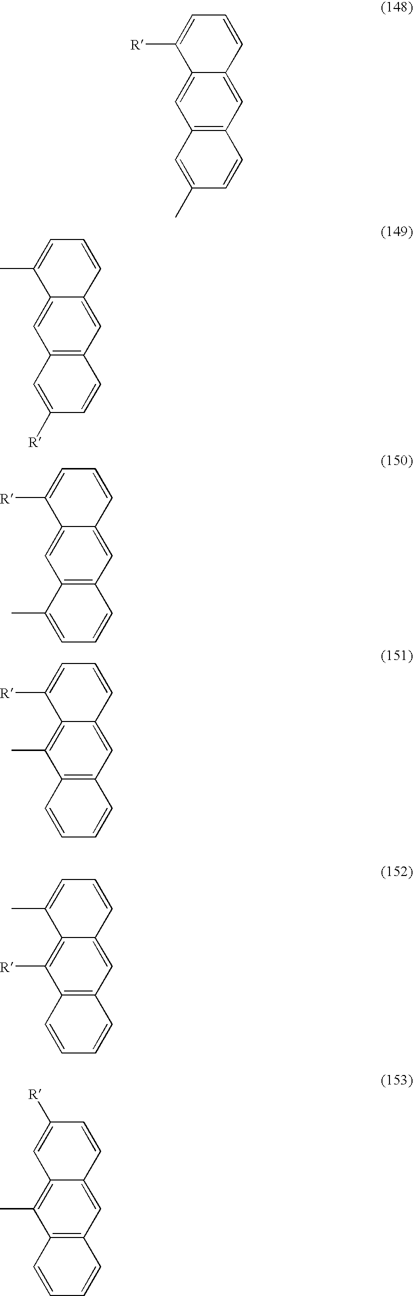

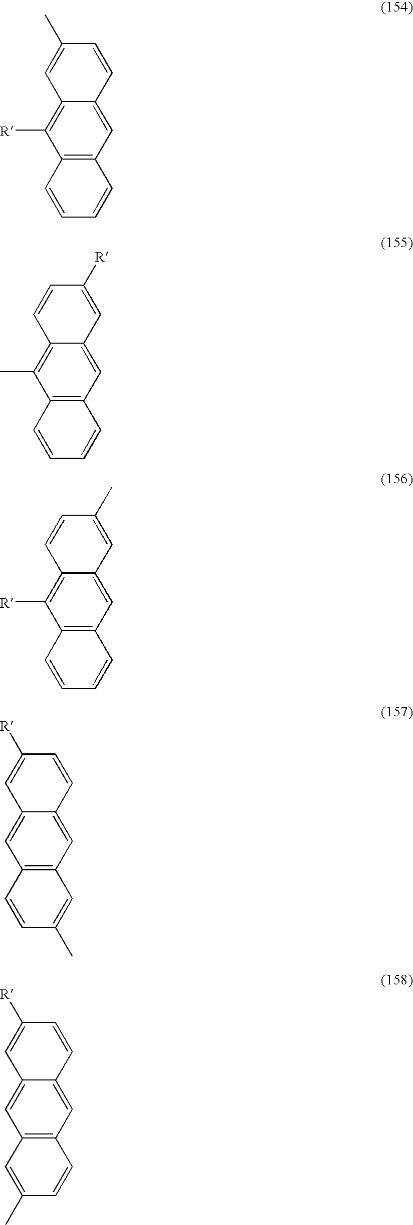

In the formulae (136) to (158), the fused rings each may be linked with a link group formed of a halogen atom, a substituted or unsubstituted alkyl group having 1 to 20 carbon atoms, a substituted or unsubstituted alkoxy group having 1 to 20 carbon atoms, a substituted or unsubstituted aryloxy group having 6 to 40 carbon atoms, a substituted or unsubstituted aryl group having 6 to 40 carbon atoms or a substituted or unsubstituted heteroaryl group having 3 to 40 carbon atoms. When the rings each are linked with plural link groups, the plural link groups may be mutually the same or different. Examples for each of the groups are the same as those described above. R′ is the same as the above.

Alternatively, Ar² and Ar³ each are preferably a group selected from a group consisting of the following.

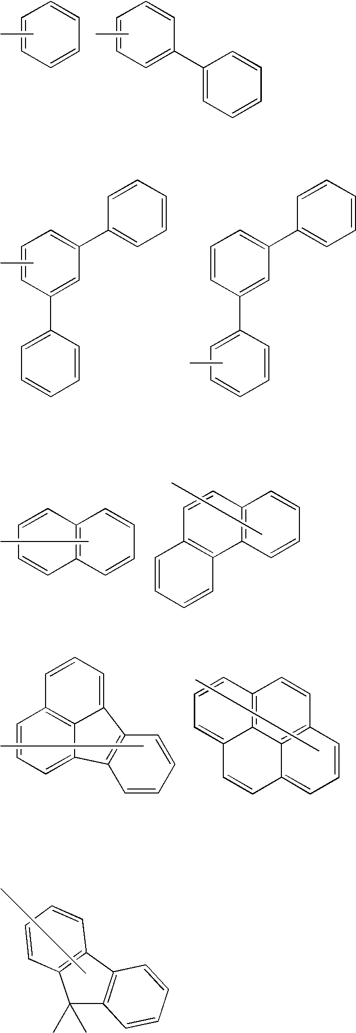

Examples of the nitrogen-containing heterocyclic derivative represented by any one of the formulae (201) to (203) according to the aspect of the invention will be shown below. However, the invention is not limited to the exemplary compounds shown below.

In the chart shown below, HAr represents any one of the following structures respectively in the structures represented by the formulae (201) to (203).

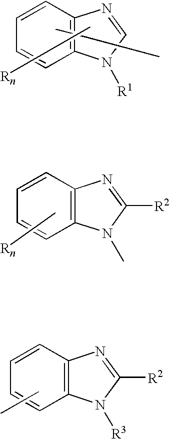

Among the exemplary compounds shown below, the exemplary compounds 1-1 to 1-17, 2-1 to 2-9, 3-1 to 3-6, 4-1 to 4-12, 5-1 to 5-6, 6-1 to 6-5 and 8-1 to 8-13 correspond to the formula (201), the exemplary compounds 9-1 to 9-17, 10-1 to 10-9, 11-1 to 11-6, 12-1 to 12-11, 13-1 to 13-6 and 14-1 to 14-5 correspond to the formula (202), and the exemplary compounds 7-1 to 7-10, 15-1 to 15-13, 16-1 to 16-8 and 17-1 to 17-8 correspond to the formula (203).

HAr—L—Ar¹—Ar²

| | | | |
|---|---|---|---|
| HAr | L | Ar¹ | Ar² |

| | | | | |
|---|---|---|---|---|
| 1-1 | 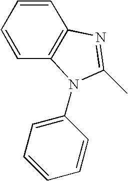 | 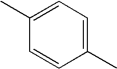 | 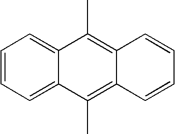 | 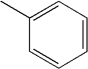 |
| 2 | 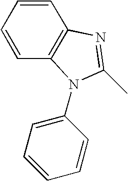 | 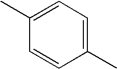 | 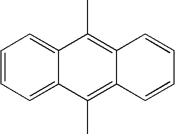 | 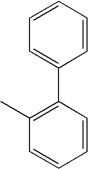 |
| 3 | 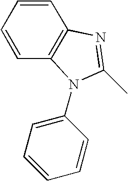 | 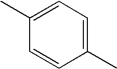 | 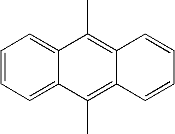 | 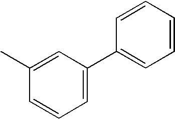 |
| 4 | 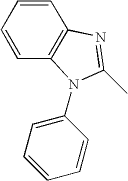 | 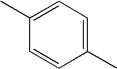 | 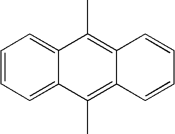 | 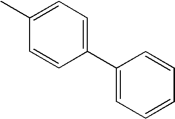 |
| 5 | 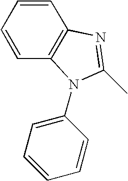 | 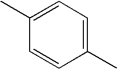 | 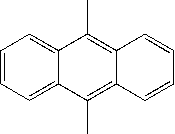 | 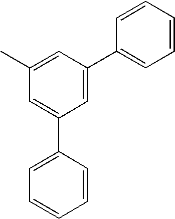 |
| 6 | 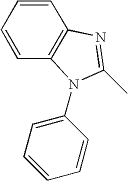 | 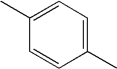 | 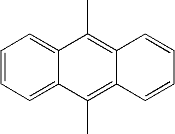 | 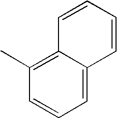 |
| 7 | 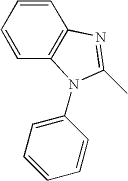 | 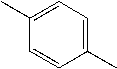 | 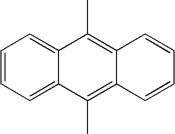 | 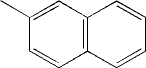 |
| 8 | 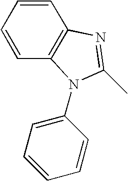 | 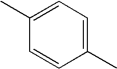 | 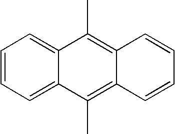 | 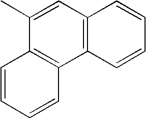 |
| 9 | 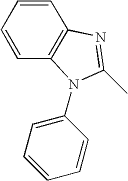 | 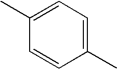 | 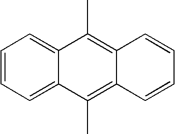 | 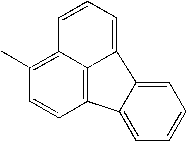 |
| 10 | 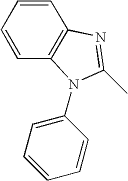 | 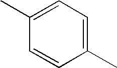 | 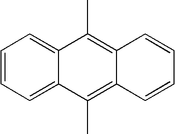 | 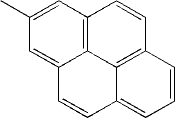 |
| 11 | 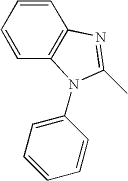 | 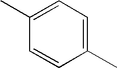 | 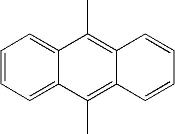 | 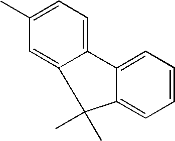 |
| 12 | 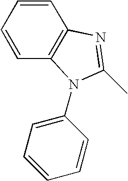 | 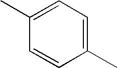 | 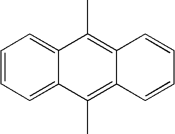 | 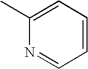 |
| 13 | 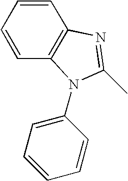 | 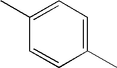 | 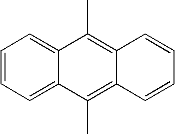 | 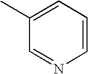 |
| 14 | 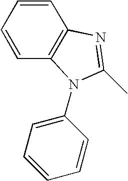 | 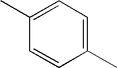 | 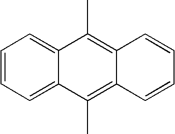 | 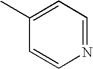 |
| 1-15 | 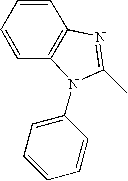 | 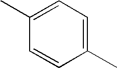 | 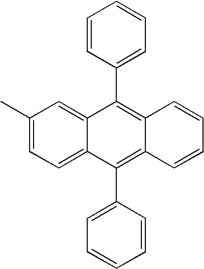 | — |
| 16 | 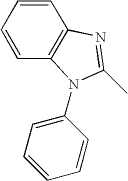 | 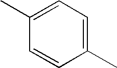 | 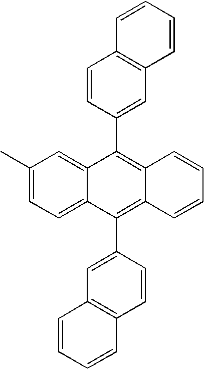 | — |
| 17 | 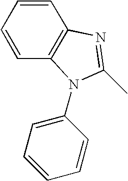 | 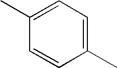 | 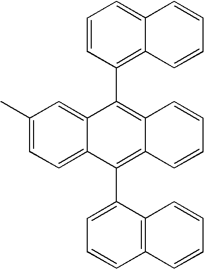 | — |

HAr—L—Ar¹—Ar²

| | HAr | L | Ar¹ | Ar² |
|---|---|---|---|---|
| 2-1 | 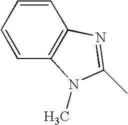 | 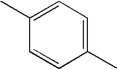 | 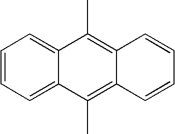 | 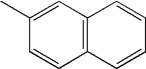 |
| 2 | 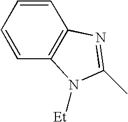 | 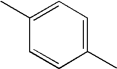 | 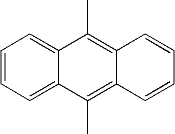 | 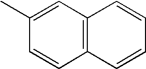 |
| 3 | 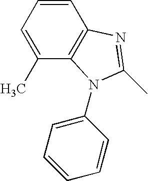 | 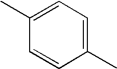 | 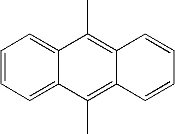 | 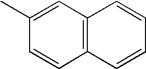 |
| 4 | 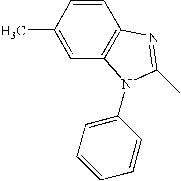 | 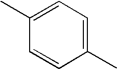 | 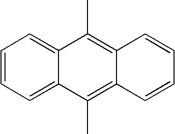 | 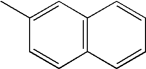 |
| 5 | 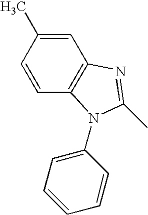 | 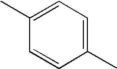 | 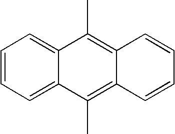 | 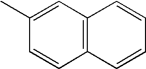 |
| 6 | 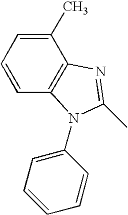 | 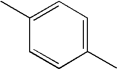 | 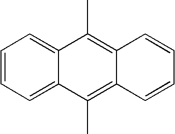 | 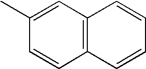 |
| 7 | 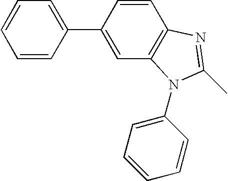 | 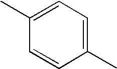 | 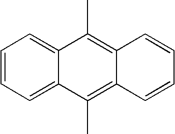 | 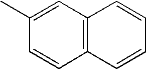 |
| 8 | 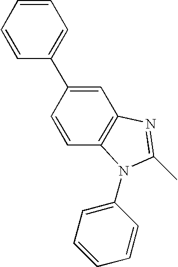 | 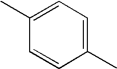 | 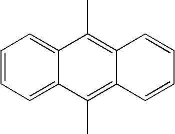 | 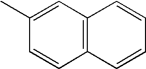 |
| 9 | 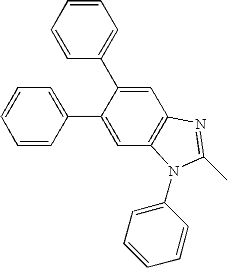 | 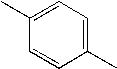 | 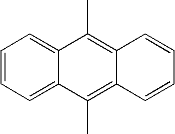 | 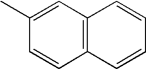 |

HAr—L—Ar¹—Ar²

| | HAr | L | Ar¹ | Ar² |
|---|---|---|---|---|
| 3-1 | 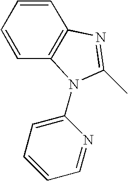 | 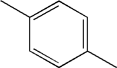 | 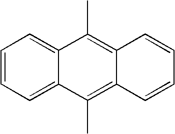 | 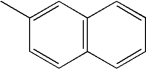 |
| 2 | 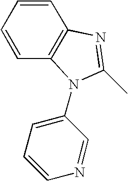 | 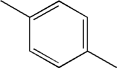 | 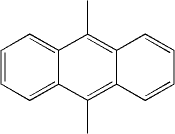 | 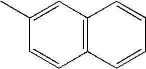 |
| 3 | 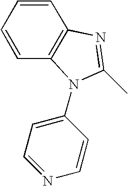 | 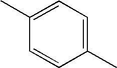 | 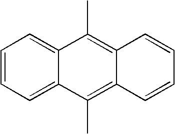 | 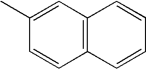 |
| 4 | 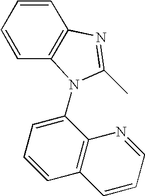 | 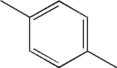 | 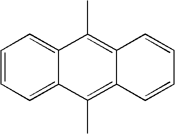 | 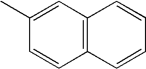 |
| 5 | 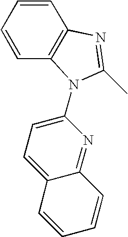 | 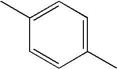 | 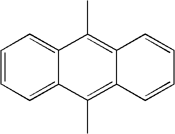 | 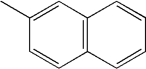 |
| 6 | 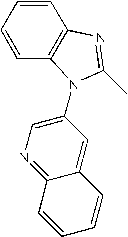 | 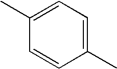 | 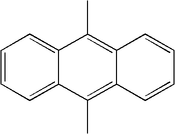 | 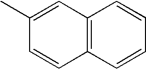 |

HAr—L—Ar¹—Ar²

| | HAr | L | Ar¹ | Ar² |
|---|---|---|---|---|
| 4-1 | 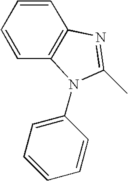 | 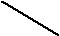 | 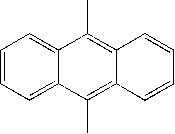 | 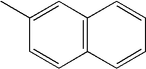 |
| 2 | 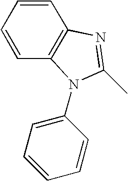 | 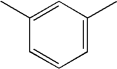 | 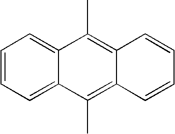 | 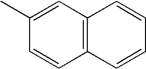 |
| 3 | 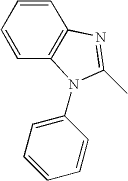 | 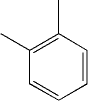 | 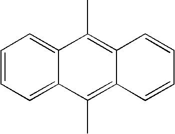 | 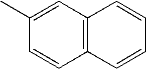 |
| 4 | 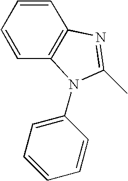 | 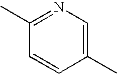 | 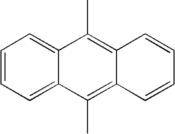 | 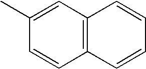 |
| 5 | 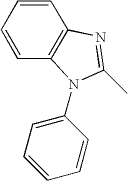 | 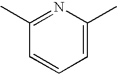 | 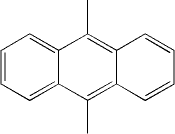 | 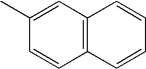 |
| 6 | 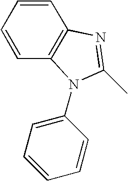 | 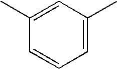 | 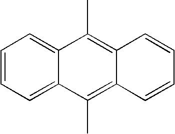 | 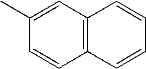 |
| 7 | 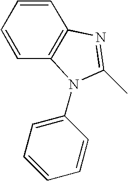 | 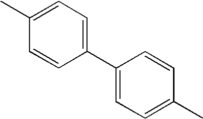 | 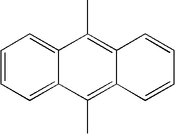 | 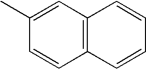 |
| 8 | 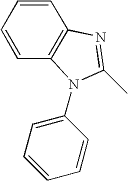 | 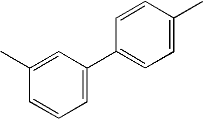 | 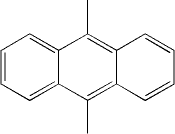 | 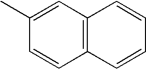 |
| 9 | 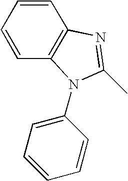 | 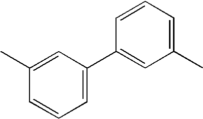 | 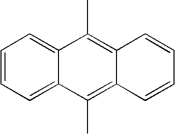 | 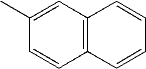 |
| 10 | 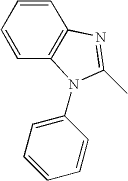 | 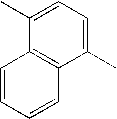 | 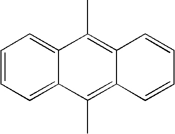 | 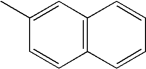 |
| 11 | 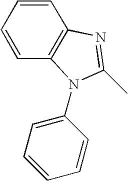 | 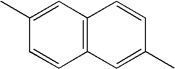 | 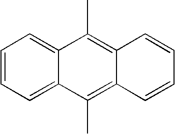 | 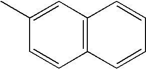 |
| 12 | 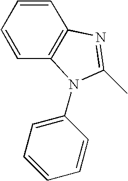 | 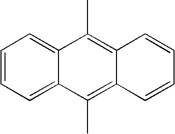 | 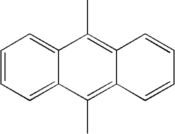 | 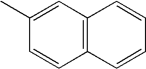 |

HAr—L—Ar¹—Ar²

| | HAr | L | Ar¹ | Ar² |
|---|---|---|---|---|
| 5-1 | 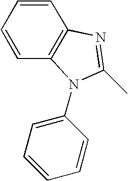 | 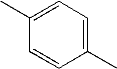 | 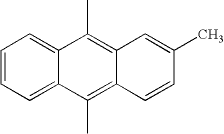 | 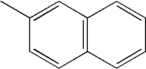 |
| 2 | 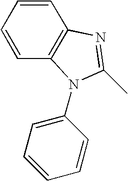 | 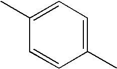 | 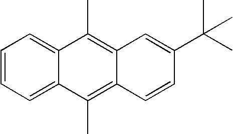 | 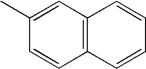 |
| 3 | 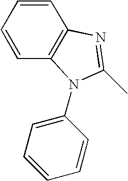 | 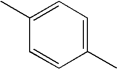 | 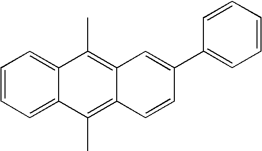 | 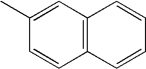 |
| 4 | 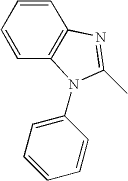 | 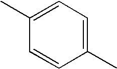 | 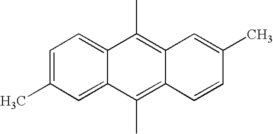 | 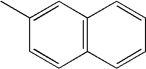 |
| 5 | 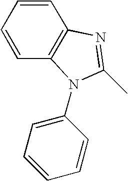 | 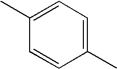 | 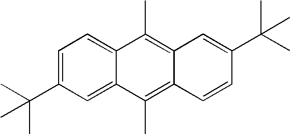 | 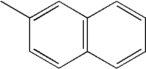 |
| 6 | 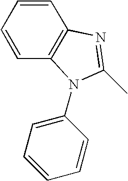 | 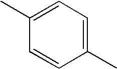 | 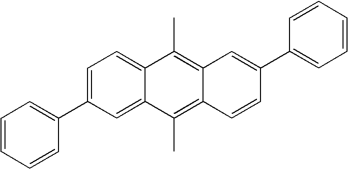 | 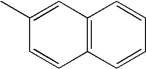 |

HAr—L—Ar¹—Ar²

| | HAr | L | Ar¹ | Ar² |
|---|---|---|---|---|
| 6-1 | 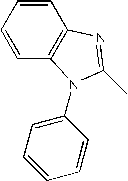 | 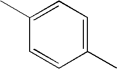 | 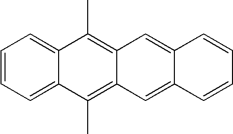 | 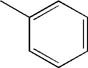 |
| 2 | 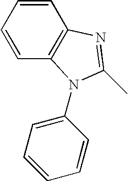 | 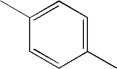 | 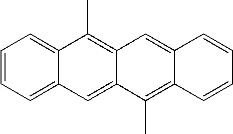 | 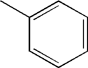 |
| 3 | 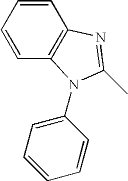 | 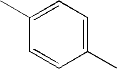 | 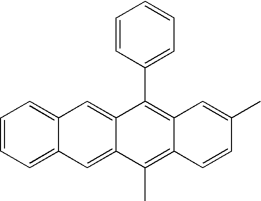 | 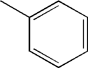 |
| 4 | 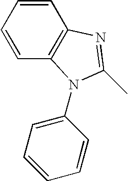 | 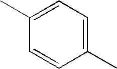 | 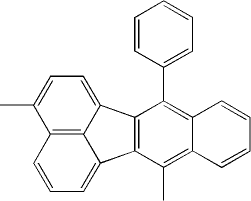 | 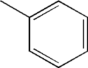 |
| 5 | 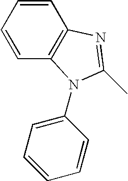 | 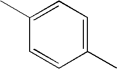 | 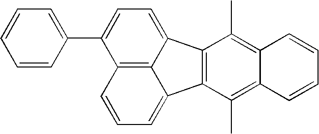 | 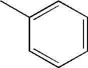 |

HAr—L—Ar³ (—Ar³═Ar¹—Ar²)

| | HAr | L | Ar¹ | Ar² |
|---|---|---|---|---|
| 7-1 | 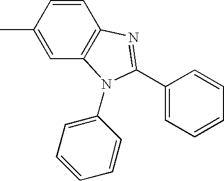 | 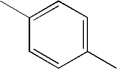 | 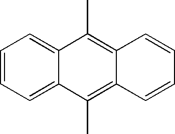 | 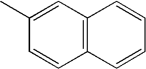 |
| 2 | 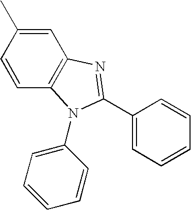 | 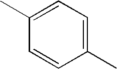 | 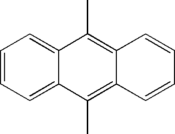 | 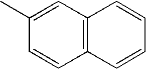 |
| 3 | 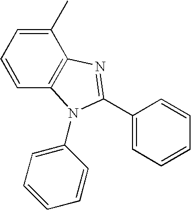 | 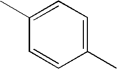 | 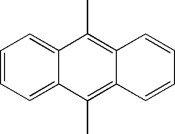 | 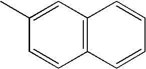 |
| 4 | 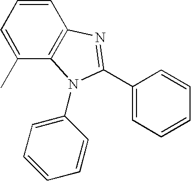 | 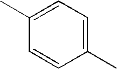 | 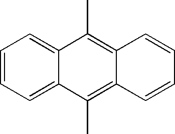 | 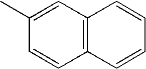 |
| 5 | 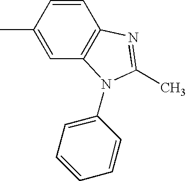 | 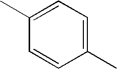 | 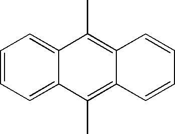 | 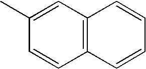 |
| 6 | 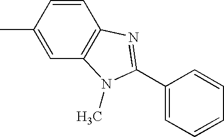 | 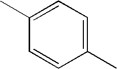 | 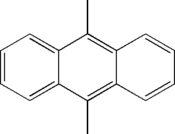 | 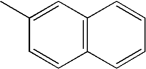 |
| 7 | 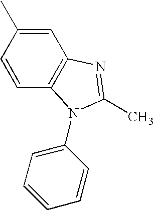 | 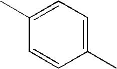 | 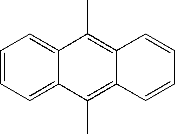 | 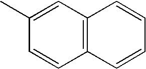 |
| 8 | 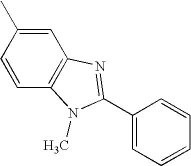 | 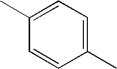 | 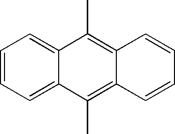 | 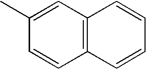 |
| 9 | 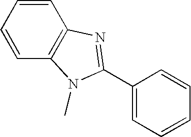 | 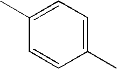 | 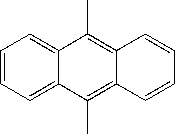 | 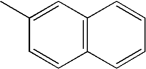 |
| 10 | 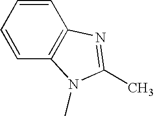 | 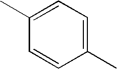 | 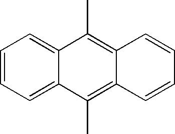 | 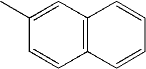 |

HAr—L—Ar¹—Ar²

| | HAr | L | Ar¹ | Ar² |
|---|---|---|---|---|
| 8-1 | 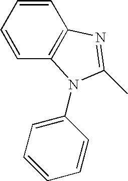 | 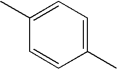 | 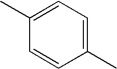 | 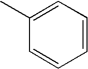 |
| 2 | 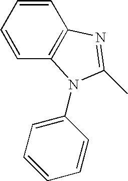 | 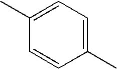 | 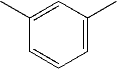 | 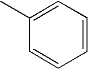 |
| 3 | 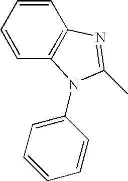 | 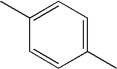 | 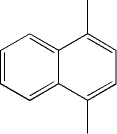 | 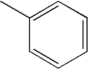 |
| 4 | 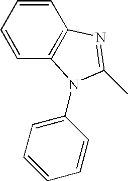 | 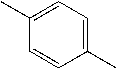 | 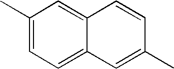 | 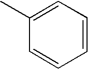 |
| 5 | 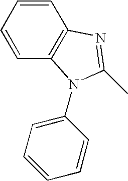 | 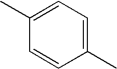 | 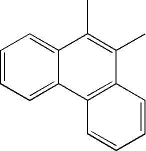 | 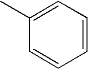 |
| 6 | 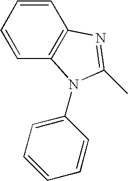 | 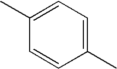 | 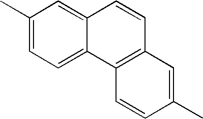 | 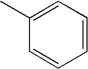 |
| 7 | 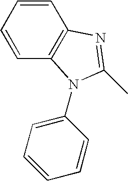 | 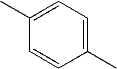 | 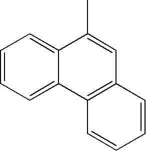 | 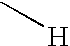 |
| 8 | 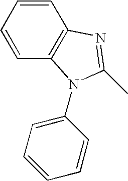 | 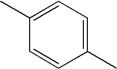 | 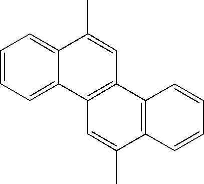 | 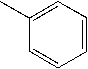 |
| 9 | 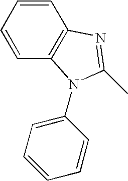 | 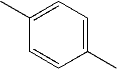 | 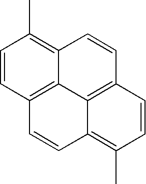 | 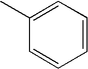 |
| 10 | 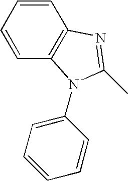 | 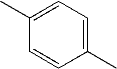 | 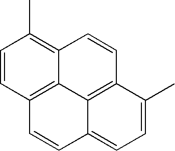 | 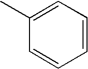 |
| 11 | 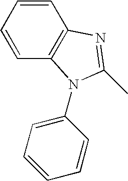 | 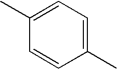 | 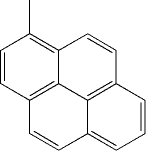 | 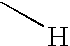 |
| 12 | 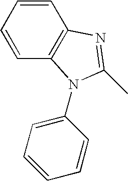 | 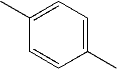 | 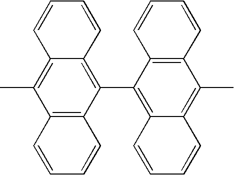 | 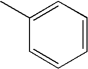 |
| 13 | 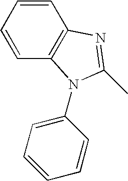 | 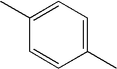 | 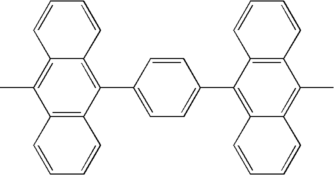 | 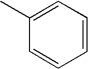 |

HAr—L—Ar³ —(Ar³ ═—Ar¹—Ar²)

| | HAr | L | Ar¹ | Ar² |
|---|---|---|---|---|
| 9-1 | 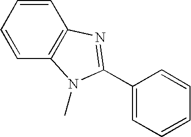 | 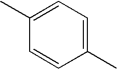 | 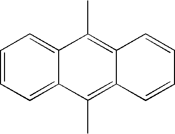 | 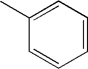 |
| 2 | 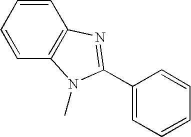 | 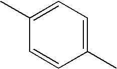 | 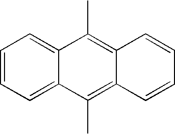 | 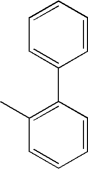 |
| 3 | 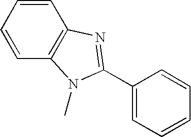 | 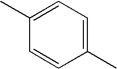 | 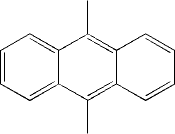 | 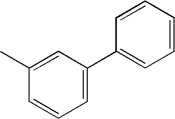 |
| 4 | 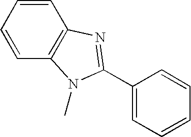 | 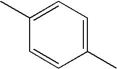 | 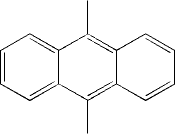 | 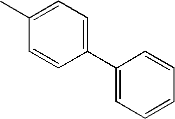 |
| 5 | 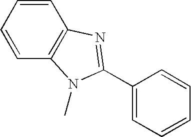 | 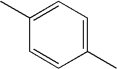 | 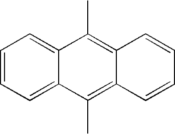 | 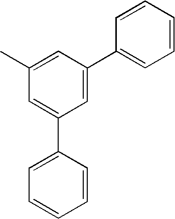 |
| 6 | 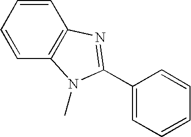 | 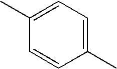 | 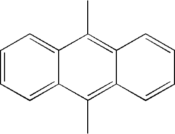 | 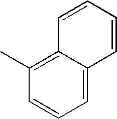 |
| 7 | 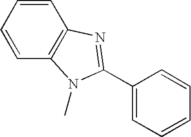 | 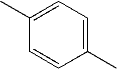 | 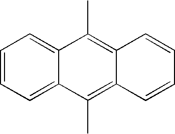 | 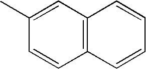 |
| 8 | 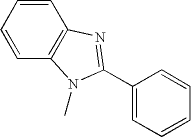 | 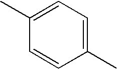 | 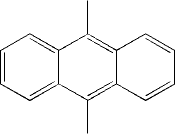 | 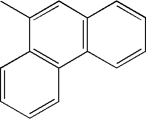 |
| 9 | 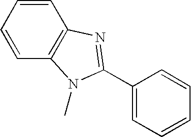 | 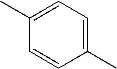 | 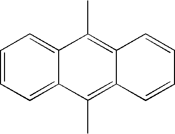 | 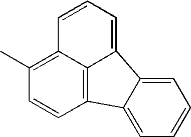 |
| 10 | 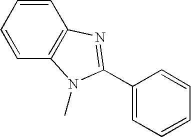 | 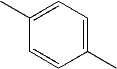 | 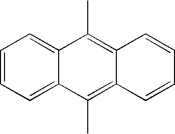 | 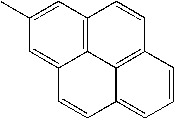 |
| 11 | 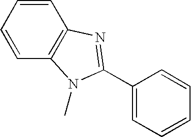 | 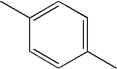 | 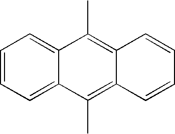 | 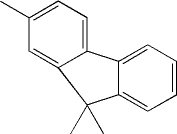 |
| 12 | 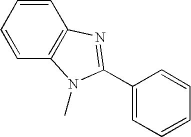 | 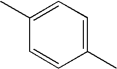 | 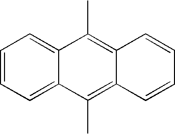 | 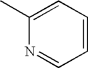 |
| 13 | 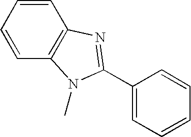 | 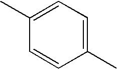 | 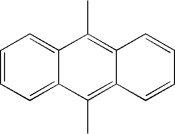 | 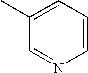 |
| 14 | 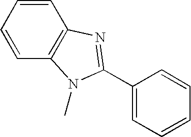 | 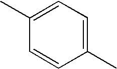 | 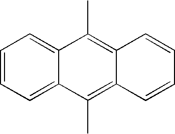 | 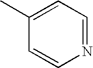 |
| 9-15 | 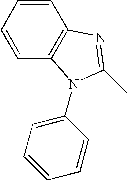 | 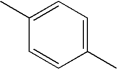 | 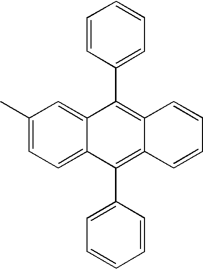 | — |
| 16 | 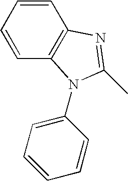 | 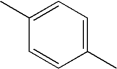 | 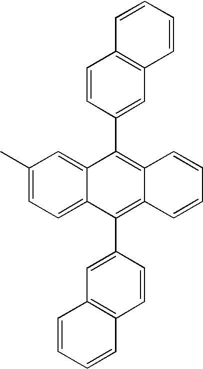 | — |
| 17 | 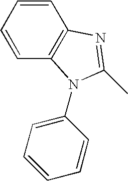 | 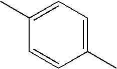 | 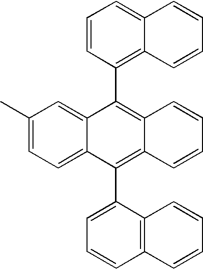 | — |

HAr—L—Ar³ (—Ar³═—Ar¹—Ar²)

| | HAr | L | Ar¹ | Ar² |
|---|---|---|---|---|
| 10-1 | 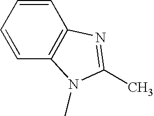 | 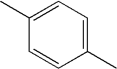 | 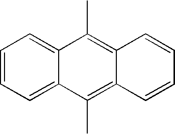 | 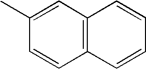 |
| 2 | 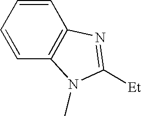 | 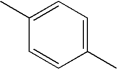 | 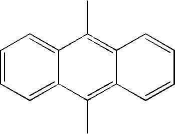 | 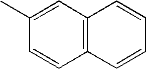 |
| 3 | 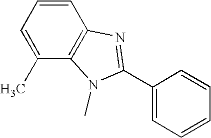 | 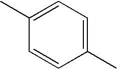 | 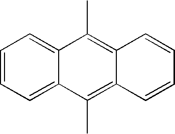 | 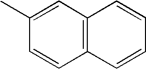 |
| 4 | 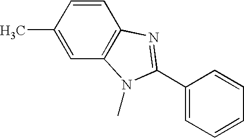 | 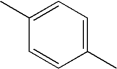 | 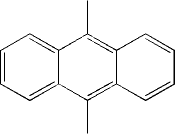 | 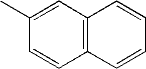 |
| 5 | 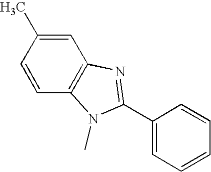 | 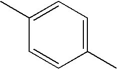 | 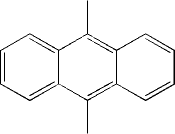 | 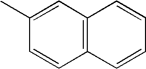 |
| 6 | 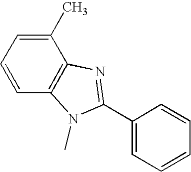 | 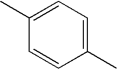 | 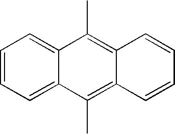 | 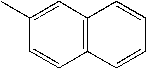 |
| 7 | 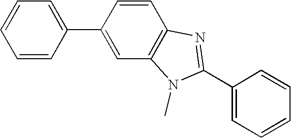 | 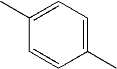 | 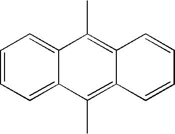 | 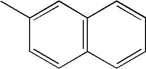 |
| 8 | 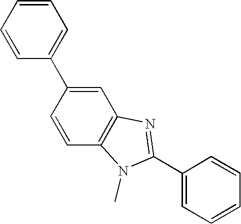 | 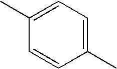 | 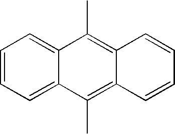 | 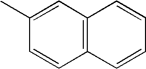 |
| 9 | 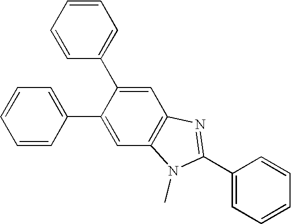 | 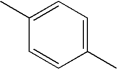 | 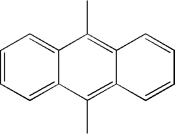 | 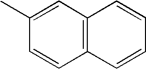 |

HAr—L—Ar³ (—Ar³═—Ar¹—Ar²)

| | HAr | L | Ar¹ | Ar² |
|---|---|---|---|---|
| 11-1 | 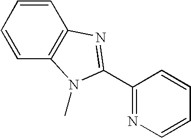 | 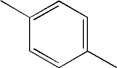 | 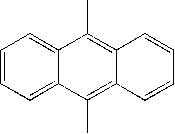 | 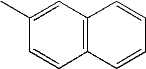 |
| 2 | 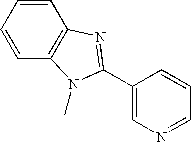 | 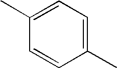 | 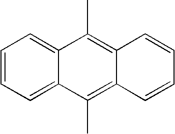 | 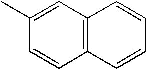 |
| 3 | 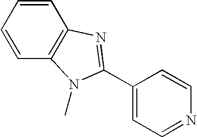 | 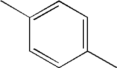 | 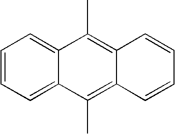 | 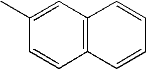 |
| 4 | 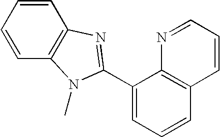 | 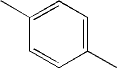 | 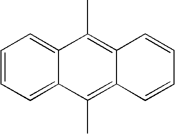 | 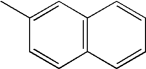 |
| 5 | 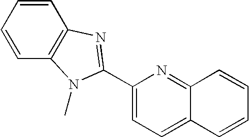 | 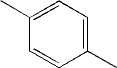 | 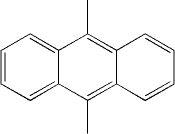 | 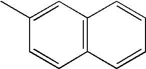 |
| 6 | 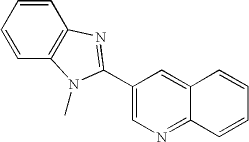 | 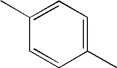 | 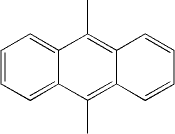 | 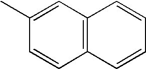 |

HAr—L—Ar³ (—Ar³═—Ar¹—Ar²)

| | HAr | L | Ar¹ | Ar² |
|---|---|---|---|---|
| 12-1 | 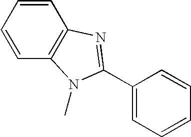 | 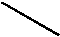 | 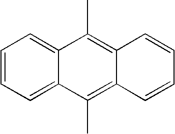 | 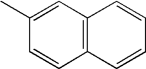 |
| 2 | 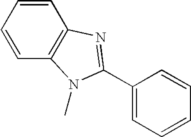 | 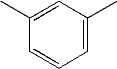 | 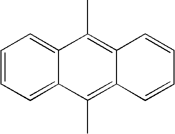 | 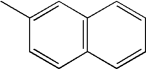 |
| 3 | 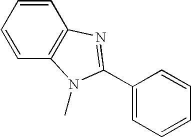 | 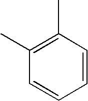 | 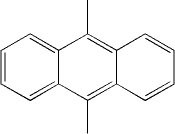 | 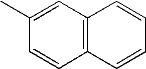 |
| 4 | 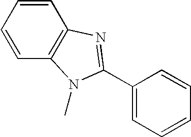 | 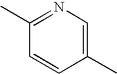 | 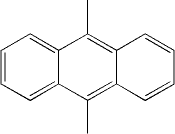 | 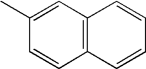 |
| 5 | 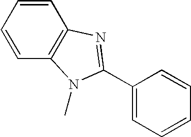 | 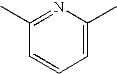 | 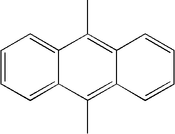 | 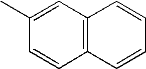 |
| 6 | 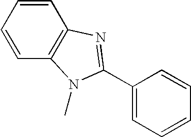 | 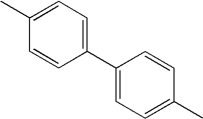 | 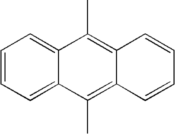 | 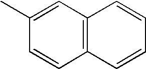 |
| 7 | 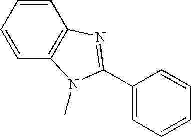 | 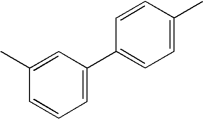 | 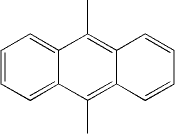 | 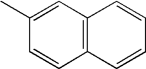 |
| 8 | 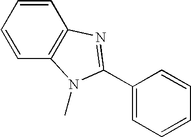 | 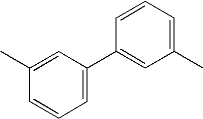 | 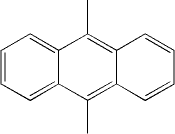 | 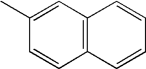 |
| 9 | 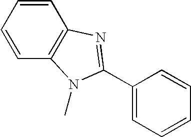 | 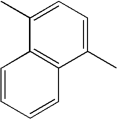 | 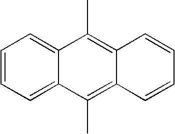 | 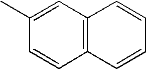 |
| 10 | 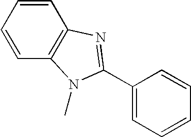 | 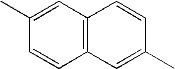 | 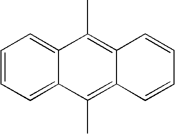 | 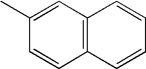 |
| 11 | 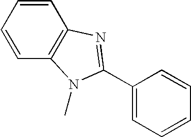 | 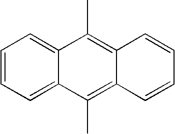 | 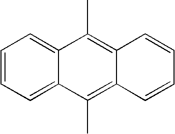 | 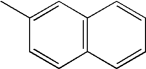 |

HAr—L—Ar³ (—Ar³═—Ar¹—Ar²)

| | HAr | L | Ar¹ | Ar² |
|---|---|---|---|---|
| 13-1 | 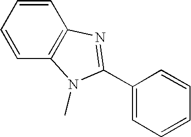 | 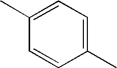 | 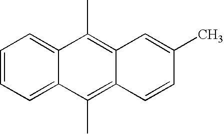 | 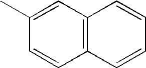 |
| 2 | 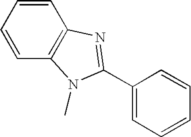 | 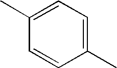 | 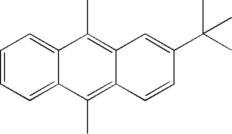 | 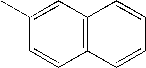 |
| 3 | 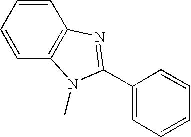 | 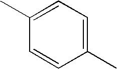 | 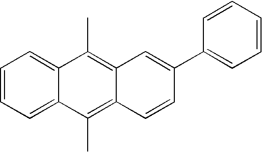 | 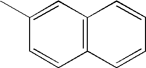 |
| 4 | 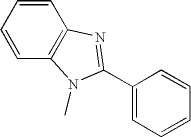 | 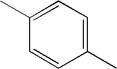 | 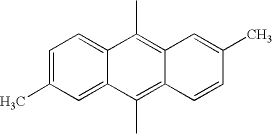 | 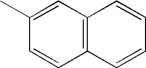 |
| 5 | 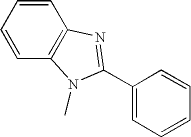 | 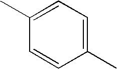 | 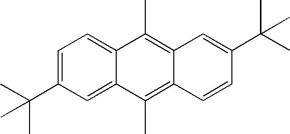 | 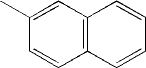 |
| 6 | 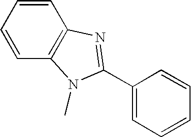 | 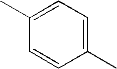 | 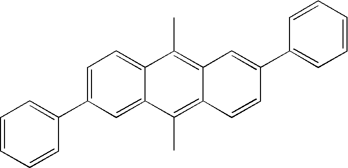 | 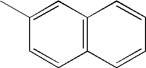 |

HAr—L—Ar³ (—Ar³═—Ar¹—Ar²)

| | HAr | L | Ar¹ | Ar² |
|---|---|---|---|---|
| 14-1 | 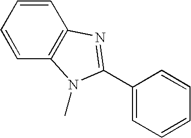 | 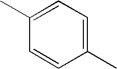 | 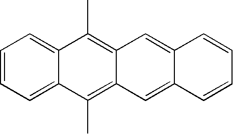 | 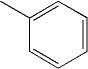 |
| 2 | 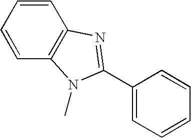 | 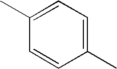 | 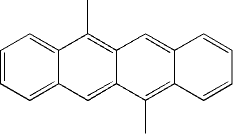 | 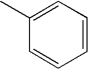 |
| 3 | 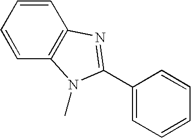 | 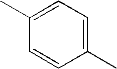 | 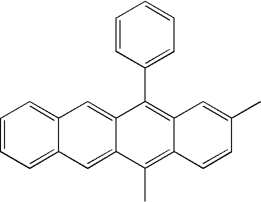 | 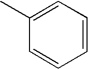 |
| 4 | 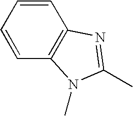 | 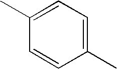 | 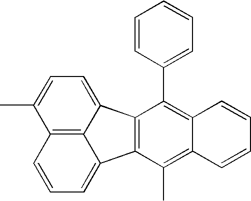 | 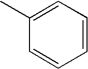 |
| 5 | 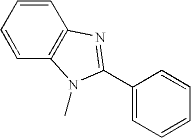 | 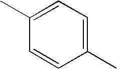 | 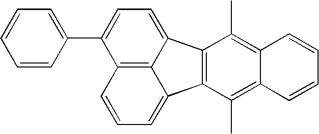 | 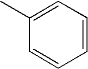 |

HAr—L—Ar³ (—Ar³═—Ar¹—Ar²)

| | HAr | L | Ar¹ | Ar² |
|---|---|---|---|---|
| 15-1 | 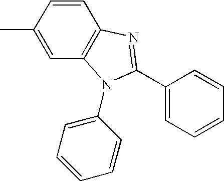 | 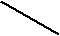 | 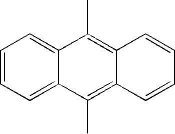 | 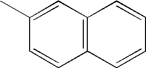 |
| 2 | 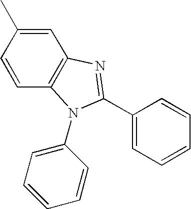 | 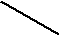 | 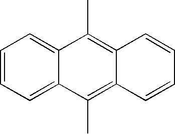 | 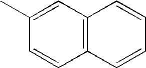 |
| 3 | 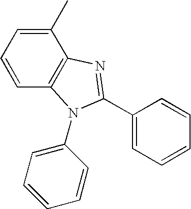 | 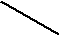 | 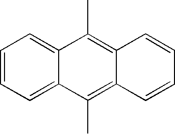 | 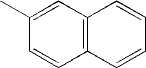 |
| 4 | 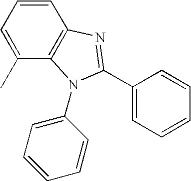 | 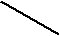 | 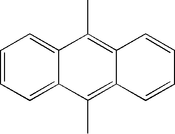 | 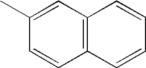 |
| 5 | 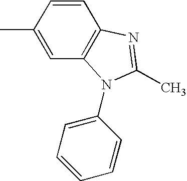 | 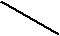 | 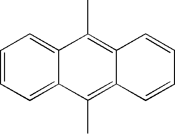 | 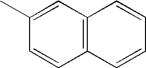 |
| 6 | 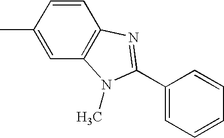 | 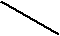 | 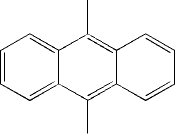 | 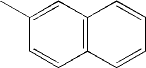 |
| 7 | 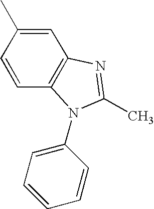 | 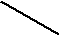 | 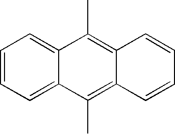 | 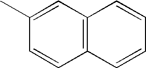 |
| 8 | 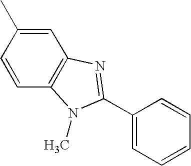 | 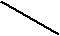 | 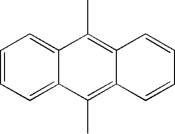 | 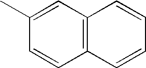 |
| 9 | 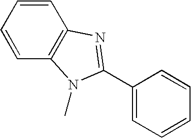 | 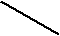 | 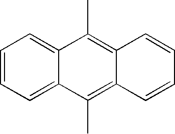 | 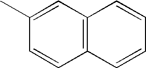 |
| 10 | 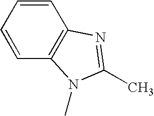 | 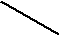 | 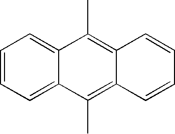 | 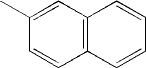 |
| 15-11 | 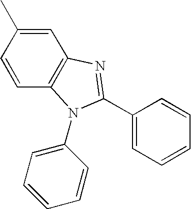 | 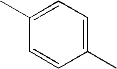 | 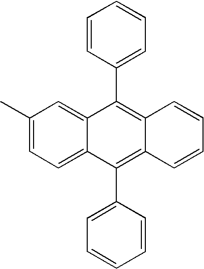 | — |
| 12 | 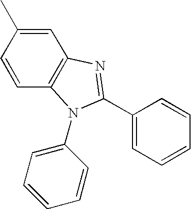 | 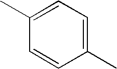 | 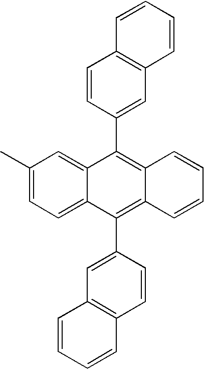 | — |
| 13 | 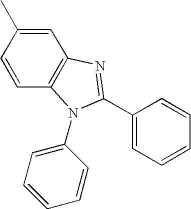 | 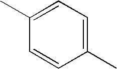 | 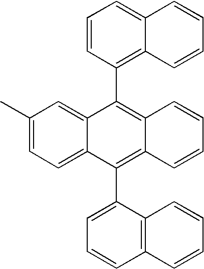 | — |

HAr—L—Ar³ (—Ar³═—Ar¹—Ar²)

| | HAr | L | Ar¹ | Ar² |
|---|---|---|---|---|
| 16-1 | 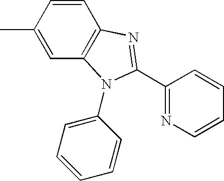 | 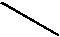 | 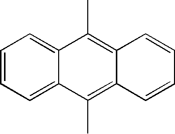 | 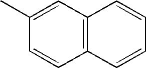 |
| 2 | 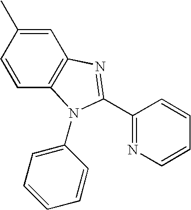 | 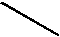 | 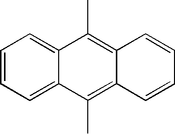 | 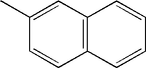 |
| 3 | 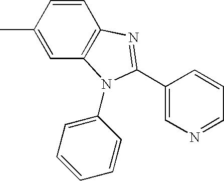 | 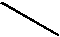 | 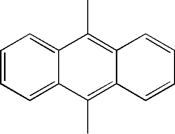 | 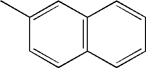 |
| 4 | 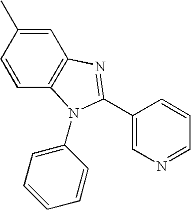 | 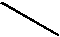 | 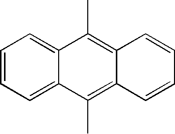 | 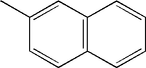 |
| 5 | 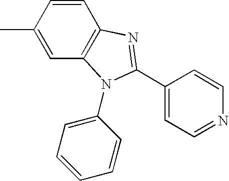 | 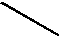 | 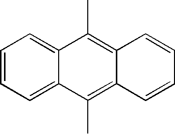 | 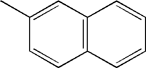 |
| 6 | 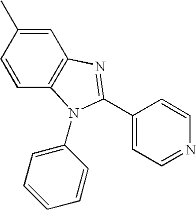 | 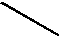 | 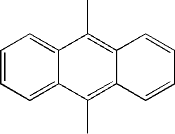 | 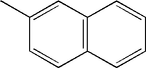 |
| 7 | 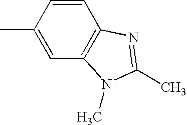 | 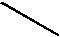 | 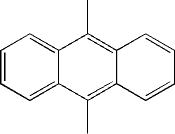 | 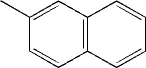 |
| 8 | 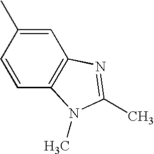 | 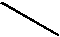 | 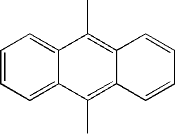 | 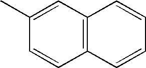 |

HAr—L—Ar³ (—Ar³═—Ar¹—Ar²)

| | HAr | L | Ar¹ | Ar² |
|---|---|---|---|---|
| 17-1 | 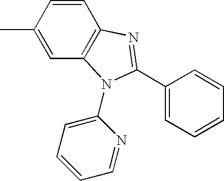 | 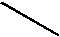 | 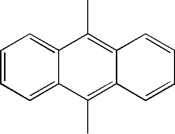 | 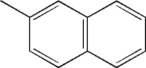 |
| 2 | 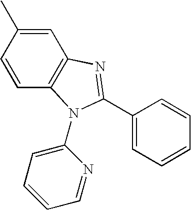 | 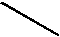 | 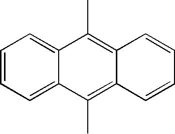 | 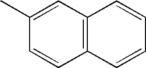 |
| 3 | 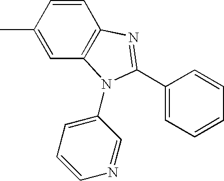 | 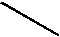 | 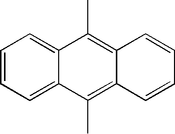 | 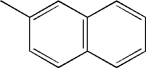 |
| 4 | 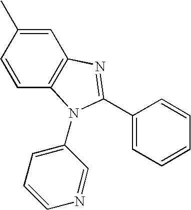 | 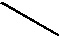 | 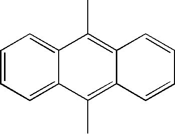 | 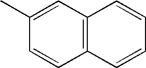 |
| 5 | 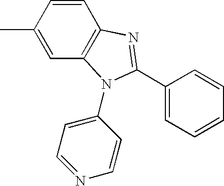 | 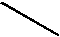 | 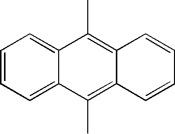 | 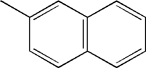 |
| 6 | 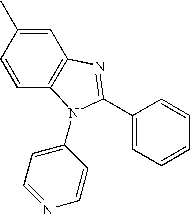 | 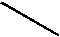 | 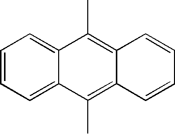 | 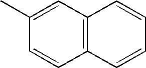 |
| 7 | 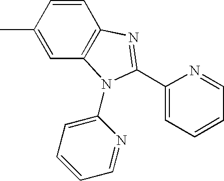 | 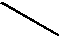 | 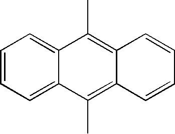 | 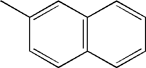 |
| 8 | 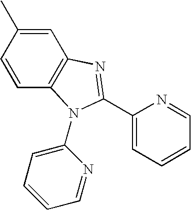 | 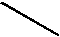 | 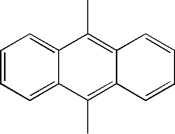 | 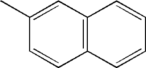 |

Among the above examples, the compounds (1-1), (1-5), (1-7), (2-1), (3-1), (4-2), (4-6), (7-2), (7-7), (7-8), (7-9) and (9-7) are particularly preferred.

A polymer compound containing the nitrogen-containing heterocyclic group or a nitrogen-containing heterocyclic derivative may be used.

Although thickness of the electron injecting layer or the electron transporting layer is not specifically limited, the thickness is preferably 1 to 100 nm.

An organic-EL-material-containing solution according to another aspect of the invention is for forming the emitting layer in the above-described organic EL device, the solution containing: a solvent; the first polycyclic fused aromatic compound dissolved in the solvent; and the first phosphorescent material dissolved in the solvent. An organic-EL-material-containing solution according to still further aspect of the invention is for forming the organic layer in the above-described organic EL device, the solution containing: a solvent; the second polycyclic fused aromatic compound dissolved in the solvent; and the second phosphorescent material dissolved in the solvent.

When an organic layer not containing the second phosphorescent material is to be formed, the organic-EL-material-containing solution according to the aspect of the invention does not contain the second phosphorescent material.

According to the organic-EL-material-containing solution, the above-described mixed-color emitting layer can be easily formed into film(s) with low cost by a coating method such as ink printing and nozzle jetting.

Examples of the solvent for the organic-EL-material-containing solution are alcohols such as methanol and ethanol, carboxylate esters such as ethyl acetate and propyl acetate, nitriles such as acetonitrile, ethers such as isopropyl ether and THF, aromatic hydrocarbons such as cyclohexylbenzene, toluene and xylene, alkyl halides such as methylene chloride, saturated hydrocarbon such as heptane, biphenyl derivative and cyclic ketone.

The biphenyl derivative is exemplarily alkyl-substituted biphenyl, examples of which are methylbiphenyl, ethylbiphenyl, diethylbiphenyl, isopropylbiphenyl, diisopropylbiphenyl, n-propylbiphenyl, n-pentylbiphenyl and methoxybiphenyl.

The alkyl group of the alkyl-substituted biphenyl more preferably has 1 to 5 carbon atoms. When the alkyl group has 1 to 5 carbon atoms, viscosity and solubility can be suitably balanced. For instance, materials such as ethylbiphenyl and isopropylbiphenyl are favorably usable as the solvent for the organic-EL-material-containing solution according to the aspect of the invention.

With respect to the composition of the solvent, 100% of the solvent may be formed of a biphenyl derivative, or the solvent may be a mixture solution in which a viscosity control reagent and the like are mixed.

When such a mixture solution is used, 20% or more of the solvent may be formed of a biphenyl derivative, 50% or more of the solvent may be formed of a biphenyl derivative, or 75% or more of the solvent may be formed of a biphenyl derivative. In order to take advantage of the viscosity and the solubility of a biphenyl derivative, a biphenyl derivative is preferably contained at a higher proportion.

Examples of the cyclic ketone are cyclic alkyl ketones such as a cyclopentanone derivative, a cyclohexanone derivative, a cycloheptanone derivative and a cyclooctanone derivative. The above cyclic ketone may be singularly used or a plurality thereof may be mixed together in use. Particularly, the solvent preferably contains a cyclohexanone derivative as the cyclic ketone.

Preferable examples of the cyclohexanone derivative are 2-acetylcyclohexanone, 2-methylcyclohexanone, 3-methylcyclohexanone, 4-methylcyclohexanone, 2-cyclohexylcyclohexanone, 2-(1-cyclohexenyl)cyclohexanone, 2,5-dimethylcyclohexanone, 3,4-dimethylcyclohexanone, 3,5-dimethylcyclohexanone, 4-ethylcyclohexanone, pulegone, menthone, 4-pentylcyclohexanone, 2-propylcyclohexanone, 3,3,5-trimethylcyclohexanone and thujone. Among the above, cyclohexanone is preferable.

As the cyclic ketone, cyclic ketone containing a nitrogen ring is also preferable, examples of which are caprolactam, N-methylcaprolactam, 1,3-dimethyl-2-imidazolidine, 2-pyrolidone, 1-acetyl-2-pyrolidone, 1-butyl-2-pyrolidone, 2-piperidone and 1,5-dimethyl-2-piperidone.

A cyclic ketone compound is preferably selected from a group consisting of cyclohexanone, cyclopentanone and cycloheptanone (including derivatives thereof).

As a result of various deliberation, the inventors have found that a low-molecular organic EL material is soluble in a cyclohexanone derivative at a higher concentration than in other solvents. In addition, the inventors have also found that, since compounds soluble in cyclohexanone derivative are not narrowly limited, an organic-EL-material-containing solution in which various low-molecular organic EL materials are used can be prepared.

It has been found that, by using a cyclohexanone derivative as the solvent, an organic-EL-material-containing solution containing a sufficient amount of a low-molecular organic EL material having high performance, which has not been able to be put in use because of its low solubility in a conventional solvent, can be prepared.

Further, since a cyclohexanone derivative boils at a high boiling temperature (156 degrees C.: cyclohexanone) and has high viscosity (2 cP: cyclohexanone), a cyclohexanone is suitable for coating processing such as ink jetting. A cyclohexanone derivative is also favorably mixed with an alcohol-base solvent (viscosity control reagent), particularly with a diol-base solvent, so that a high viscosity solution can be prepared by controlling the viscosity. Thus, a cyclohexanone derivative is an excellent solvent for a low-molecular organic EL material, viscosity of which hardly changes merely by dissolving the material in the solvent.

### BRIEF DESCRIPTION OF THE DRAWINGS

FIG. 1 schematically shows an arrangement of an organic EL device according to an exemplary embodiment of the invention.

### DETAILED DESCRIPTION OF PREFERRED EMBODIMENT(S)

### Arrangement of Organic EL Device

Arrangement(s) of an organic EL device will be described below.

### (1) Arrangement of Organic EL Device

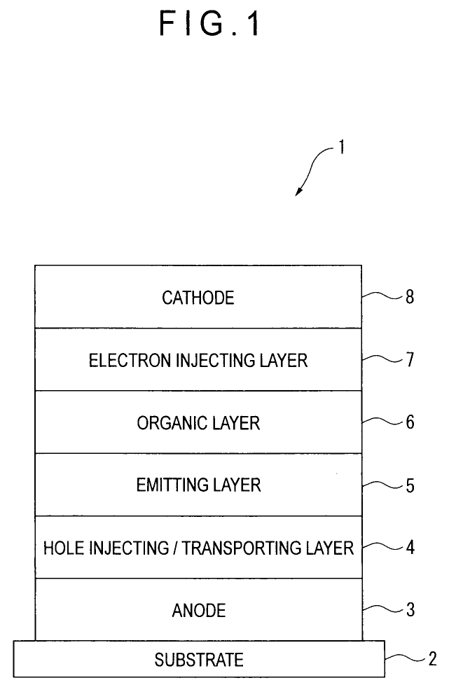

FIG. 1 schematically shows an arrangement of an organic EL device according to this exemplary embodiment.

The organic EL device 1 includes: a transparent substrate 2; an anode 3; at least one of a hole injecting layer and a hole transporting layer (hereinafter referred to as hole injecting/transporting layer) 4; an emitting layer 5; an organic layer 6; an electron injecting layer 7; and a cathode 8.

The hole injecting/transporting layer 4 and the electron injecting layer 7 may not be provided.

An electron blocking layer may be provided to the emitting layer 5 adjacently to the anode 3. With this arrangement, electrons can be trapped in the emitting layer 5, thereby enhancing probability of exciton generation in the emitting layer 5.

### (2) Substrate 2

The substrate 2, which supports the organic EL device, is preferably a smoothly-shaped substrate that transmits 50% or more of light in a visible region of 400 nm to 700 nm. An example of a material for the substrate 2 is a glass.

### (3) Anode 3

The anode 3 injects holes into the hole injecting/transporting layer 4 or the emitting layer 5. It is effective that the anode has a work function of 4.5 eV or more. Exemplary materials for the anode are indium-tin oxide (ITO), tin oxide (NESA), indium zinc oxide, gold, silver, platinum and copper.

### (4) Hole Injecting/Transporting Layer 4

The hole injecting/transporting layer 4 is provided between the emitting layer 5 and the anode 3 for aiding the injection of holes into the emitting layer and transporting the holes to the emitting region. As the hole injecting/transporting layer 4, for instance, 4,4′-bis[N-(1-naphthyl)-N-phenylamino]biphenyl (hereinafter abbreviated as NPD) is usable.

Other examples of the hole injecting/transporting material (which means at least either one of the hole injecting material and the hole transporting material) are a triazole derivative (see, for instance, the specification of U.S. Pat. No. 3,112,197), an oxadiazole derivative (see, for instance, the specification of U.S. Pat. No. 3,189,447), an imidazole derivative (see, for instance, JP-B-37-16096), a polyarylalkane derivative (see, for instance, the specifications of U.S. Pat. No. 3,615,402, No. 3,820,989 and No. 3,542,544, JP-B-45-555, JP-B-51-10983, JP-A-51-93224, JP-A-55-17105, JP-A-56-4148, JP-A-55-108667, JP-A-55-156953, and JP-A-56-36656), a pyrazoline derivative and a pyrazolone derivative (see, for instance, the specifications of U.S. Pat. No. 3,180,729 and No. 4,278,746, JP-A-55-88064, JP-A-55-88065, JP-49-105537, JP-A-55-51086, JP-A-56-80051, JP-A-56-88141, JP-A-57-45545, JP-A-54-112637 and JP-A-55-74546), a phenylenediamine derivative (see, for instance, the specification of U.S. Pat. No. 3,615,404, JP-B-51-10105, JP-B-46-3712, JP-B-47-25336, JP-A-54-53435, JP-A-54-110536 and JP-A-54-119925), an arylamine derivative (see, for instance, the specifications of U.S. Pat. No. 3,567,450, No. 3,180,703, No. 3,240,597, No. 3,658,520, No. 4,232,103, No. 4,175,961 and No. 4,012,376, JP-B-49-35702, JP-B-39-27577, JP-A-55-144250, JP-A-56-119132 and JP-A-56-22437 and the specification of West Germany Patent No. 1,110,518), an amino-substituted chalcone derivative (see, for instance, the specification of U.S. Pat. No. 3,526,501), an oxazole derivative (disclosed in, for instance, the specification of U.S. Pat. No. 3,257,203), a styrylanthracene derivative (see, for instance, JP-A-56-46234), a fluorenone derivative (see, for instance, JP-A-54-110837), a hydrazone derivative (see, for instance, the specification of U.S. Pat. No. 3,717,462 and JP-A-54-59143, JP-A-55-52063, JP-A-55-52064, JP-A-55-46760, JP-A-55-85495, JP-A-57-11350, JP-A-57-148749 and JP-A-02-311591), a stilbene derivative (see, for instance, JP-A-61-210363, JP-A-61-228451, JP-A-61-14642, JP-A-61-72255, JP-A-62-47646, JP-A-62-36674, JP-A-62-10652, JP-A-62-30255, JP-A-60-93455, JP-A-60-94462, JP-A-60-174749 and JP-A-60-175052), a silazane derivative (see the specification of U.S. Pat. No. 4,950,950), a polysilane type (see JP-A-02-204996), an aniline-based copolymer (see JP-A-02-282263), and a conductive polymer oligomer (particularly, thiophene oligomer) disclosed in JP-A-01-211399.

The hole-injectable material, examples of which are as listed above, is preferably a porphyrin compound (disclosed in JP-A-63-295695 etc.), an aromatic tertiary amine compound or a styrylamine compound (see, for instance, the specification of U.S. Pat. No. 4,127,412, JP-A-53-27033, JP-A-54-58445, JP-A-54-149634, JP-A-54-64299, JP-A-55-79450, JP-A-55-144250, JP-A-56-119132, JP-A-61-295558, JP-A-61-98353 or JP-A-63-295695), particularly preferably an aromatic tertiary amine compound.

In addition, 4,4′-bis(N-(1-naphthyl)-N-phenylamino)biphenyl (hereinafter, abbreviated as NPD) having in the molecule two fused aromatic rings disclosed in U.S. Pat. No. 5,061,569, 4,4′,4″-tris(N-(3-methylphenyl)-N-phenylamino) triphenylamine (hereinafter, abbreviated as MTDATA) in which three triphenylamine units disclosed in JP-A-04-308688 are bonded in a starburst form and the like may also be used.

Alternatively, inorganic compounds such as p-type Si and p-type SiC can also be used as the hole-injecting material. Further, a hexaazatriphenylene derivative disclosed in Japanese Patent No. 3614405 and No. 3571977 and U.S. Pat. No. 4,780,536 may also preferably be used as the hole-injecting material.

### (5) Emitting Layer 5

The above-described polycyclic fused aromatic compound may be used in the emitting layer 5. The above-described material may be used as the first phosphorescent material. The polycyclic fused aromatic compound and the first phosphorescent material are dissolved in the above-described solvent, and the solution is used as the organic-EL-material-containing solution.

### (6) Organic Layer 6

In the organic layer 6, the above-described polycyclic fused aromatic compound having a larger ionization potential than the polycyclic fused aromatic compound used in the emitting layer 5 is usable. In addition, the above-described material may be used as the second phosphorescent material. The second phosphorescent material may be the same as or different from the first phosphorescent material.

### (7) Electron Injecting Layer 7

The electron injecting layer 7 aids the injection of electrons into the organic layer 6 or the emitting layer 5. The electron injecting layer and the electron transporting layer may be formed together. The above-described material may be used as the electron injecting layer 7.

In the organic EL device according to the aspect of the invention, a reductive dopant may be preferably contained in an interfacial region between the cathode and the organic thin-film layer.

With this arrangement, the organic EL device can emit light with enhanced luminance intensity and have a longer lifetime.

The reductive dopant is defined as a substance capable of reducing an electron-transporting compound. Accordingly, as long as the substance has reducibility of a predetermined level, various substances may be usable. For instance, at least one substance selected from a group consisting of alkali metal, alkali earth metal, rare-earth metal, oxide of alkali metal, halide of alkali metal, oxide of alkali earth metal, halide of alkali earth metal, oxide of rare-earth metal, halide of rare-earth metal, organic complex of alkali metal, organic complex of alkali earth metal and organic complex of rare-earth metal can be favorably used.

Specifically, a preferable reductive dopant is at least one alkali metal selected from a group consisting of Li (work function: 2.9 eV), Na (work function: 2.36 eV), K (work function: 2.28 eV), Rb (work function: 2.16 eV) and Cs (work function: 1.95 eV), or at least one alkali earth metal selected from a group consisting of Ca (work function: 2.9 eV), Sr (work function: 2.0 to 2.5 eV) and Ba (work function: 2.52 eV). A substance having work function of 2.9 eV or less is particularly preferable.

Among the above, a more preferable reductive dopant is at least one alkali metal selected from a group consisting of K, Rb and Cs. A further more preferable reductive dopant is Rb or Cs. The most preferable reductive dopant is Cs. Since the above alkali metals have particularly high reducibility, addition of a relatively small amount of these alkali metals to an electron injecting zone can enhance luminance intensity and lifetime of the organic EL device. As a reductive dopant having work function of 2.9 eV or less, a combination of two or more of the alkali metals is also preferable. Particularly, a combination including Cs (e.g., Cs and Na, Cs and K, Cs and Rb, or Cs, Na and K) is preferable. A reductive dopant containing Cs in a combining manner can efficiently exhibit reducibility. Addition of the reductive dopant to the electron injecting zone can enhance luminance intensity and lifetime of the organic EL device.

### (8) Cathode 8

An example of the cathode is aluminum.

### (Manufacturing Method of Organic EL Device)

By using the above-exemplified materials, the anode 3, the hole injecting/transporting layer 4, the emitting layer 5, the organic layer 6, the electron injecting layer 7 and the cathode 8 are formed on the substrate 2, through which the organic EL device 1 can be manufactured. Alternatively, the organic EL device can be also manufactured in the reverse order of the above (i.e., from the cathode to the anode). Manufacturing examples will be described below.

In manufacturing the organic EL device 1, a thin film made of anode material is initially formed on a suitable transparent substrate 2 to be 1 μm thick or less, more preferably 10 to 200 nm thick, by a method such as vapor deposition or sputtering, through which an anode 3 is manufactured.

Then, a hole injecting/transporting layer 4 is provided on the anode 3. The hole injecting/transporting layer 4 can be formed by a method such as vacuum deposition, spin coating, casting and LB method. The thickness of the hole injecting/transporting layer 4 may be suitably determined preferably in a range of 5 nm to 5 μm.

Next, an emitting layer 5, which is to be formed on the hole injecting/transporting layer 4, can be formed by forming a desirable organic emitting material into film by dry processing (representative example: vacuum deposition) or by wet processing such as spin coating or casting. The thickness of the emitting layer 5 is preferably in a range of 5 nm to 40 nm.

An organic layer 6 is subsequently provided on the emitting layer 5. The organic layer 6 is formed by the same method as the emitting layer 5. The thickness of the organic layer is preferably in a range of 5 nm to 40 nm.

The aggregate thickness of the emitting layer 5 and the organic layer 6 is preferably in a range of 10 nm to 80 nm, more preferably in a range of 10 nm to 50 nm.

An electron injecting layer 7 is subsequently provided on the organic layer 6. The organic layer 7 is formed by the same method as the hole injecting/transporting layer 4. The thickness of the electron injecting layer 7 may be suitably determined preferably in a range of 5 nm to 5 μm.

Lastly, a cathode 8 is laminated thereon, and the organic EL device 1 is obtained. The cathode 8 is formed of metal by vapor deposition or sputtering. However, in order to protect the underlying organic layer from damages at the time of film forming, vacuum deposition is preferable.

A method of forming each of the layers in the organic EL device 1 is not particularly limited.

Conventionally-known methods such as vacuum deposition and spin coating are usable. Specifically, the organic thin-film layer may be formed by a conventional coating method such as vacuum deposition, molecular beam epitaxy (MBE method) and coating methods using a solution such as a dipping, spin coating, casting, bar coating, roll coating and ink jetting.

Although the thickness of each organic layer of the organic EL device 1 is not particularly limited, the thickness is typically preferably in a range of several nanometers to 1 μm because an excessively-thinned film is likely to entail defects such as a pin hole while an excessively-thickened film requires high voltage to be applied and deteriorates efficiency.

It should be noted that the invention is not limited to the above exemplary embodiment but may include any modification and improvement as long as such modification and improvement are compatible with an object of the invention.

For instance, while the organic layer contains the second phosphorescent material in this exemplary embodiment, the organic layer may not contain the second phosphorescent material.

### EXAMPLES

Next, the invention will be described in further detail by exemplifying Example(s) and Comparative(s). However, the invention is not limited by the description of Example(s).

### <Test 1>

Initially, effectiveness of an organic layer was tested.

### Example 1

A glass substrate (size: 25 mm×75 mm×1.1 mm thick) having an ITO transparent electrode (manufactured by Geomatec Co., Ltd.) was ultrasonic-cleaned in isopropyl alcohol for five minutes, and then UV/ozone-cleaned for 30 minutes.

After the glass substrate having the transparent electrode line was cleaned, the glass substrate was mounted on a substrate holder of a vacuum deposition apparatus. Then, 50-nm thick film of 4,4′-bis[N-(1-naphthyl)-N-phenylamino]biphenyl (hereinafter abbreviated as “NPD film”) was formed initially onto a surface of the glass substrate provided with the transparent electrode line by resistance heating deposition in such a manner that the NPD film covered the transparent electrode. The NPD film served as the hole injecting/transporting layer.

Then, an emitting layer was formed on the NPD film. The following compound (H1), which was used as the phosphorescent host, was formed into 40-nm thick film by resistance heating deposition. At the same time, the following compound (D1) (Ir(ppy)₃), which was used as the phosphorescent emitting material, was deposited at a content of 5% (mass ratio) of the compound (H1). This film served as the phosphorescent emitting layer.

Then, an organic layer was formed on the phosphorescent emitting layer. The following compound (H2) was formed into 10-nm thick film. The organic layer served as the hole blocking layer.

Further, 40-nm thick film of the following compound J was formed on this film. This film served as an electron injecting layer.

After that, LiF was formed into 1-nm thick film. Metal (Al) was vapor-deposited on the LiF film to form a 150-nm thick metal cathode, thereby providing the organic EL device.

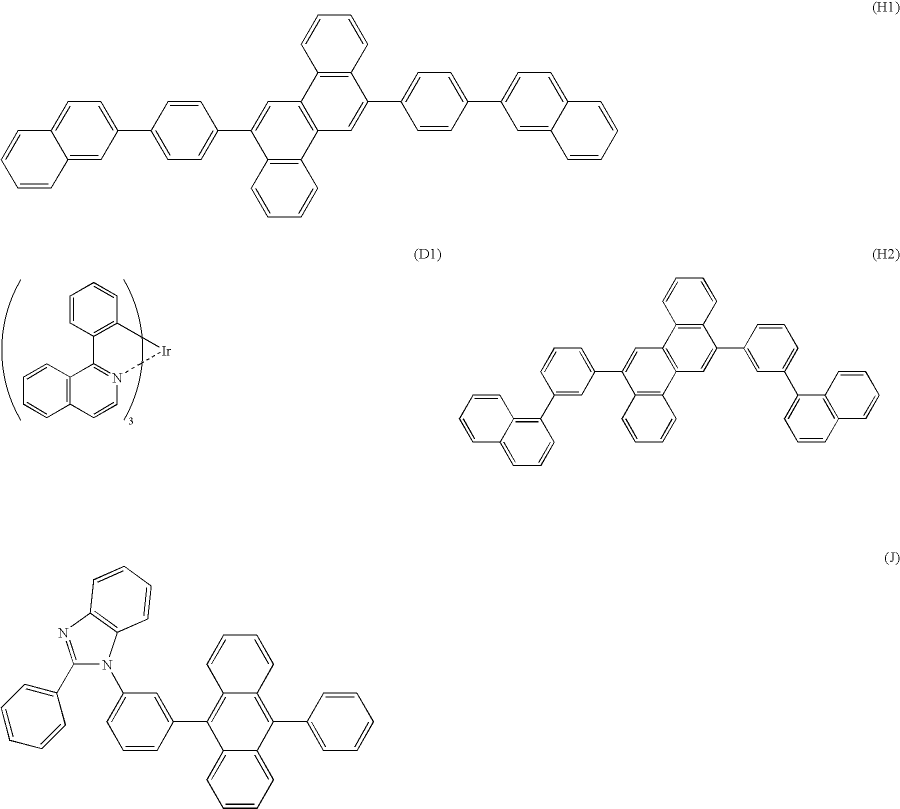

### Example 2

Except that the following compound (H3) was used as the organic layer, the organic EL device according to the Example 2 was manufactured in the same manner as the Example 1.

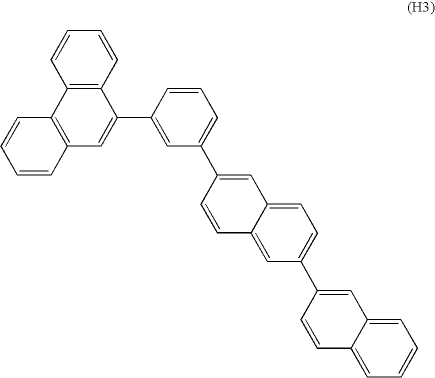

### [Comparative 1]

Except that Balq (bis-(2-methyl-8-quinolinolate)-4-(phenylphenolate) aluminum) was used as the organic layer, the organic EL device according to the Comparative I was manufactured in the same manner as the Example 1.

### [Evaluation of Organic EL Device]

The organic EL devices each manufactured as described above were driven by direct-current electricity of 1 mA/cm² to emit light, so that emission chromaticity and voltage were measured. In addition, by conducting a direct-current continuous current test with the initial luminance intensity being set at 5000 cd/m² for each organic EL device, time elapsed until the initial luminance intensity was reduced to the half (i.e., time until half-life) was measured for each organic EL device.

The results of the evaluation are shown in Table 1.

TABLE 1

| | Voltage | Current Density | Chromaticity | | Lifetime |
|---|---|---|---|---|---|
| | (V) | (Ma/cm²) | x | y | @5000nit |
| Example 1 | 5.49 | 1.00 | 0.682 | 0.316 | 1000 H |
| Example 2 | 4.79 | 1.00 | 0.683 | 0.316 | 1000 H |
| Comparative 1 | 4.58 | 1.00 | 0.682 | 0.317 | 500 H |

As is clear from the Table 1, the organic EL devices according to the Examples 1 and 2 have long lifetime.

On the other hand, the Comparative 1, where Balq (a material conventionally used for a hole blocking layer) was used, has short lifetime.

### <Test 2>

Next, an arrangement where the organic layer contained the phosphorescent material was tested.

### Example 3

A glass substrate (size: 25 mm×75 mm×1.1 mm thick) having an ITO transparent electrode (manufactured by Geomatec Co., Ltd.) was ultrasonic-cleaned in isopropyl alcohol for five minutes, and then UV/ozone-cleaned for 30 minutes.

After the glass substrate having the transparent electrode line was cleaned, the glass substrate was mounted on of a substrate holder of a vacuum deposition apparatus. Then, 50-nm thick film of 4,4′-bis[N-(1-naphthyl)-N-phenylamino]biphenyl (hereinafter abbreviated as “NPD film”) was initially formed by resistance heating deposition onto a surface of the glass substrate where the transparent electrode line was provided in a manner of covering the transparent electrode. The NPD film served as the hole injecting/transporting layer.

Then, an emitting layer was formed on the NPD film. The compound (H1) was formed into 20-nm thick film by resistance heating deposition. At the same time, the compound (D1), which was used as the phosphorescent emitting material, was deposited at a content of 5% (mass ratio) of the compound (H1).

Then, an organic layer was formed on the phosphorescent emitting layer. The compound (H2) was formed into 20-nm thick film by resistance heating deposition. At the same time, the compound (D1), which was used as the phosphorescent emitting material, was deposited at a content of 5% (mass ratio) of the compound (H2).

Further, 40-nm film of the compound J was formed on the organic layer. This film served as an electron injecting layer.

After that, LiF was formed into 1-nm thick film. Metal (Al) was vapor-deposited on the LiF film to form a 150-nm thick metal cathode, thereby providing the organic EL device.

### Example 4

Except that the compound (H3) was used in place of the compound (H2) used for the organic layer, the organic EL device according to the Example 4 was manufactured in the same manner as the Example 1.

### [Comparative 2]

Except that no organic layer was provided, the organic EL device according to the Comparative 2 was manufactured in the same manner as the Example 1.

### [Comparative 3]

Except that no emitting layer was provided, the organic EL device according to the Comparative 3 was manufactured in the same manner as the Example 1.

### [Comparative 4]

Except that no emitting layer was provided and thickness was different, the organic EL device according to the Comparative 4 was manufactured in the same manner as the Example 2. In the Comparative 4, the film thickness of the emitting layer was 20 nm while the film thickness of the organic layer was 20 nm.

### [Evaluation of Organic EL Device]

The organic EL devices respectively manufactured in the Examples 3, 4 and the Comparatives 2 to 4 were driven by direct-current electricity to emit light, so that emission chromaticity and voltage were measured. In addition, by conducting a direct-current continuous current test with the initial luminance intensity being set at 1000 cd/m² for each organic EL device, time elapsed until the initial luminance intensity was reduced to the half (i.e., time until half-life) was measured for each organic EL device.

The results of the evaluation are shown in the Table 2 below. Triplet energy gap Eg(T) of the compounds (H1) to (H3) is shown in the Table 3 below.

TABLE 2

| | Voltage | Current Density | Chromaticity | | Lifetime |
|---|---|---|---|---|---|
| | (V) | (mA/cm²) | x | y | @5000nit |
| Example 3 | 4.73 | 1.00 | 0.683 | 0.316 | 5000 H |
| Example 4 | 4.12 | 1.00 | 0.683 | 0.317 | 5000 H |
| Comparative 2 | 3.94 | 1.00 | 0.682 | 0.317 | 500 H |
| Comparative 3 | 4.30 | 1.00 | 0.685 | 0.313 | 4000 H |
| Comparative 4 | 4.37 | 1.00 | 0.678 | 0.321 | 4000 H |

TABLE 3

| | Eg(T) |
|---|---|
| Compound H1 | 2.38 |
| Compound H2 | 2.40 |
| Compound H3 | 2.44 |

As is clear from the Table 2, the organic EL devices according to the Examples 3 and 4, each of which includes the emitting layer and the organic layer for which different polycyclic fused aromatic compounds were respectively used, have long lifetime.

On the other hand, the Comparative 2 has considerably short lifetime as compared to the Examples 3 and 4.

The priority applications respectively numbered as JP2007-303712 and JP2008-297887 upon which this patent application is based are hereby incorporated by reference.

What is claimed is:

1. An organic electroluminescence device, comprising:
an anode;
a cathode; and
an organic thin-film layer provided between the anode and the cathode, wherein the organic thin-film layer comprises:
an emitting layer comprising: a first polycyclic fused aromatic compound having a substituted or unsubstituted polycyclic fused aromatic skeleton; and a first phosphorescent material for emitting phosphorescence; and
an organic layer provided on the emitting layer adjacently to the cathode, the organic layer comprising a second polycyclic fused aromatic compound having a substituted or unsubstituted polycyclic fused aromatic skeleton.

2. The organic electroluminescence device according to claim 1, wherein at least either one of the first polycyclic fused aromatic compound and the second polycyclic aromatic compound has minimum excited triplet energy gap of 2.1 eV to 2.7 eV, and the polycyclic fused aromatic skeleton has 10 to 30 ring-forming atoms.

3. The organic electroluminescence device according to claim 1, wherein ionization 20 potential of the second polycyclic fused aromatic compound is larger than ionization potential of the first polycyclic fused aromatic compound.

4. The organic electroluminescence device according to claim 1, wherein minimum triplet energy gap Eg(T2) of the second polycyclic fused aromatic compound is larger than minimum triplet energy gap Eg(T1) of the first polycyclic fused aromatic compound.

5. The organic electroluminescence device according to claim 1, wherein the organic layer further comprises a second phosphorescent material for emitting phosphorescence.

6. The organic electroluminescence device according to claim 1, wherein the organic layer further comprises the first phosphorescent material.

7. The organic electroluminescence device according to claim 1, wherein the polycyclic fused aromatic skeletons each are present as a divalent or multivalent group in a chemical structure formula.

8. The organic electroluminescence device according to claim 1, wherein
the polycyclic fused aromatic skeletons each have a substituent, and
the substituent is a substituted or unsubstituted aryl group or a heteroaryl group.

9. The organic electroluminescence device according to claim 8, wherein the substituent of the polycyclic fused aromatic skeletons each is other than a substituent having a carbazole skeleton.

10. The organic electroluminescence device according to claim 7, wherein the polycyclic fused aromatic skeletons each are selected from a group consisting of substituted or unsubstituted phenanthrene-diyl, chrysene-diyl, fluoranthene-diyl and triphenylene-diyl.

11. The organic electroluminescence device according to claim 10, wherein the polycyclic fused aromatic skeletons each are substituted by a group containing phenanthrene, chrysene, fluoranthene or triphenylene.

12. The organic electroluminescence device according to claim 1, wherein the polycyclic fused aromatic skeletons each are represented by one of formulae (1) to (4) as follows, 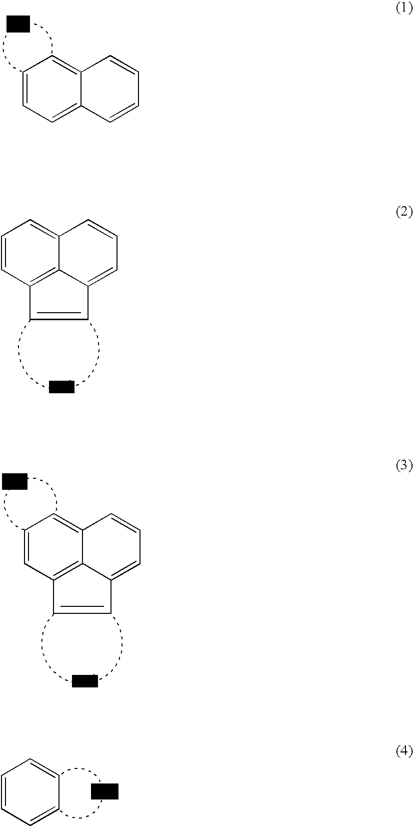
where Ar¹ to Ar⁵ each represent a substituted or unsubstituted fused ring structure having 4 to 10 ring-forming carbon atoms (excluding the number of carbon atoms in a substituent).

13. The organic electroluminescence device according to claim 1, wherein at least either one of the first phosphorescent material and the second phosphorescent material contains a metal complex comprising: a metal selected from Ir, Pt, Os, Au, Cu, Re and Ru; and a ligand.

14. The organic electroluminescence device according to claim 1, wherein wavelength of maximum emission luminance of the first phosphorescent material and the second phosphorescent material is in a range of 470 nm to 700 nm.

15. The organic electroluminescence device according to claim 1, wherein a difference in wavelength of maximum emission luminance between the first phosphorescent material and the second phosphorescent material is within plus or minus 20 nm.

16. The organic electroluminescence device according to claim 1, wherein the organic thin-film layer further comprises an electron injecting layer between the cathode and the organic layer, and
the electron injecting layer contains a nitrogen-containing heterocyclic derivative.

17. An organic-electroluminescent-material-containing solution for forming the emitting layer in the organic electroluminescence device according to claim 1, the solution comprising:
a solvent;
the first polycyclic fused aromatic compound dissolved in the solvent; and
the first phosphorescent material dissolved in the solvent.

18. An organic-electroluminescent-material-containing solution for forming the organic layer in the organic electroluminescence device according to claim 5, the solution comprising:
a solvent;
the second polycyclic fused aromatic compound dissolved in the solvent; and
the second phosphorescent material dissolved in the solvent.
